(19) United States
(12) Patent Application Publication
(10) Pub. No.: US 2010/0248144 A1
(43) Pub. Date: Sep. 30, 2010

(54) POSITIVE RESIST COMPOSITION, METHOD OF FORMING RESIST PATTERN

(75) Inventors: Takeshi IWAI, Kawasaki-shi (JP); Jun IWASHITA, Kawasaki-shi (JP); Daichi TAKAKI, Kawasaki-shi (JP)

Correspondence Address: KNOBBE MARTENS OLSON & BEAR LLP, 2040 MAIN STREET, FOURTEENTH FLOOR, IRVINE, CA, 92614, US

(73) Assignee: TOKYO OHKA KOGYO CO., LTD., Kawasaki-shi (JP)

(21) Appl. No.: 12/730,070

(22) Filed: Mar. 23, 2010

(30) Foreign Application Priority Data
Mar. 26, 2009 (JP) 2009-077623
Jan. 28, 2010 (JP) 2010-017352

(51) Int. Cl. G03F 7/004; G03F 7/20

(52) U.S. Cl. 430/285.1; 430/270.1; 430/281.1; 430/326

(57) ABSTRACT

The positive resist composition including a base material component (A) which exhibits increased solubility in an alkali developing solution under action of acid and an acid generator component (B) which generates acid upon exposure,
the positive resist composition characterized in that in those cases where a resist film is formed on a substrate using the positive resist composition and is then subjected to a selective exposure and developing to form a hole pattern, followed by a bake treatment,
a bake treatment temperature (Tf), at which the size of the hole is reduced by 10%, as compared to the size of the hole before the bake treatment, is at least 100° C.; and also that
in those cases where a resist film is formed on a substrate using the positive resist composition and is then subjected to a selective exposure and developing to form a hole pattern, followed by the entire surface exposure and then by a bake treatment, a bake treatment temperature (Tf′), at which the size of the hole is reduced by 10%, as compared to the size of the hole before the bake treatment, is at least 18° C. lower than the Tf.

### BACKGROUND OF THE INVENTION

1. Field of the Invention

The present invention relates to a positive resist composition and a method of forming a resist pattern that uses the positive resist composition.

Priority is claimed on Japanese Patent Application No. 2009-077623, filed Mar. 26, 2009, and Japanese Patent Application No. 2010-017352, filed on Jan. 28, 2010, the contents of which is incorporated herein by reference.

2. Description of the Related Art

In lithography techniques, for example, a resist film composed of a resist material is formed on a substrate, and the resist film is subjected to selective exposure of radial rays such as light or electron beam through a mask having a predetermined pattern, followed by development, thereby forming a resist pattern having a predetermined shape on the resist film.

A resist material in which the exposed portions become soluble in a developing solution is called a positive-type, and a resist material in which the exposed portions become insoluble in a developing solution is called a negative-type.

In recent years, in the production of semiconductor elements and liquid crystal display elements, advances in lithography techniques have lead to rapid progress in the field of pattern miniaturization.

Typically, these miniaturization techniques involve shortening the wavelength (increasing the energy) of the exposure light source. Conventionally, ultraviolet radiation typified by g-line and i-line radiation (emission lines of mercury) has been used, but nowadays KrF excimer lasers and ArF excimer lasers are now starting to be introduced in mass production. Furthermore, research is also being conducted into lithography techniques that use an exposure light source having a shorter wavelength (a higher energy) than these excimer lasers, such as electron beam, extreme ultraviolet radiation (EUV), and X ray.

Resist materials for use with these types of exposure light sources require lithography properties such as a high resolution capable of reproducing patterns of minute dimensions, and a high level of sensitivity to these types of exposure light sources.

As a resist material which satisfies these conditions, a chemically amplified resist composition is used, which includes a base material component that exhibits a changed solubility in an alkali developing solution under action of acid and an acid generator that generates acid upon exposure.

For example, as a chemically amplified positive resist composition, those containing a resin component (base resin) which exhibits increased solubility in an alkali developing solution under action of acid and an acid generator component are typically used. If the resist film formed using the resist composition is selectively exposed during formation of a resist pattern, then within the exposed portions, acid is generated from the acid generator, and the action of this acid causes an increase in the solubility of the resin component in an alkali developing solution, making the exposed portions soluble in the alkali developing solution.

Currently, resins that contain structural units derived from (meth)acrylate esters within the main chain (acrylic resins) are typically used as base resins for resists that use ArF excimer laser lithography, as they exhibit excellent transparency in the vicinity of 193 nm (for example, refer to Patent Document 1). Here, the term “(meth)acrylic acid” is a generic term that includes either or both of acrylic acid having a hydrogen atom bonded to the α-position and methacrylic acid having a methyl group bonded to the α-position. The term “(meth)acrylate ester” is a generic term that includes either or both of the acrylate ester having a hydrogen atom bonded to the α-position and the methacrylate ester having a methyl group bonded to the α-position. The term “(meth)acrylate” is a generic term that includes either or both of the acrylate having a hydrogen atom bonded to the α-position and the methacrylate having a methyl group bonded to the α-position.

Further, in order to improve various lithography properties, a base resin having a plurality of structural units is currently used for a chemically amplified resist. For example, in the case of a positive resist, a base resin containing a structural unit having an acid dissociable, dissolution inhibiting group that is dissociated by the action of acid generated from the acid generator, a structural unit having a polar group such as a hydroxyl group, a structural unit having a lactone structure, and the like is typically used. Among these structural units, a structural unit having a lactone structure is generally considered as being effective in improving the adhesion between the resist film and the substrate, and increasing the compatibility with an alkali developing solution, thereby contributing to improvement in various lithography properties.

Further, in recent years, studies on the miniaturization of resist patterns have been conducted by causing the molecular weight to change before and after the exposure using a base resin that is cleaved by the action of acid, although a satisfactory level of changes in the molecular weight has not been achieved (for example, refer to Patent Documents 2 to 4).

Furthermore, even if a polymer exhibits a satisfactory level of changes in the molecular weight when cleaved by the action of acid, the polymer does not necessarily exhibit a required level of heat resistance for a resist material (for example, refer to Patent Documents 5 and 6).

### Documents of Related Art

### [Patent Documents]

[Patent Document 1] Japanese Unexamined Patent Application, First Publication No. 2003-241385

[Patent Document 2] Japanese Unexamined Patent Application, First Publication No. 2006-349939

[Patent Document 3] Japanese Unexamined Patent Application, First Publication No. 2008-009269

[Patent Document 4] Japanese Unexamined Patent Application, First Publication No. 2008-250157

[Patent Document 5] Japanese Unexamined Patent Application, First Publication No. Hei 5-86334

[Patent Document 6] Japanese Unexamined Patent Application, First Publication No. 2005-290214

### SUMMARY OF THE INVENTION

As further progress is made in lithography techniques and the application field for lithography techniques expands, development of a novel material for use in lithography will be desired. For example, as miniaturization of resist patterns progress, improvement will be demanded for resist materials with respect to various lithography properties such as resolution, line edge roughness (LER) and the like.

The present invention takes the above circumstances into consideration, with an object of providing a positive resist composition that exhibits excellent lithography properties, and a method of forming a resist pattern using the positive resist composition.

In order to solve the above-mentioned problems, the present invention employs the following aspects.

That is, a first aspect of the present invention is a positive resist composition including a base material component (A) which exhibits increased solubility in an alkali developing solution under action of acid and an acid generator component (B) which generates acid upon exposure, the positive resist composition characterized in that in those cases where a resist film is formed on a substrate using the positive resist composition and is then subjected to a selective exposure and developing to form a hole pattern, followed by a bake treatment, it is required that a bake treatment temperature (Tf) at which the extent of reduction in the dimensions of the hole reaches 10% as compared to those prior to the bake treatment is at least 100° C.; and also that in those cases where a resist film is formed on a substrate using the positive resist composition and is then subjected to a selective exposure and developing to form a hole pattern, followed by the entire surface exposure and then by a bake treatment, a bake treatment temperature (Tf′) at which the extent of reduction in the dimensions of the hole reaches 10% as compared to those prior to the bake treatment is at least 18° C. lower than the Tf described above.

A second aspect of the present invention is a method of forming a resist pattern, including: applying a resist composition of the first aspect to a substrate to form a resist film on the substrate; conducting exposure of the resist film; and alkali-developing the resist film to form a resist pattern.

In the present description and claims, the term “aliphatic” is a relative concept used in relation to the term “aromatic”, and defines a group or compound that has no aromaticity.

The term “alkyl group” includes linear, branched and cyclic, monovalent saturated hydrocarbon groups, unless otherwise specified.

The term “alkylene group” includes linear, branched and cyclic divalent saturated hydrocarbons, unless otherwise specified. The same applies for the alkyl group within an alkoxy group.

A “halogenated alkyl group” is a group in which part or all of the hydrogen atoms of an alkyl group have been substituted with halogen atoms. Examples of the halogen atoms include a fluorine atom, a chlorine atom, a bromine atom and an iodine atom.

A “fluorinated alkyl group” or a “fluorinated alkylene group” is a group in which part or all of the hydrogen atoms of an alkyl group or an alkylene group have been substituted with a fluorine atom.

The term “structural unit” refers to a monomer unit that contributes to the formation of a polymeric compound (namely, a resin, polymer or copolymer).

The term “structural unit derived from an acrylate ester” refers to a structural unit that is formed by the cleavage of the ethylenic double bond of an acrylate ester.

The term “acrylate ester” is a generic term that includes acrylate esters having a hydrogen atom bonded to the carbon atom on the α-position, and acrylate esters having a sub stituent (an atom other than a hydrogen atom or a group) bonded to the carbon atom on the α-position. Examples of the substituent bonded to the carbon atom on the α-position include an alkyl group of 1 to 5 carbon atoms, a halogenated alkyl group of 1 to 5 carbon atoms and a hydroxyalkyl group. A carbon atom on the α-position of an acrylate ester refers to the carbon atom bonded to the carbonyl group, unless specified otherwise.

The term “hydroxystyrene derivative” is a generic term that includes both the narrow definition of hydroxystyrene, as well as compounds in which the α-position hydrogen atom of the narrowly defined hydroxystyrene has been substituted with a substituent group such as an alkyl group or a haloalkyl group or the like, and derivatives thereof. Furthermore, unless stated otherwise, the “α-position (the carbon atom on the α-position)” of hydroxystyrene refers to the carbon atom to which the benzene ring is bonded.

The expression “structural unit derived from a hydroxystyrene derivative” describes a structural unit that is formed by the cleavage of the ethylenic double bond of the hydroxystyrene derivative.

The term “styrene” refers to a general concept including styrene itself, as well as structures in which the hydrogen atom at the α-position in styrene has been substituted by another substituent group such as an alkyl group.

The term “structural unit derived from styrene” refers to a structural unit which is formed by the cleavage of the ethylenic double bond of styrene. In the styrene, the hydrogen atom of the phenyl group may be substituted by a substituent such as an alkyl group of 1 to 5 carbon atoms.

The term “exposure” is used as a general concept that includes irradiation with any form of radiation.

According to the present invention, there can be provided a positive resist composition that exhibits excellent lithography properties, and a method of forming a resist pattern using the positive resist composition.

### DETAILED DESCRIPTION OF THE INVENTION

### <<Positive Resist Composition>>

The positive resist composition (hereafter, frequently referred to simply as “resist composition”) of the present invention includes a base material component (A) (hereafter, referred to as “component (A)”) which exhibits increased solubility in an alkali developing solution under action of acid and an acid generator component (B) (hereafter, referred to as “component (B)”) which generates acid upon irradiation.

In the positive resist composition, when radial rays are irradiated (when exposure is conducted), acid is generated from the component (B), and the solubility of the component (A) in an alkali developing solution is increased by the action of the generated acid. Therefore, in the formation of a resist pattern, by conducting selective exposure of a resist film formed by using the positive resist composition of the present invention, the solubility of the exposed portions of the resist film in an alkali developing solution is increased, whereas the solubility of the unexposed portions in an alkali developing solution is unchanged, and hence, a resist pattern can be formed by alkali developing.

Here, the term “base material component” refers to an organic compound capable of forming a film. As the base material component, an organic compound having a molecular weight of 500 or more can be preferably used. When the organic compound has a molecular weight of 500 or more, the film-forming ability is improved, and a nano level resist pattern can be readily formed.

The “organic compound having a molecular weight of 500 or more” which can be used as a base material component is broadly classified into non-polymers and polymers.

In general, as a non-polymer, any of those which have a molecular weight in the range of 500 to less than 4,000 is used. Hereafter, a non-polymer having a molecular weight in the range of 500 to less than 4,000 is referred to as a low molecular weight compound.

As a polymer, any of those which have a molecular weight of 2,000 or more is used. Hereafter, a polymer having a molecular weight of 2,000 or more is referred to as a polymeric compound. With respect to a polymeric compound, the “molecular weight” is the weight average molecular weight in terms of the polystyrene equivalent value determined by gel permeation chromatography (GPC). Hereafter, a polymeric compound is frequently referred to simply as a “resin”.

The above-mentioned components (A) and (B) will be described later in detail.

Further, with respect to the positive resist composition of the present invention, in those cases where a resist film is formed on a substrate and is then subjected to a selective exposure and developing to form a hole pattern, followed by a bake treatment, it is required that a bake treatment temperature (Tf) at which the extent of reduction in the dimensions of the hole reaches 10% as compared to those prior to the bake treatment is at least 100° C.; and also that in those cases where a resist film is formed on a substrate using the positive resist composition and is then subjected to a selective exposure and developing to form a hole pattern, followed by the entire surface exposure and then by a bake treatment, a bake treatment temperature (Tf′) at which the extent of reduction in the dimensions of the hole reaches 10% as compared to those prior to the bake treatment is at least 18° C. lower than the Tf described above.

Hereafter, the Tf described above is frequently referred to as the “resist softening point before exposure”.

Further, the Tf′ described above is frequently referred to as the “resist softening point after exposure”.

Furthermore, the difference between Tf and Tf′ (i.e., (Tf−Tf′)) is frequently referred to as the “gap between the resist softening points”.

### Regarding the Measurements of Tf and Tf′, and Gap Between the Resist Softening Points]

Specifically, the Tf and Tf′ are measured in the following manner, to determine the gap between the resist softening points.

### (1) Formation of Isolated Hole Pattern

An organic anti-reflection film composition is applied onto an 8-inch silicon wafer, and the composition is then baked appropriately within a temperature range from 160 to 250° C. for 60 to 90 seconds and dried, thereby forming an organic anti-reflection film having a film thickness of 65 nm. Then, the positive resist composition is applied onto the anti-reflection film using a spinner, and is then prebaked (PAB) at a temperature from 80 to 120° C. for 60 to 90 seconds and dried, thereby forming a resist film having a film thickness of 100 nm.

Subsequently, the resist film is selectively irradiated through a mask pattern with a KrF excimer laser (248 nm). The exposure light source can be appropriately changed depending on the types of base material components as long as the same exposure light source is used for exposing each of the resist compositions.

Thereafter, a post exposure bake (PEB) treatment is conducted at a temperature from 80 to 120° C. for 60 to 90 seconds, followed by alkali development for 60 seconds at 23° C. in a 2.38% by weight aqueous solution of tetramethylammonium hydroxide (TMAH) (for example, NMD-3 (product name; manufactured by Tokyo Ohka Kogyo Co., Ltd.), or the like), thereby forming an isolated hole pattern with a hole diameter of 170 nm and a pitch of 1,200 nm in the resist film.

### (2) Measurement of Resist Softening Point Before Exposure (Tf)

Each of the obtained isolated hole patterns is subjected either to a temperature of 23° C. (i.e., no postbake treatment) or a postbake treatment of different temperatures; i.e., at 80° C., 90° C. or a total of 14 different temperatures from 95° C. to 160° C. with 5° C. intervals, for 60 seconds. The dimensional variation in the hole diameter with respect to the hole dimension of the hole pattern with no postbake treatment (i.e., the hole pattern subjected to a temperature of 23° C.) is recorded for the hole patterns subjected to a postbake treatment at each temperature. The resist softening point before exposure (Tf) is defined as a temperature at which the extent of reduction in the hole dimension reaches 10%, with respect to the hole dimension of the hole pattern with no postbake treatment (i.e., the hole pattern subjected to a temperature of 23° C.). The range of postbake treatment temperatures may be appropriately adjusted, depending on the types of materials used.

### (3) Measurement of Resist Softening Point After Exposure (Tf′)

Each of the isolated hole patterns described in the above section (2) on which no postbake treatment has been conducted is subjected to exposure across the entire surface by irradiating with a Krf excimer laser (248 nm) thereto once again. The exposure dose for each of the resist compositions in this process is the same level as the optimum exposure dose for obtaining an isolated hole pattern with a hole diameter of 170 nm described in the above section (1). Then, a PEB treatment is conducted at a temperature from 80 to 120° C. for 60 to 90 seconds. Thereafter, as in the section (2) described above, each of the obtained isolated hole patterns is subjected either to a temperature of 23° C. (i.e., no postbake treatment) or a postbake treatment of different temperatures; i.e., at 80° C., 90° C. or a total of 14 different temperatures from 95° C. to 160° C. with 5° C. intervals, for 60 seconds. The dimensional variation in the hole diameter with respect to the hole dimension of the hole pattern with no postbake treatment (i.e., the hole pattern subjected to a temperature of 23° C.) is recorded for the hole patterns subjected to a postbake treatment at each temperature. The resist softening point after exposure (Tf′) is defined as a temperature at which the extent of reduction in the hole dimension reaches 10%, with respect to that of the hole pattern with no postbake treatment (i.e., the hole pattern subjected to a temperature of 23° C.).

### (4) Calculation of Gap Between the Resist Softening Points

The difference between the obtained Tf and Tf′ values (i.e., (Tf−Tf′)) corresponds to the “gap between the resist softening points”.

The resist softening point before exposure (Tf) is at least 100° C., preferably from 100 to 180° C., more preferably from 105 to 160° C., and still more preferably from 115 to 160° C. When the resist softening point before exposure (Tf) is within the above-mentioned range, excellent lithography properties can be achieved.

The gap between the resist softening points is required to be at least 18° C., and is preferably 20° C. or more. It is thought that the larger the difference (i.e., the gap), the more the resolution and resist pattern profile improve, especially during the process using EUV and electron beam (EB). If to specify the upper limit for the gap between the resist softening points, for example, it is preferably within a range from 20 to 100° C.

The resist softening point after exposure (Tf′) is, for example, preferably within a range from 30 to 130° C., and more preferably within a range from 70 to 120° C.

The resist softening point before exposure (Tf) and the gap between the resist softening points can be adjusted depending on the types and amounts of each components used in the positive resist composition. Among the components, it is particularly desirable that the adjustments be made, depending on the base material component (component (A)).

### <Component (A)>

As the component (A), either a single organic compound typically used as a base material component for a positive resist, or a mixture of two or more of such organic compounds, may be used.

The component (A) may be a polymeric compound component (A1) which exhibits increased solubility in an alkali developing solution under action of acid (hereafter, frequently referred to as “component (A1)”), a low molecular weight compound (A2) which exhibits increased solubility in an alkali developing solution under action of acid (hereafter, referred to as “component (A2)”), or a mixture of these components.

### [Component (A1)]

As the component (A1), either a single polymeric compound component (base resin) typically used as a base material component for a chemically amplified resist, or a mixture of two or more of such components, may be used.

In the present invention, it is preferable that the component (A1) be either a polymeric compound component (A11) (hereafter, frequently referred to as “component (A11)”) having a core portion that includes a hydrocarbon group or a heterocycle of two or more valences and also at least one arm portion that is bonded to the core portion and is represented by general formula (1) shown below; or a polymeric compound component (A12) (hereafter, frequently referred to as “component (A12)”) having a core portion that includes a polymer having a molecular weight of 500 or more and 20,000 or less and also at least one arm portion that is bonded to the core portion and is represented by general formula (1) shown below.

Further, when the component (A1) is the component (A11), it is preferable that the component (A11) include two or more of the aforementioned core portions, and also these core portions be bonded to each other via a linkage portion composed of an atom or a divalent linking group.

[Chemical Formula 1]

—(X)—Y (1)

[X represents a divalent linking group having an acid dissociable group, and Y represents a polymer chain].

### [Component (A11)]

### <<Core Portion>>

In the component (A11) of the present invention, the core portion is constituted of a hydrocarbon group or a heterocycle of two or more valences.

The hydrocarbon group may be either an aliphatic hydrocarbon group, an aromatic hydrocarbon group or a group constituted of only carbon atoms. An aliphatic hydrocarbon group refers to a hydrocarbon group that has no aromaticity.

The aliphatic hydrocarbon group may be a chain-like aliphatic hydrocarbon group, a cyclic aliphatic hydrocarbon group, or a combination of these aliphatic hydrocarbon groups. Further, the aliphatic hydrocarbon group may be either saturated or unsaturated.

As the aromatic hydrocarbon group, a hydrocarbon group having an aromatic hydrocarbon ring can be used. For example, the aromatic hydrocarbon group may be constituted solely of an aromatic hydrocarbon ring, or may be a combination of an aromatic hydrocarbon ring and the aforementioned aliphatic hydrocarbon group.

The number of carbon atoms within the hydrocarbon group is preferably within a range of from 1 to 20.

Examples of the hydrocarbon group include a group having a structure represented by the formulas shown below.

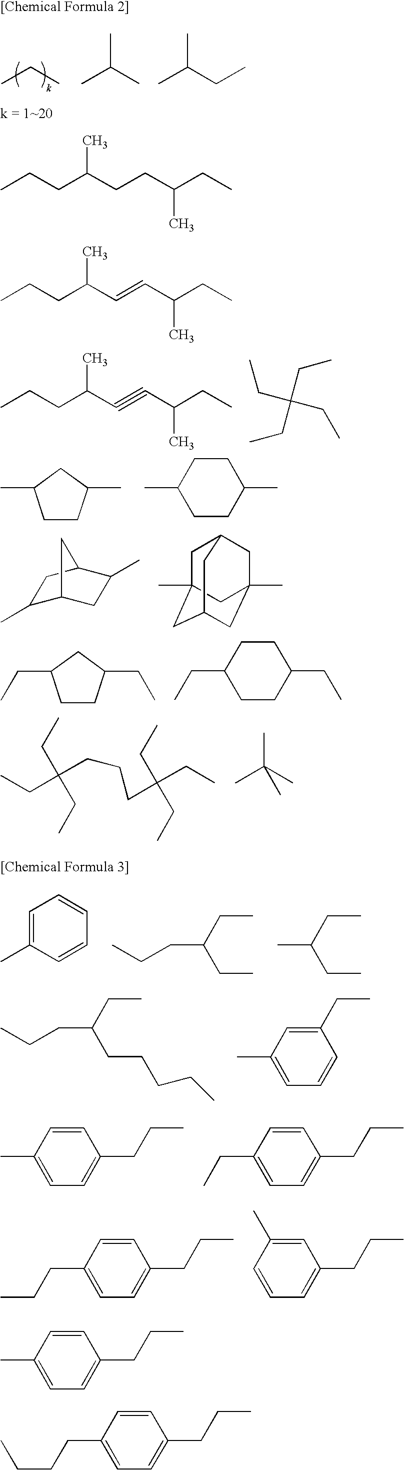

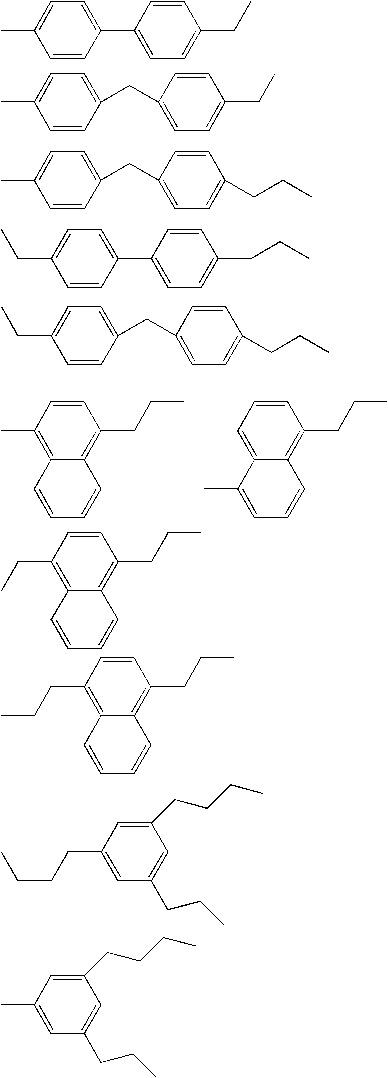

The heterocycle may be an aliphatic heterocycle containing a hetero atom within the ring structure or an aromatic heterocycle containing a hetero atom within the ring structure, and an aromatic heterocycle containing a hetero atom within the ring structure is preferable.

The heterocycle may be either monocyclic or polycyclic.

The hetero atom is an atom other than a carbon atom, and examples thereof include a nitrogen atom, a sulfur atom and an oxygen atom.

The number of carbon atoms within the heterocycle is preferably within a range of from 1 to 20.

Examples of the heterocycle include a group having a structure represented by the formulas shown below. In the formulas, the bonding position may be any one of the carbon atoms.

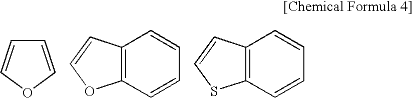

The component (A11) may include only one core portion or two or more core portions, and preferably includes two or more core portions.

When the component (A11) includes a plurality of core portions, the plurality of core portions may be the same with each other or may be different from each other, and preferably be the same with each other, as the effects of the present invention become particularly excellent.

When the component (A11) includes a plurality of core portions, the plurality of core portions are preferably bonded with each other via a linkage portion.

### <<Linkage Portion>>

The linkage portion is preferably an atom or a divalent linking group.

Examples of the atom for the linkage portion include a carbon atom, an oxygen atom and a nitrogen atom, and a carbon atom or an oxygen atom is preferable.

Preferable examples of the divalent linking group of the linkage portion include a divalent hydrocarbon group which may have a sub stituent, and a divalent linking group containing a hetero atom.

When the divalent linking group of the linkage portion is a divalent hydrocarbon group which may have a substituent, it is preferable that at least one of the core portions is constituted of a heterocycle, and it is more preferable that both of the core portions are constituted of a heterocycle.

A hydrocarbon group “has a substituent” means that part or all of the hydrogen atoms within the hydrocarbon group is substituted with groups or atoms other than hydrogen atom.

The hydrocarbon group may be either an aliphatic hydrocarbon group or an aromatic hydrocarbon group. An “aliphatic hydrocarbon group” refers to a hydrocarbon group that has no aromaticity.

The aliphatic hydrocarbon group may be saturated or unsaturated. In general, the aliphatic hydrocarbon group is preferably saturated.

As specific examples of the aliphatic hydrocarbon group, a linear or branched aliphatic hydrocarbon group, and an aliphatic hydrocarbon group containing a ring in the structure thereof can be given.

The linear or branched aliphatic hydrocarbon group preferably has 1 to 10 carbon atoms, more preferably 1 to 8 carbon atoms, still more preferably 1 to 5 carbon atoms, and most preferably 1 or 2 carbon atoms.

As the linear aliphatic hydrocarbon group, a linear alkylene group is preferable. Specific examples thereof include a methylene group [—CH₂—], an ethylene group [—(CH₂)₂—], a trimethylene group [—(CH₂)₃—], a tetramethylene group [—(CH₂)₄—], a pentamethylene group [—(CH₂)₅—], a heptamethylene group [—(CH₂)₇—], an octamethylene group [—(CH₂)₈—], a nonamethylene group [—(CH₂)₉—] and a decamethylene group [—(CH₂)₁₀—].

As a branched aliphatic hydrocarbon group, a branched alkylene group is preferable, and specific examples thereof include alkylalkylene groups, including alkylmethylene groups such as —CH(CH₃)—, —CH(CH₂CH₃)—, —C(CH₃)₂—, —C(CH₃)(CH₂CH₃)—, —C(CH₃)(CH₂CH₂CH₃)—, and —C(CH₂CH₃)₂—; alkylethylene groups such as —CH(CH₃)CH₂—, —CH(CH₃)CH(CH₃)—, —C(CH₃)₂CH₂—, —CH(CH₂CH₃)CH₂—, and —C(CH₂CH₃)₂—CH₂—; alkyltrimethylene groups such as —CH(CH₃)CH₂CH₂—, and —CH₂CH(CH₃)CH₂—; and alkyltetramethylene groups such as —CH(CH₃)CH₂CH₂CH₂—, and —CH₂CH(CH₃)CH₂CH₂—. As the alkyl group within the alkylalkylene group, a linear alkyl group of 1 to 5 carbon atoms is preferable.

The linear or branched aliphatic hydrocarbon group (chain-like aliphatic hydrocarbon group) may or may not have a substituent. Examples of such substituents include a fluorine atom, a fluorinated lower alkyl group of 1 to 5 carbon atoms which is substituted by a fluorine atom, and an oxygen atom (═O).

As examples of the aliphatic hydrocarbon group containing a ring in the structure thereof, a cyclic aliphatic hydrocarbon group (a group in which two hydrogen atoms have been removed from an aliphatic hydrocarbon ring), and a group in which the cyclic aliphatic hydrocarbon group is bonded to the terminal of the aforementioned chain-like aliphatic hydrocarbon group or interposed within the aforementioned chain-like aliphatic hydrocarbon group, can be given.

The cyclic aliphatic hydrocarbon group preferably has 3 to 20 carbon atoms, and more preferably 3 to 12 carbon atoms.

The cyclic aliphatic hydrocarbon group may be either a polycyclic group or a monocyclic group. As the monocyclic group, a group in which two hydrogen atoms have been removed from a monocycloalkane of 3 to 6 carbon atoms is preferable. Examples of the monocycloalkane include cyclopentane and cyclohexane. As the polycyclic group, a group in which two hydrogen atoms have been removed from a polycycloalkane of 7 to 12 carbon atoms is preferable. Specific examples of the polycycloalkane include adamantane, norbornane, isobornane, tricyclodecane and tetracyclododecane.

The cyclic aliphatic hydrocarbon group may or may not have a substituent. Examples of substituents include an alkyl group of 1 to 5 carbon atoms, a fluorine atom, a fluorinated alkyl group of 1 to 5 carbon atoms which is substituted by a fluorine atom, and an oxygen atom (═O).

Examples of the aromatic hydrocarbon group include a divalent aromatic hydrocarbon group in which one hydrogen atom has been removed from a benzene ring of a monovalent aromatic hydrocarbon group such as a phenyl group, a biphenyl group, a fluorenyl group, a naphthyl group, an anthryl group or a phenanthryl group;

an aromatic hydrocarbon group in which part of the carbon atoms constituting the ring of the aforementioned divalent aromatic hydrocarbon group has been substituted with a hetero atom such as an oxygen atom, a sulfur atom or a nitrogen atom; and

an aromatic hydrocarbon group in which one hydrogen atom has been removed from a benzene ring of an arylalkyl group such as a benzyl group, a phenethyl group, a 1-naphthylmethyl group, a 2-naphthylmethyl group, a 1-naphthylethyl group or a 2-naphthylethyl group.

The aromatic hydrocarbon group may or may not have a substituent. Examples of sub stituents include an alkyl group of 1 to 5 carbon atoms, a fluorine atom, a fluorinated alkyl group of 1 to 5 carbon atoms which is substituted by a fluorine atom, and an oxygen atom (═O).

With respect to a “divalent linking group containing a hetero atom”, a hetero atom is an atom other than carbon and hydrogen, and examples thereof include an oxygen atom, a nitrogen atom, a sulfur atom and a halogen atom.

Specific examples of the divalent linking group containing a hetero atom include —O—, —C(═O)—, —C(═O)—O—, a carbonate bond (—O—C(═O)—O—), —NH—, —NR⁰⁴— (in the formula, R⁰⁴ represents an alkyl group), —NH—C(═O)—, and ═N—. Further, a combination of any one of these “divalent linking groups containing a hetero atom” with a divalent hydrocarbon group can also be used. As examples of the divalent hydrocarbon group, the same groups as those described above for the hydrocarbon group which may have a substituent can be given, and a linear or branched aliphatic hydrocarbon group is preferable.

The divalent linking group may or may not have an acid dissociable portion in the structure thereof. An “acid dissociable portion” refers to a portion within the organic group which is dissociated from the organic group by action of acid generated upon exposure. When the divalent linking group has an acid dissociable portion, it is preferable that the acid dissociable portion has a tertiary carbon atom.

In the present invention, as the divalent linking group, an alkylene group, a divalent aliphatic cyclic group or a divalent linking group containing a hetero atom is preferable. Among these, an alkylene group is particularly desirable.

In those cases where the divalent linking group represents an alkylene group, the alkylene group preferably has 1 to 10 carbon atoms, more preferably 1 to 6 carbon atoms, still more preferably 1 to 4 carbon atoms, and most preferably 1 to 3 carbon atoms. Specific examples of alkylene groups include the same linear alkylene groups and branched alkylene groups as those described above.

In those cases where the divalent linking group represents a divalent aliphatic cyclic group, as the aliphatic cyclic group, the same aliphatic cyclic groups as those described above for the “aliphatic hydrocarbon group containing a ring in the structure thereof” can be used.

As the aliphatic cyclic group, a group in which two or more hydrogen atoms have been removed from cyclopentane, cyclohexane, norbornane, isobornane, adamantane, tricyclodecane or tetracyclododecane is particularly desirable.

In those cases where the divalent linking group represents a divalent linking group containing a hetero atom, preferable examples of linking groups include —O—, —C(═O)—O—, —C(═O)—, —O—C(═O)—O—, —C(═O)—NH—, —NH— (H may be replaced with a sub stituent such as an alkyl group, an acyl group or the like), —S—, —S(═O)₂—, —S(═O)₂—O—, a group represented by formula -A-O—B—, and a group represented by formula -[A-C(═O)—O]ₘ—B—. Herein, each of A and B independently represents a divalent hydrocarbon group which may have a substituent, and m represents an integer of 1 to 3.

In those cases where the divalent linking group represents —NH—, H may be replaced with a substituent such as an alkyl group, an acyl group or the like. The substituent (an alkyl group, an acyl group or the like) preferably has 1 to 10 carbon atoms, more preferably 1 to 8 carbon atoms, and most preferably 1 to 5 carbon atoms.

In the group represented by the formula -A-O—B— or -[A-C(═O)—O]ₘ—B—, each of A and B independently represents a divalent hydrocarbon group which may have a substituent.

Examples of divalent hydrocarbon groups for A and B which may have a substituent include the same groups as those described above for the “divalent hydrocarbon group which may have a substituent” usable as the divalent linking group.

As A, a linear aliphatic hydrocarbon group is preferable, more preferably a linear alkylene group, still more preferably a linear alkylene group of 1 to 5 carbon atoms, and a methylene group or an ethylene group is particularly desirable.

As B, a linear or branched aliphatic hydrocarbon group is preferable, and a methylene group, an ethylene group or an alkylmethylene group is more preferable. The alkyl group within the alkylmethylene group is preferably a linear alkyl group of 1 to 5 carbon atoms, more preferably a linear alkyl group of 1 to 3 carbon atoms, and most preferably a methyl group.

Further, in the group represented by the formula -[A-C(═O)—O]ₘ—B—, m represents an integer of 1 to 3, preferably an integer of 1 to 2, and most preferably 1.

Furthermore, the divalent linking group in the present invention may be a divalent polymer. The average degree of polymerization of the polymer between two cores is preferably no more than 50, and more preferably no more than 20.

### <<Arm Portion>>

In the component (A11) of the present invention, the arm portion is bonded to the core portion and is also represented by general formula (1) above.

### [Y: Polymer Chain]

In formula (1), Y represents a polymer chain (hereafter, referred to as “polymer chain Y”).

In a plurality of arm portions in the component (A11), the polymer chains Y may be the same with each other or may be different from each other, and preferably be the same with each other, as the effects of the present invention become particularly excellent.

The polymer chain Y preferably includes a structural unit (hereafter, referred to as “structural unit (a5)”) derived from a hydroxystyrene derivative.

Further, the polymer chain Y preferably includes a structural unit (hereafter, referred to as “structural unit (a7)”) in which at least part of the hydrogen atoms in the hydroxyl group of the structural unit derived from hydroxystyrene or the hydrogen atom in the group —C(═O)OH of the structural unit derived from vinylbenzoic acid is protected by a substituent.

The polymer chain Y may further include a structural unit (hereafter, referred to as “structural unit (a6)”) derived from styrene, and may also include other structural units (such as the structural units (a1), (a2), (a3) and (a4) to be described later) such as a structural unit having an acid dissociable, dissolution inhibiting group.

(Structural Unit (a5))

The structural unit (a5) is a structural unit derived from a hydroxystyrene derivative.

When the polymer chain Y includes the structural unit (a5), the dry etching resistance is improved. Furthermore, the structural unit (a5) is also advantageous in terms of easy availability and low cost of hydroxystyrene used as a source material.

Preferable examples of the structural unit (a5) include structural units represented by general formula (a5-1) shown below.

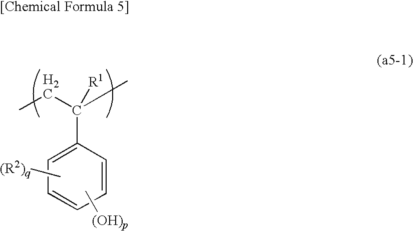

[In formula (a5-1), R¹ represents a hydrogen atom, an alkyl group of 1 to 5 carbon atoms or a halogenated alkyl group of 1 to 5 carbon atoms; R² represents a halogen atom, an alkyl group of 1 to 5 carbon atoms or a halogenated alkyl group of 1 to 5 carbon atoms; p represents an integer of 1 to 3; and q represents an integer of 0 to 4; with the proviso that p+q is 1 to 5.]

In general formula (a5-1) above, specific examples of the alkyl group of 1 to 5 carbon atoms for R¹ include linear or branched alkyl groups such as a methyl group, an ethyl group, a propyl group, an isopropyl group, a n-butyl group, an isobutyl group, a tert-butyl group, a pentyl group, an isopentyl group and a neopentyl group. Of these, a methyl group is particularly desirable.

The halogenated alkyl group of 1 to 5 carbon atoms for R¹ is a group in which part or all of the hydrogen atoms within the aforementioned alkyl group of 1 to 5 carbon atoms has been substituted with a halogen atom (such as a fluorine atom, a chlorine atom, a bromine atom or an iodine atom). Of these, a fluorinated alkyl group of 1 to 5 carbon atoms is preferable, and a group in which all of the hydrogen atoms has been substituted with a fluorine atom is particularly desirable. Specific examples of the fluorinated alkyl group of 1 to 5 carbon atoms include a trifluoromethyl group, a hexafluoroethyl group, a heptafluoropropyl group and a nonafluorobutyl group.

As R¹, a hydrogen atom or an alkyl group of 1 to 5 carbon atoms is preferable, and a hydrogen atom or a methyl group is particularly desirable.

p represents an integer of 1 to 3, and preferably 1.

The bonding position of the hydroxyl group may be any of the o-position, m-position and p-position of the phenyl group. When p is 1, the p-position is preferable in terms of availability and low cost. When p is 2 or 3, a desired combination of the bonding positions can be used.

q is an integer of 0 to 4, preferably 0 or 1, and most preferably 0 from an industrial viewpoint.

As the alkyl group of 1 to 5 carbon atoms for R², the same alkyl groups of 1 to 5 carbon atoms as those described above for R¹ can be used.

As examples of the halogen atom for R², a fluorine atom, a chlorine atom, a bromine atom and an iodine atom can be given. Among these, a fluorine atom is preferable.

The halogenated alkyl group of 1 to 5 carbon atoms for R² is a group in which at least one hydrogen atoms of the alkyl group of 1 to 5 carbon atoms for R² are substituted with halogen atoms. Examples of the halogen atom include the same halogen atoms as those described above.

When q is 1, the substitution position of R² may be any of the o-position, the m-position and the p-position.

When q is 2, a desired combination of the substitution positions can be used.

However, 1≦p+q≦5.

As the structural unit (a5), one type of structural unit may be used alone, or two or more types of structural units may be used in combination.

The amount of the structural unit (a5) based on the combined total of all structural units constituting the polymer chain Y is preferably 50 to 90 mol %, more preferably 55 to 90 mol %, and still more preferably 60 to 90 mol %. By making the amount of the structural unit (a5) at least as large as the lower limit of the above-mentioned range, an adequate level of alkali solubility can be achieved. On the other hand, when the amount of the structural unit (a5) is no more than the upper limit of the above-mentioned range, a good balance can be achieved with the other structural units.

(Structural Unit (a6))

The structural unit (a6) is a structural unit derived from styrene.

In the present invention, the structural unit (a6) is not essential. However, inclusion of the structural unit (a6) makes it possible to adjust the solubility in an alkali developing solution. Further, inclusion of the structural unit (a6) is preferable since the dry etching resistance is improved.

Preferable examples of the structural unit (a6) include structural units represented by general formula (a6-1) shown below.

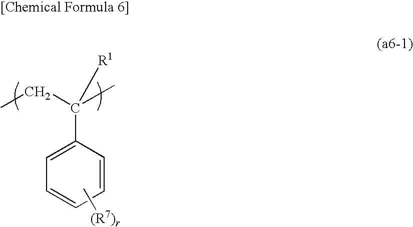

[In formula (a6-1), R¹ is the same as defined above; R⁷ represents a halogen atom, an alkyl group of 1 to 5 carbon atoms or a halogenated alkyl group of 1 to 5 carbon atoms; and r represents an integer of 0 to 3.]

In general formula (a6-1) above, R¹ is the same as defined for R¹ in formula (a5-1) above.

As R⁷, the same groups as those described above for R² defined in formula (a5-1) can be mentioned.

r represents an integer of 0 to 3, preferably 0 or 1, and most preferably 0 from an industrial viewpoint.

When r is 1, the substitution position of R⁷ may be any of the o-position, m-position and p-position of the phenyl group.

When r is 2 or 3, a desired combination of the substitution positions can be used. The plurality of R⁷ may be the same or different from each other.

As the structural unit (a6), one type of structural unit may be used alone, or two or more types of structural units may be used in combination.

When the polymer chain Y includes the structural unit (a6), the proportion of the structural unit (a6) based on the combined total of all structural units constituting the polymer chain Y is preferably 1 to 20 mol %, more preferably 3 to 15 mol %, and still more preferably 5 to 15 mol %. Making this proportion at least as large as the lower limit of the above-mentioned range ensures that the effects obtained by including the structural unit (a6) are achieved, whereas by making the proportion no more than the upper limit of the above-mentioned range, a good balance can be achieved with the other structural units.

(Structural Unit (a7))

The structural unit (a7) is a structural unit in which at least part of the hydrogen atoms in the hydroxyl group of the structural unit derived from hydroxystyrene or the hydrogen atom in the group —C(═O)OH of the structural unit derived from vinylbenzoic acid is protected by a sub stituent.

In the structural unit (a7), examples of the substituent include a tertiary alkyl group-containing group, an alkoxyalkyl group, an acid dissociable, dissolution inhibiting group, and an organic group containing an acid dissociable, dissolution inhibiting group.

### Tertiary Alkyl Group-Containing Group

In the present description, the term “tertiary alkyl group” refers to an alkyl group having a tertiary carbon atom. As mentioned above, the term “alkyl group” refers to a monovalent saturated hydrocarbon group, and includes chain-like (linear or branched) alkyl groups and cyclic alkyl groups.

The term “tertiary alkyl group-containing group” refers to a group which includes a tertiary alkyl group in the structure thereof. The tertiary alkyl group-containing group may be either constituted of only a tertiary alkyl group, or constituted of a tertiary alkyl group and an atom or group other than a tertiary alkyl group.

Examples of the “atom or group other than a tertiary alkyl group” which constitutes the tertiary alkyl group-containing group with a tertiary alkyl group include a carbonyloxy group, a carbonyl group, an alkylene group and an oxygen atom.

In the structural unit (a7), as the tertiary alkyl group-containing group, a tertiary alkyl group-containing group which does not have a ring structure, and a tertiary alkyl group-containing group which has a ring structure can be mentioned.

A tertiary alkyl group-containing group which does not have a ring structure is a group which has a branched tertiary alkyl group as the tertiary alkyl group, and has no ring structure in the structure thereof.

As the branched tertiary alkyl group, for example, a group represented by general formula (I) shown below may be mentioned.

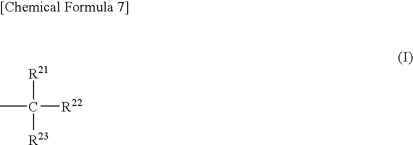

In formula (I), each of R²¹ to R²³ independently represents a linear or branched alkyl group. The number of carbon atoms within the alkyl group is preferably from 1 to 5, and more preferably from 1 to 3.

Further, in the group represented by general formula (I), the total number of carbon atoms is preferably from 4 to 7, more preferably from 4 to 6, and most preferably 4 or 5.

Preferable examples of groups represented by general formula (I) include a tert-butyl group and a tert-pentyl group, and a tert-butyl group is more preferable.

Examples of tertiary alkyl group-containing groups which do not have a ring structure include the aforementioned branched tertiary alkyl group; a tertiary alkyl group-containing, chain-like alkyl group in which the aforementioned branched tertiary alkyl group is bonded to a linear or branched alkylene group; a tertiary alkyloxycarbonyl group which has the aforementioned branched tertiary alkyl group as the tertiary alkyl group; and a tertiary alkyloxycarbonylalkyl group which has the aforementioned branched tertiary alkyl group as the tertiary alkyl group.

As the alkylene group within the tertiary alkyl group-containing, chain-like alkyl group, an alkylene group of 1 to 5 carbon atoms is preferable, an alkylene group of 1 to 4 carbon atoms is more preferable, and an alkylene group of 1 or 2 carbon atoms is the most desirable.

As a chain-like tertiary alkyloxycarbonyl group, for example, a group represented by general formula (II) shown below can be mentioned. In general formula (II), R²¹ to R²³ are the same as defined for R²¹ to R²³ in general formula (I) above. As the chain-like tertiary alkyloxycarbonyl group, a tert-butyloxycarbonyl group (t-boc) and a tert-pentyloxycarbonyl group are preferable.

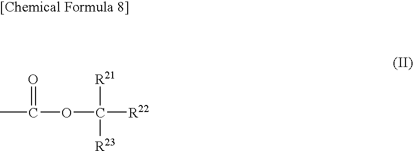

As a chain-like tertiary alkyloxycarbonylalkyl group, for example, a group represented by general formula (III) shown below can be mentioned. In general formula (III), R²¹ to R²³ are the same as defined for R²¹ to R²³ in general formula (I) above. f represents an integer of 1 to 3, and is preferably 1 or 2. As the chain-like tertiary alkyloxycarbonylalkyl group, a tert-butyloxycarbonylmethyl group and a tert-butyloxycarbonylethyl group are preferable.

Among these, as the tertiary alkyl group-containing group which does not have a ring structure, a tertiary alkyloxycarbonyl group or a tertiary alkyloxycarbonylalkyl group is preferable, a tertiary alkyloxycarbonyl group is more preferable, and a tert-butyloxycarbonyl group (t-boc) is the most preferable.

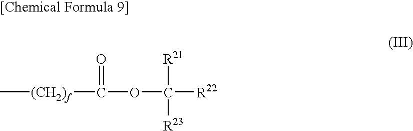

A tertiary alkyl group-containing group which has a ring structure is a group which contains a tertiary carbon atom and a ring structure in the structure thereof.

In the tertiary alkyl group-containing group which has a ring structure, the ring structure preferably has 4 to 12 carbon atoms constituting the ring, more preferably 5 to 10 carbon atoms, and most preferably 6 to 10 carbon atoms. As the ring structure, for example, groups in which one or more hydrogen atoms have been removed from a monocycloalkane or a polycycloalkane such as a bicycloalkane, tricycloalkane or tetracycloalkane may be used. Preferable examples include groups in which one or more hydrogen atoms have been removed from a monocycloalkane such as cyclopentane and cyclohexane; and groups in which one or more hydrogen atoms have been removed from a polycycloalkane such as adamantane, norbornane, isobornane, tricyclodecane or tetracyclododecane.

As the tertiary alkyl group-containing group which has a ring structure, for example, a group having the following group (1) or (2) as the tertiary alkyl group can be used.

(1) A group in which a linear or branched alkyl group is bonded to a carbon atom which constitutes the ring of a cyclic alkyl group (cycloalkyl group), so that the carbon atom becomes a tertiary carbon atom.

(2) A group in which an alkylene group (branched alkylene group) having a tertiary carbon atom is bonded to a carbon atom constituting the ring of a cycloalkyl group.

In the aforementioned group (1), the linear or branched alkyl group preferably has 1 to 5 carbon atoms, more preferably 1 to 4 carbon atoms, and most preferably 1 to 3 carbon atoms.

Examples of the group (1) include a 2-methyl-2-adamantyl group, a 2-ethyl-2-adamantyl group, a 1-methyl-1-cycloalkyl group and a 1-ethyl-1-cycloalkyl group.

In other words, when represented by a general formula, as the tertiary alkyl group-containing group which has a ring structure according to the aforementioned group (1), those represented by formula (p0) shown below are preferable, those represented by formula (p0-1) shown below are more preferable, and those represented by formula (p0-1-1) shown below are still more preferable.

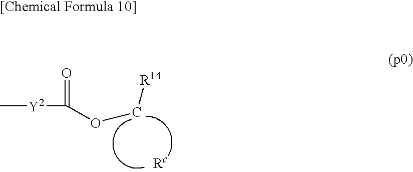

[In the formula, Y² represents either a single bond or the same divalent linking group as defined above as the divalent linking group of the linkage portion connecting a plurality of core portions; R¹⁴ represents an alkyl group of 1 to 5 carbon atoms; and R^{c} represents a group which forms an aliphatic cyclic group with the carbon atoms to which R^{c} is bonded.]

Examples of R^{c} include the same aliphatic cyclic groups as those described above, a polycyclic aliphatic cyclic group is preferable.

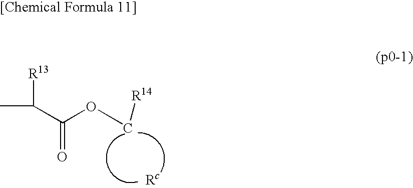

[In the formula, R¹³ represents a hydrogen atom or a methyl group; R¹⁴ represents an alkyl group of 1 to 5 carbon atoms; and R^{c} represents a group which forms an aliphatic cyclic group with the carbon atoms to which R^{c} is bonded.]

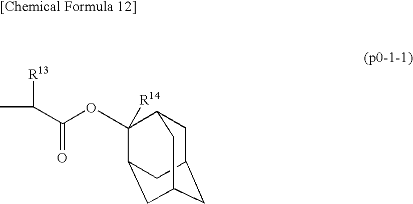

[In the formula, R¹³ represents a hydrogen atom or a methyl group; and R¹⁴ represents an alkyl group of 1 to 5 carbon atoms.]

In the aforementioned group (2), the cycloalkyl group having a branched alkylene group bonded thereto may have a substituent. Examples of such substituents include a fluorine atom, a fluorinated lower alkyl group of 1 to 5 carbon atoms which is substituted by a fluorine atom, and an oxygen atom (═O).

As an example of the group (2), a group represented by chemical formula (IV) shown below may be given.

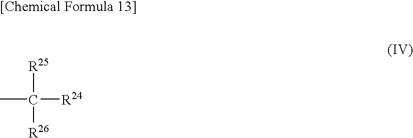

In formula (IV), R²⁴ represents a cycloalkyl group which may or may not have a substituent. Examples of the substituent which the cycloalkyl group may have include a fluorine atom, a fluorinated alkyl group of 1 to 5 carbon atoms which is substituted by a fluorine atom, and an oxygen atom (═O).

Each of R²⁵ and R²⁶ independently represents a linear or branched alkyl group.

As the alkyl group, the same alkyl groups as those for R²¹ to R²³ in general formula (I) above may be used.

### Alkoxyalkyl Group

As an example of the alkoxyalkyl group in the structural unit (a7), a group represented by general formula (V) shown below may be given.

[Chemical Formula 14]

—R⁵²—O—R⁵¹ (V)

In formula (V), R⁵¹ represents a linear, branched or cyclic alkyl group.

When R⁵¹ represents a linear or branched alkyl group, it is preferably an alkyl group of 1 to 5 carbon atoms, more preferably an ethyl group or a methyl group, and an ethyl group is particularly desirable.

When R⁵¹ represents a cyclic alkyl group, it preferably has 4 to 15 carbon atoms, more preferably 4 to 12 carbon atoms, and most preferably 5 to 10 carbon atoms. As examples of the cyclic alkyl group, groups in which one or more hydrogen atoms have been removed from a monocycloalkane or a polycycloalkane such as a bicycloalkane, tricycloalkane or tetracycloalkane, and which may or may not be substituted with a fluorine atom or a fluorinated alkyl group, may be given. Specific examples include groups in which one or more hydrogen atoms have been removed from a monocycloalkane such as cyclopentane and cyclohexane; and groups in which one or more hydrogen atoms have been removed from a polycycloalkane such as adamantane, norbornane, isobornane, tricyclodecane or tetracyclododecane. Of these, a group in which one or more hydrogen atoms have been removed from adamantane is preferable.

R⁵² represents a linear or branched alkylene group. The alkylene group preferably has 1 to 5 carbon atoms, more preferably 1 to 3 carbon atoms, and most preferably 1 or 2 carbon atoms.

Of the various possibilities described above, as the alkoxyalkyl group, a group represented by general formula (VI) shown below is particularly desirable.

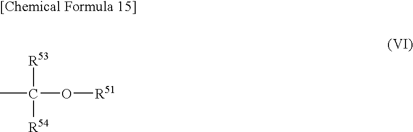

In general formula (VI), R⁵¹ is the same as defined above, and each of R⁵³ and R⁵⁴ independently represents a linear or branched alkyl group or a hydrogen atom.

With respect to R⁵³ and R⁵⁴, the alkyl group preferably has 1 to 15 carbon atoms, and may be either linear or branched. The alkyl group for R⁵³ and R⁵⁴ is preferably an ethyl group or a methyl group, and is most preferably a methyl group.

It is particularly desirable that either one of R⁵³ and R⁵⁴ be a hydrogen atom, and the other be a methyl group.

### Acid Dissociable, Dissolution Inhibiting Group

In the structural unit (a7), the acid dissociable, dissolution inhibiting group is not particularly limited, and can be selected appropriately from the multitude of groups that have been proposed for the resins of resist compositions designed for use with KrF excimer lasers, ArF excimer lasers, and the like. Specific examples thereof include the acid dissociable, dissolution inhibiting groups (VII) shown below.

Examples of the acid dissociable, dissolution inhibiting groups (VII) include a group represented by general formula (VII-a) shown below and a group represented by general formula (VII-b) shown below.

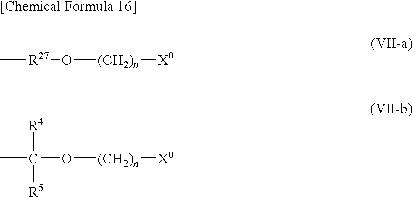

[In formula (VII-a), R²⁷ represents a linear or branched alkylene group; X⁰ represents an aliphatic cyclic group, an aromatic cyclic hydrocarbon group or an alkyl group of 1 to 5 carbon atoms; and n represents an integer of 0 to 3. In formula (VII-b), X⁰ is the same as X⁰ defined in the above formula (VII-a), and R⁴ represents a hydrogen atom or an alkyl group of 1 to 5 carbon atoms; or each of X⁰ and R⁴ may independently represent an alkylene group of 1 to 5 carbon atoms, and X⁰ may be bonded to R⁴; R⁵ represents a hydrogen atom or an alkyl group of 1 to 5 carbon atoms; and n represents an integer of 0 to 3.]

In general formula (VII-a) above, R²⁷ represents a linear or branched alkylene group.

The alkylene group preferably has 1 to 5 carbon atoms, more preferably 1 to 3 carbon atoms, and most preferably 1 or 2 carbon atoms.

In general formulas (VII-a) and (VII-b) above, n represents an integer of 0 to 3, preferably an integer of 0 to 2, more preferably 0 or 1, and most preferably 0.

In general formulas (VII-a) and (VII-b) above, each X⁰ independently represents an aliphatic cyclic group, an aromatic cyclic hydrocarbon group or an alkyl group of 1 to 5 carbon atoms.

The aliphatic cyclic group for X⁰ is a monovalent aliphatic cyclic group. The aliphatic cyclic group can be selected appropriately, for example, from the multitude of groups that have been proposed for conventional ArF resists. Specific examples of the aliphatic cyclic group include an aliphatic monocyclic group of 5 to 7 carbon atoms and an aliphatic polycyclic group of 10 to 16 carbon atoms.

The aliphatic cyclic group may or may not have a substituent. Examples of sub stituents include an alkyl group of 1 to 5 carbon atoms, an alkoxy group of 1 to 5 carbon atoms, a fluorine atom, a fluorinated alkyl group of 1 to 5 carbon atoms which is substituted by a fluorine atom, and an oxygen atom (═O).

The basic ring of the aliphatic cyclic group exclusive of sub stituents is not limited to be constituted from only carbon and hydrogen (not limited to hydrocarbon groups), and may include an oxygen atom or the like in the ring structure.

As the aliphatic monocyclic group of 5 to 7 carbon atoms, a group in which one hydrogen atom has been removed from a monocycloalkane can be mentioned, and specific examples include a group in which one hydrogen atom has been removed from cyclopentane, cyclohexane or the like.

Examples of the aliphatic polycyclic group of 10 to 16 carbon atoms include groups in which one hydrogen atom has been removed from a bicycloalkane, tricycloalkane, tetracycloalkane or the like. Specific examples include groups in which one hydrogen atom has been removed from a polycycloalkane such as adamantane, norbornane, isobornane, tricyclodecane or tetracyclododecane. Of these, an adamantyl group, a norbornyl group and a tetracyclododecyl group is preferred industrially, and an adamantyl group is particularly desirable.

As the aromatic cyclic hydrocarbon group for X⁰, aromatic polycyclic groups of 10 to 16 carbon atoms can be mentioned. Examples of such aromatic polycyclic groups include groups in which one hydrogen atom has been removed from naphthalene, anthracene, phenanthrene or pyrene. Specific examples include a 1-naphthyl group, a 2-naphthyl group, a 1-anthryl group, a 2-anthryl group, a 1-phenanthryl group, a 2-phenanthryl group, a 3-phenanthryl group and a 1-pyrenyl group, and a 2-naphthyl group is particularly preferred industrially.

As the alkyl group of 1 to 5 carbon atoms for X⁰, the same as the above-mentioned alkyl groups of 1 to 5 carbon atoms for R¹ can be used, and a methyl group or an ethyl group is more preferable, and an ethyl group is most preferable.

In general formula (VII-b) above, as the alkyl group of 1 to 5 carbon atoms for R⁴, the same as the above-mentioned alkyl groups of 1 to 5 carbon atoms for X⁰ can be used. From an industrial perspective, a methyl group or an ethyl group is preferable, and a methyl group is particularly desirable.

R⁵ represents an alkyl group of 1 to 5 carbon atoms, or a hydrogen atom. As the alkyl group of 1 to 5 carbon atoms for R⁵, the same alkyl groups of 1 to 5 carbon atoms as those described above for R⁴ can be used. From an industrial perspective, R⁵ is preferably a hydrogen atom.

It is particularly desirable that either one of R⁴ and R⁵ be a hydrogen atom, and the other be a methyl group.

Further, in general formula (VII-b) above, each of X⁰ and R⁴ may independently represent an alkylene group of 1 to 5 carbon atoms, and X⁰ may be bonded to R⁴.

In such a case, in general formula (VII-b) above, a cyclic group is formed by R⁴, X⁰, the oxygen atom having X⁰ bonded thereto, and the carbon atom having the oxygen atom and R⁴ bonded thereto.

Such a cyclic group is preferably a 4 to 7-membered ring, and more preferably a 4 to 6-membered ring. Specific examples of the cyclic group include a tetrahydropyranyl group and a tetrahydrofuranyl group.

In terms of achieving an excellent resist pattern profile or the like, as the acid dissociable, dissolution inhibiting group (VII), it is preferable that R⁵ be a hydrogen atom, and R⁴ be a hydrogen atom or an alkyl group of 1 to 5 carbon atoms.

Specific examples of the acid dissociable, dissolution inhibiting group (VII) include groups in which X⁰ represents an alkyl group of 1 to 5 carbon atoms, i.e., 1-alkoxyalkyl groups such as a 1-methoxyethyl group, a 1-ethoxyethyl group, a 1-isopropoxyethyl group, a 1-n-butoxyethyl group, a 1-tert-butoxyethyl group, a methoxymethyl group, an ethoxymethyl group, an isopropoxymethyl group, an n-butoxymethyl group and a tert-butoxymethyl group.

Further, examples of groups in which X⁰ represents an aliphatic cyclic group include those represented by formulas (11) to (24) shown below.

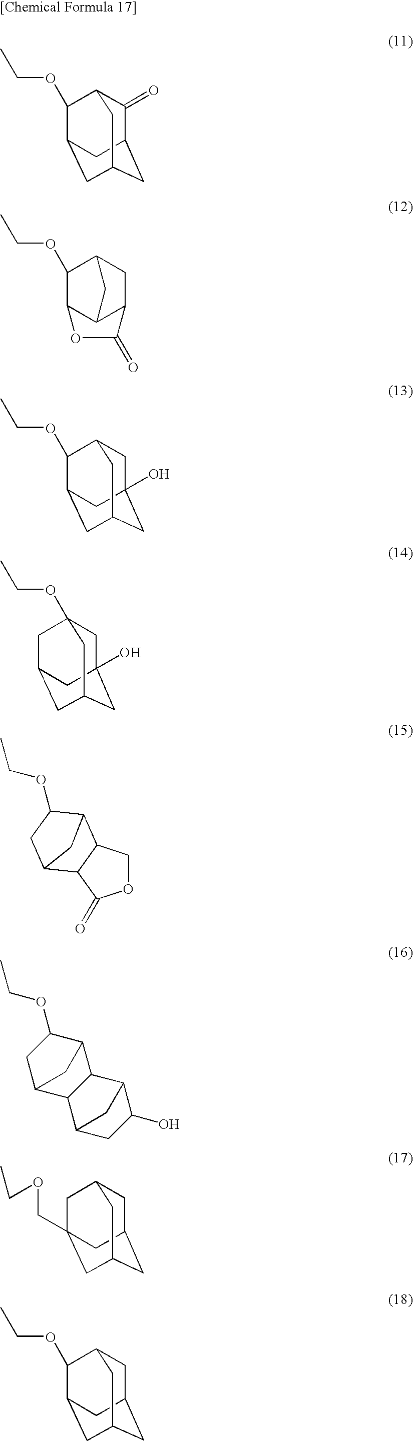

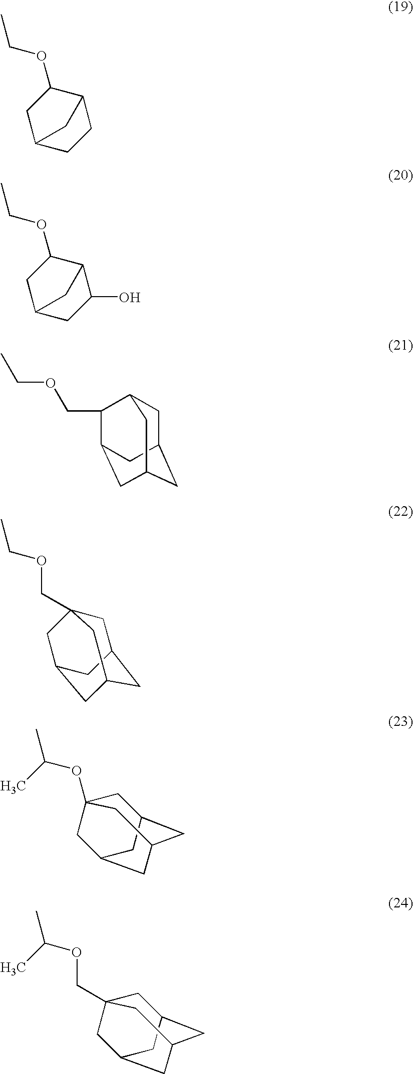

### Organic Group Containing an Acid Dissociable, Dissolution Inhibiting Group

In the present description, an “organic group containing an acid dissociable, dissolution inhibiting group” refers to a group constituted of an acid dissociable, dissolution inhibiting group and a group or atom that is not dissociated by acid (i.e., a group or atom that is not dissociated by acid, and remains bonded to the component (A) after the acid dissociable, dissolution inhibiting group has been dissociated).

The organic group containing an acid dissociable, dissolution inhibiting group is not particularly limited, and can be selected appropriately from the multitude of groups that have been proposed for the resins of resist compositions designed for use with KrF excimer lasers, ArF excimer lasers, and the like. Specific examples include those described above for the aforementioned “organic group containing an acid dissociable, dissolution inhibiting group”, such as an organic group containing an acid dissociable, dissolution inhibiting group (VII), i.e., an organic group (VIII) containing an acid dissociable, dissolution inhibiting group.

As an example of the organic group (VIII) containing an acid dissociable, dissolution inhibiting group, a group represented by general formula (VIII) shown below may be given.

In an organic group (VIII) having such a structure, when acid is generated from the component (B) upon exposure, the bond between the oxygen atom having Q bonded thereto and the carbon atom having R⁴ and R⁵ bonded thereto is cleaved by the generated acid, and the —C(R⁴)(R⁵)—OX⁰ group is dissociated.

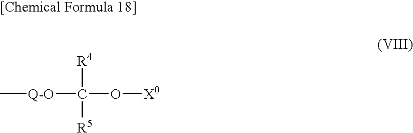

[In formula (VIII), X⁰ represents an aliphatic cyclic group, an aromatic cyclic hydrocarbon group or an alkyl group of 1 to 5 carbon atoms; and R⁴ represents a hydrogen atom or an alkyl group of 1 to 5 carbon atoms; or each of X⁰ and R⁴ may independently represent an alkylene group of 1 to 5 carbon atoms, and X⁰ may be bonded to R⁴; R⁵ represents an alkyl group of 1 to 5 carbon atoms or a hydrogen atom; and Q represents a divalent aliphatic cyclic group.]

In general formula (VIII) above, X⁰, R⁴ and R⁵ are the same groups as those described for X⁰, R⁴ and R⁵ in general formula (VII-b) above, respectively.

Examples of the divalent aliphatic cyclic group for Q include groups in which one hydrogen atom has been removed from the aliphatic cyclic group for X⁰ described above.

Among the examples shown above, the hydrogen atom in the hydroxyl group of the structural unit (a7) is preferably protected by being substituted with a tertiary alkyl group-containing group, and more preferably protected by being substituted with a group represented by general formula (II) or (p0) above.

Preferable examples of the structural unit (a7) include a structural unit represented by general formula (a7-1) shown below, a structural unit represented by general formula (a7-2) shown below, a structural unit represented by general formula (a7-3) shown below, and a structural unit represented by general formula (a7-4) shown below.

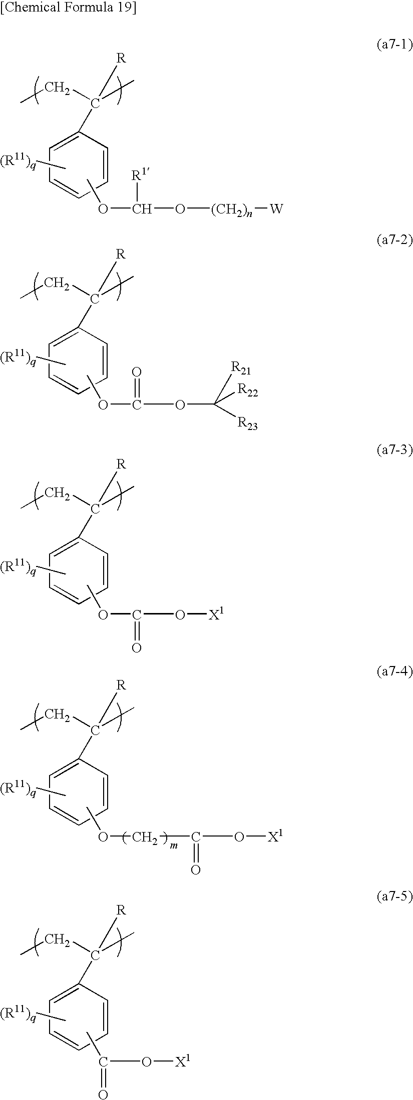

[In formulas (a7-1) to (a7-5), R¹ is the same as R¹ defined in the above formula (a5-1); R¹¹ is the same as R² defined in the above formula (a5-1); q is the same as q defined in the above formula (a5-1); R¹ ′ is the same as R⁴ defined above; n is the same as defined above; W is the same as X⁰ defined above; m is 1 to 3;each of R²¹, R²² and R²³ is the same as R²¹ to R²³ in the above general formula (I); and X¹ represents an acid dissociable, dissolution inhibiting group.]

In formulas (a7-1) to (a7-5) above, the bonding position of the groups “—O—CHR¹′—O—(CH₂)ₙ—W”, “—O—C(O)—O—C(R²¹)(R²²)(R²³)”, —O—C(O)—O—X¹”, “—O—(CH₂)ₘ—C(O)—O—X¹” and “—C(O)—O—X¹” at the phenyl group may be any one of the o-position, the m-position, or the p-position of the phenyl group, and the p-position is most desirable, as the effects of the present invention become excellent.

R²¹ to R²³ are preferably an alkyl group of 1 to 5 carbon atoms, more preferably an alkyl group of 1 to 3 carbon atoms, and specific examples thereof include the same alkyl groups of 1 to 5 carbon atoms as those described above for R¹.

Examples of X¹ include the same groups as those described above in relation to the tertiary alkyl group containing group and alkoxyalkyl group.

m is preferably 1 or 2, and more preferably 1.

Of the various possibilities described above, the structural unit (a7) is particularly preferably the structural unit represented by the above-mentioned general formula (a7-1) or (a7-4).

Specific examples of preferable structures for the structural unit (a7) are shown below.

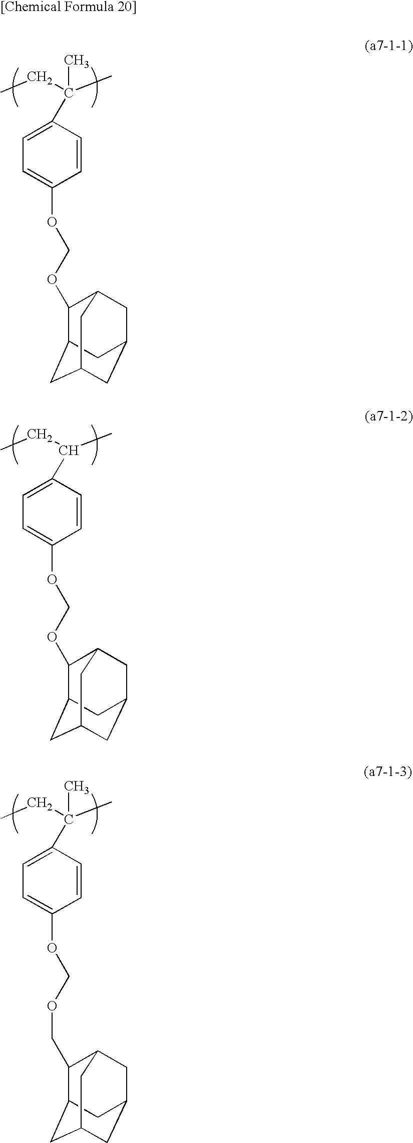

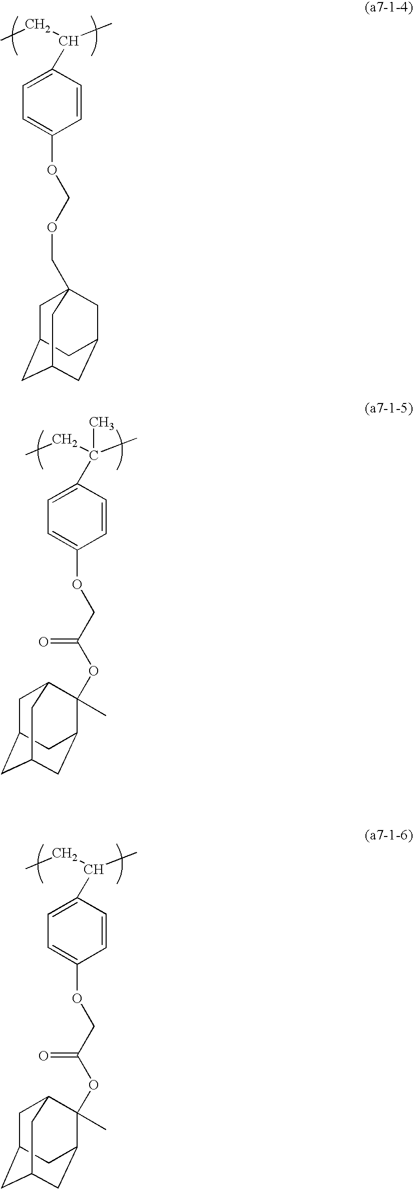

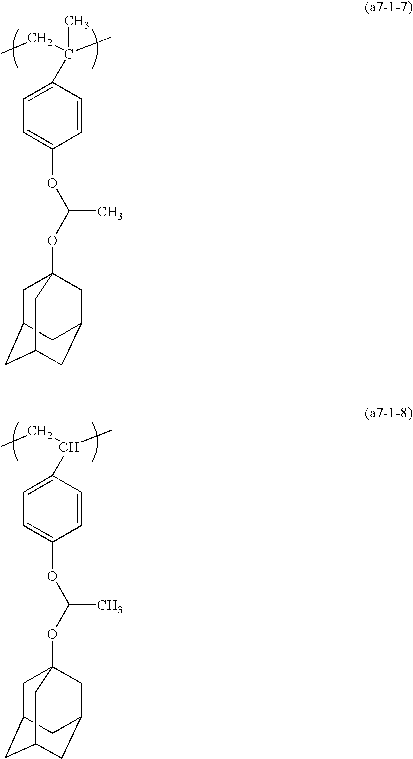

As the structural unit (a7), among the examples shown above, at least one structural unit selected from those represented by chemical formulas (a7-1-1) to (a7-1-8) is preferable, and those represented by chemical formulas (a7-1-1) to (a7-1-2) and (a7-1-5) to (a7-1-8) are most preferable, as the effects of the present invention become excellent.

As the structural unit (a7), one type of structural unit may be used alone, or two or more types of structural units may be used in combination.

When the polymer chain Y contains the structural unit (a7), the amount of the structural unit (a7) based on the combined total of all structural units constituting the polymer chain Y is preferably 1 to 40 mol %, more preferably 5 to 40 mol %, and still more preferably 10 to 40 mol %. When the amount of the structural unit (a7) is at least as large as the lower limit of the above-mentioned range, the solubility of the polymer chain Y in an organic solvent is improved. On the other hand, when the amount of the structural unit (a7) is no more than the upper limit of the above-mentioned range, a good balance can be achieved with the other structural units.

(Structural unit (a1))

The structural unit (a1) is a structural unit derived from an acrylate ester containing an acid dissociable, dissolution inhibiting group. When the structural unit (a7) does not have an acid dissociable, dissolution inhibiting group, the structural unit (a1) is an indispensable component.

As the acid dissociable, dissolution inhibiting group in the structural unit (a1), any of the groups that have been proposed as acid dissociable, dissolution inhibiting groups for the base resins of chemically amplified resists can be used, provided the group has an alkali dissolution-inhibiting effect that renders the entire polymer chain Y insoluble in an alkali developing solution prior to dissociation, and then following dissociation by action of acid, increases the solubility of the entire polymer chain Y in the alkali developing solution. Generally, groups that form either a cyclic or chain-like tertiary alkyl ester with the carboxyl group of the (meth)acrylic acid, and acetal-type acid dissociable, dissolution inhibiting groups such as alkoxyalkyl groups are widely known.

Here, a tertiary alkyl ester describes a structure in which an ester is formed by substituting the hydrogen atom of a carboxyl group with a chain-like or cyclic tertiary alkyl group, and a tertiary carbon atom within the chain-like or cyclic tertiary alkyl group is bonded to the oxygen atom at the terminal of the carbonyloxy group (—C(O)—O—). In this tertiary alkyl ester, in general, the action of acid causes cleavage of the bond between the oxygen atom and the tertiary carbon atom.

The chain-like or cyclic alkyl group may have a substituent.

Hereafter, for the sake of simplicity, groups that exhibit acid dissociability as a result of the formation of a tertiary alkyl ester with a carboxyl group are referred to as “tertiary alkyl ester-type acid dissociable, dissolution inhibiting groups”.

Examples of tertiary alkyl ester-type acid dissociable, dissolution inhibiting groups include aliphatic branched, acid dissociable, dissolution inhibiting groups and aliphatic cyclic group-containing acid dissociable, dissolution inhibiting groups.

In the present description and claims, the term “aliphatic branched” refers to a branched structure having no aromaticity.

The “aliphatic branched, acid dissociable, dissolution inhibiting group” is not limited to be constituted of only carbon atoms and hydrogen atoms (not limited to hydrocarbon groups), but is preferably a hydrocarbon group.

Further, the “hydrocarbon group” may be either saturated or unsaturated, but is preferably saturated.

As an example of the aliphatic branched, acid dissociable, dissolution inhibiting group, for example, a group represented by the formula —C(R⁷¹)(R⁷²)(R⁷³) can be mentioned. In the formula, each of R⁷¹ to R⁷³ each independently represents a linear alkyl group of 1 to 5 carbon atoms. The group represented by the formula —C(R⁷¹)(R⁷²)(R⁷³) preferably has 4 to 8 carbon atoms, and specific examples include a tert-butyl group, a 2-methyl-2-butyl group, a 2-methyl-2-pentyl group and a 3-methyl-3-pentyl group. Among these, a tert-butyl group is particularly desirable.

The term “aliphatic cyclic group” refers to a monocyclic group or polycyclic group that has no aromaticity.

The “aliphatic cyclic group” within the structural unit (a1) may or may not have a substituent. Examples of sub stituents include an alkyl group of 1 to 5 carbon atoms, an alkoxy group of 1 to 5 carbon atoms, a fluorine atom, a fluorinated alkyl group of 1 to 5 carbon atoms which is substituted by a fluorine atom, and an oxygen atom (═O).

The basic ring of the “aliphatic cyclic group” exclusive of substituents is not limited to be constituted from only carbon and hydrogen (not limited to hydrocarbon groups), but is preferably a hydrocarbon group. Further, the “hydrocarbon group” may be either saturated or unsaturated, but is preferably saturated. Furthermore, the “aliphatic cyclic group” is preferably a polycyclic group.

As such aliphatic cyclic groups, for example, groups in which one or more hydrogen atoms have been removed from a monocycloalkane or a polycycloalkane such as a bicycloalkane, tricycloalkane or tetracycloalkane which may or may not be substituted with an alkyl group of 1 to 5 carbon atoms, a fluorine atom or a fluorinated alkyl group, may be used. Specific examples include groups in which one or more hydrogen atoms have been removed from a monocycloalkane such as cyclopentane or cyclohexane; and groups in which one or more hydrogen atoms have been removed from a polycycloalkane such as adamantane, norbornane, isobornane, tricyclodecane or tetracyclododecane. Further, these groups in which one or more hydrogen atoms have been removed from a monocycloalkane and groups in which one or more hydrogen atoms have been removed from a polycycloalkane may have part of the carbon atoms constituting the ring replaced with an ethereal oxygen atom (—O—).

Examples of aliphatic cyclic group-containing acid dissociable, dissolution inhibiting groups include

(i) a group which has a tertiary carbon atom on the ring structure of a monovalent aliphatic cyclic group; and

(ii) a group which has a branched alkylene group containing a tertiary carbon atom, and a monovalent aliphatic cyclic group to which the tertiary carbon atom is bonded.

Specific examples of (i) a group which has a tertiary carbon atom on the ring structure of a monovalent aliphatic cyclic group include groups represented by general formulas (1-1) to (1-9) shown below.

Specific examples of (ii) a group which has a branched alkylene group containing a tertiary carbon atom, and a monovalent aliphatic cyclic group to which the tertiary carbon atom is bonded include groups represented by general formulas (2-1) to (2-6) shown below.

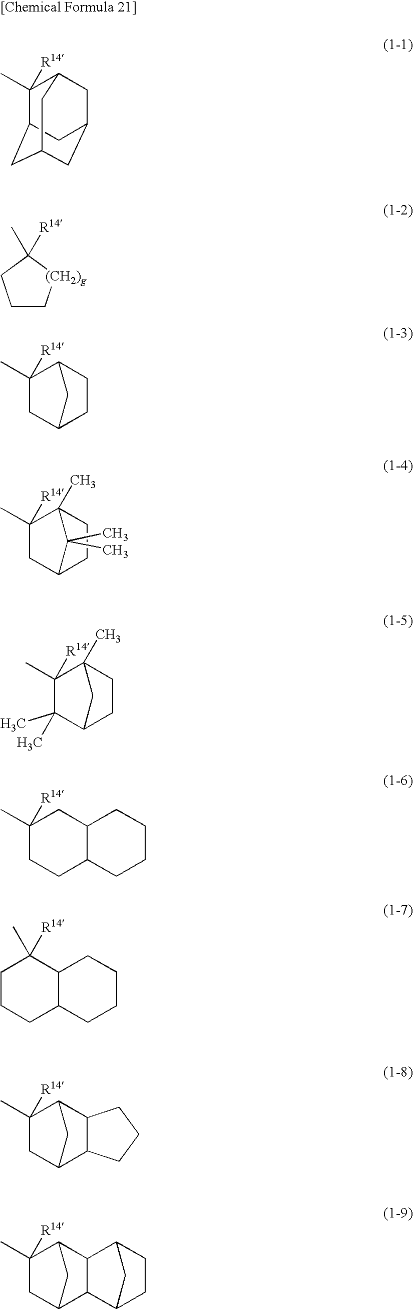

[In the formulas above, R¹⁴′ represents an alkyl group; and g represents an integer of 0 to 8.]

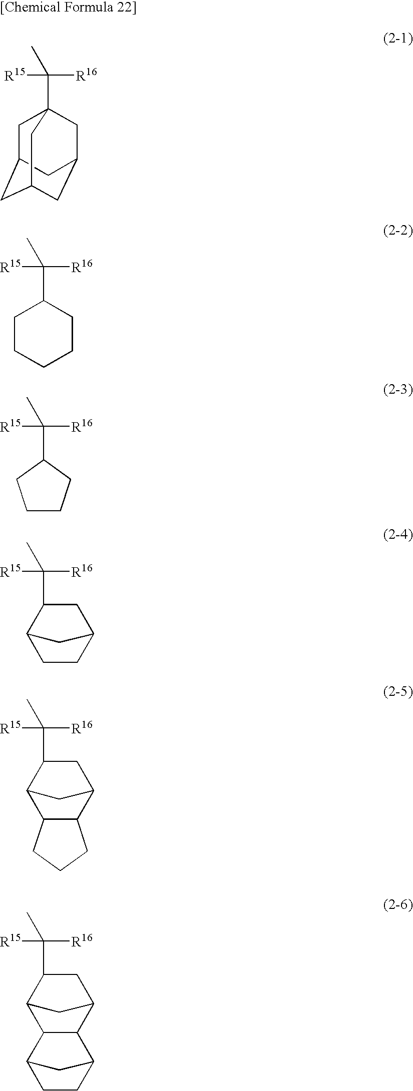

[In the formulas above, each of R¹⁵ and R¹⁶ independently represents an alkyl group (which may be linear or branched, and preferably has 1 to 5 carbon atoms).]

As the alkyl group for R¹⁴′, a linear or branched alkyl group is preferable.

The linear alkyl group preferably has 1 to 5 carbon atoms, more preferably 1 to 4 carbon atoms, and still more preferably 1 or 2 carbon atoms. Specific examples include a methyl group, an ethyl group, a n-propyl group, a n-butyl group and a n-pentyl group. Among these, a methyl group, an ethyl group or a n-butyl group is preferable, and a methyl group or an ethyl group is more preferable.

The branched alkyl group preferably has 3 to 10 carbon atoms, and more preferably 3 to 5 carbon atoms. Specific examples of such branched alkyl groups include an isopropyl group, an isobutyl group, a tert-butyl group, an isopentyl group and a neopentyl group, and an isopropyl group is particularly desirable.

g is preferably an integer of 0 to 3, more preferably an integer of 1 to 3, and still more preferably 1 or 2.

As the alkyl group for R¹⁵ and R¹⁶, the same alkyl groups as those for R¹⁴′ can be used.

In formulas (1-1) to (1-9) and (2-1) to (2-6) above, part of the carbon atoms constituting the ring may be replaced with an ethereal oxygen atom (—O—).

Further, in formulas (1-1) to (1-9) and (2-1) to (2-6) above, the hydrogen atoms bonded to the carbon atoms constituting the ring may be substituted with a substituent. Examples of the substituents include an alkyl group of 1 to 5 carbon atoms, a fluorine atom and a fluorinated alkyl group.

An “acetal-type acid dissociable, dissolution inhibiting group” generally substitutes a hydrogen atom at the terminal of an alkali-soluble group such as a carboxy group or hydroxyl group, so as to be bonded with an oxygen atom. When acid is generated upon exposure, the generated acid acts to break the bond between the acetal-type acid dissociable, dissolution inhibiting group and the oxygen atom to which the acetal-type, acid dissociable, dissolution inhibiting group is bonded.

Examples of acetal-type acid dissociable, dissolution inhibiting groups include groups represented by general formula (p1) shown below.

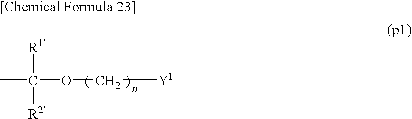

[In the formula, R¹′ and R²′ each independently represent a hydrogen atom or an alkyl group of 1 to 5 carbon atoms; n represents an integer of 0 to 3; and Y¹ represents an alkyl group of 1 to 5 carbon atoms or an aliphatic cyclic group.]

In general formula (p1) above, n is preferably an integer of 0 to 2, more preferably 0 or 1, and most preferably 0.

Examples of the alkyl group of 1 to 5 carbon atoms for R¹′ and R²′ include linear or branched alkyl groups such as a methyl group, an ethyl group, a propyl group, an isopropyl group, a n-butyl group, an isobutyl group, a tert-butyl group, a pentyl group, an isopentyl group and a neopentyl group. Of these, a methyl group or an ethyl group is preferable, and a methyl group is most preferable.

In the present invention, it is preferable that at least one of R¹′ and R²′ be a hydrogen atom. That is, it is preferable that the acid dissociable, dissolution inhibiting group (p1) is a group represented by general formula (p1-1) shown below.

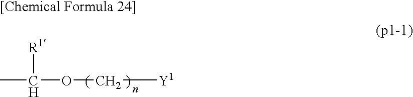

[In the formula, R¹′, n and Y¹ are the same as defined above.]

As the alkyl group of 1 to 5 carbon atoms for Y¹, the same alkyl groups of 1 to 5 carbon atoms as those described above for R¹′ can be used.

As the aliphatic cyclic group for Y¹, any of the aliphatic monocyclic/polycyclic groups which have been proposed for conventional ArF resists and the like can be appropriately selected for use. For example, the same groups described above in connection with the “aliphatic cyclic group” can be used. The aliphatic cyclic group for Y¹ preferably has 4 to 15 carbon atoms.

Further, as the acetal-type, acid dissociable, dissolution inhibiting group, groups represented by general formula (p2) shown below can also be used.

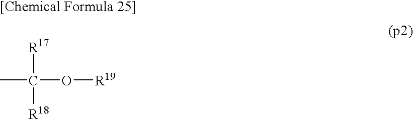

[In the formula, R¹⁷ and R¹⁸ each independently represents a linear or branched alkyl group or a hydrogen atom; and R¹⁹ represents a linear, branched or cyclic alkyl group; or R¹⁷ and R¹⁹ each independently represents a linear or branched alkylene group, and R¹⁷ is bonded to R¹⁹ to form a ring.]

The alkyl group for R¹⁷ and R¹⁸ preferably has 1 to 15 carbon atoms, and may be either linear or branched. As the alkyl group, an ethyl group or a methyl group is preferable, and a methyl group is most preferable. It is particularly desirable that either one of R¹⁷ and R¹⁸ be a hydrogen atom, and the other be a methyl group.

R¹⁹ represents a linear, branched or cyclic alkyl group which preferably has 1 to 15 carbon atoms, and may be any of linear, branched or cyclic.

When R¹⁹ represents a linear or branched alkyl group, it is preferably an alkyl group of 1 to 5 carbon atoms, more preferably an ethyl group or a methyl group, and most preferably an ethyl group.

When R¹⁹ represents a cyclic alkyl group, it preferably has 4 to 15 carbon atoms, more preferably 4 to 12 carbon atoms, and most preferably 5 to 10 carbon atoms. As examples of the cyclic alkyl group, groups in which one or more hydrogen atoms have been removed from a monocycloalkane or a polycycloalkane such as a bicycloalkane, tricycloalkane or tetracycloalkane, which may or may not be substituted with a fluorine atom or a fluorinated alkyl group, may be used. Specific examples of such groups include groups in which one or more hydrogen atoms have been removed from a monocycloalkane such as cyclopentane or cyclohexane; and groups in which one or more hydrogen atoms have been removed from a polycycloalkane such as adamantane, norbornane, isobornane, tricyclodecane or tetracyclododecane. Among these, a group in which one or more hydrogen atoms have been removed from adamantane is preferable.

Further, in general formula (p2) above, R¹⁷ and R¹⁹ may each independently represent a linear or branched alkylene group (preferably an alkylene group of 1 to 5 carbon atoms), and R¹⁹ may be bonded to R¹⁷.

In such a case, a cyclic group is formed by R¹⁷, R¹⁹, the oxygen atom having R¹⁹ bonded thereto, and the carbon atom having the oxygen atom and R¹⁷ bonded thereto. Such a cyclic group is preferably a 4 to 7-membered ring, and more preferably a 4 to 6-membered ring. Specific examples of the cyclic group include tetrahydropyranyl group and tetrahydrofuranyl group.

Specific examples of acetal-type acid dissociable, dissolution inhibiting groups include groups represented by formulas (p3-1) to (p3-12) shown below.

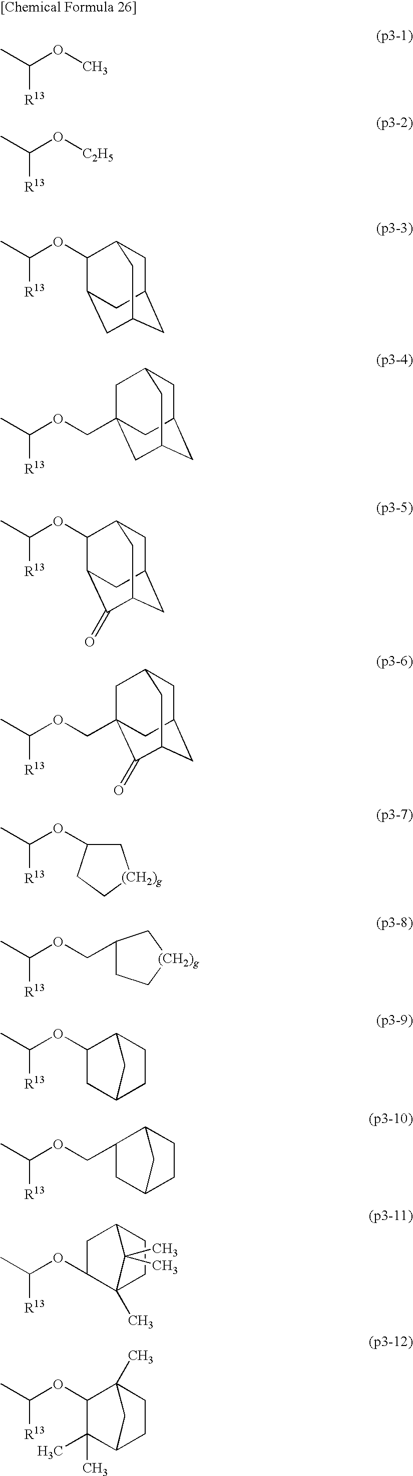

[In the formulas above, R¹³ represents a hydrogen atom or a methyl group; and g is the same as defined above.]

As the structural unit (a1), it is preferable to use at least one member selected from the group consisting of structural units represented by formula (a1-0-1) shown below and structural units represented by formula (a1-0-2) shown below.

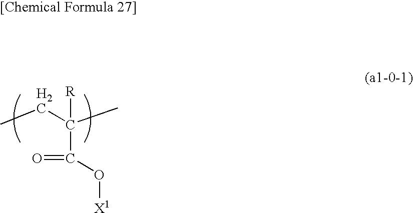

[In the formula, R represents a hydrogen atom, an alkyl group of 1 to 5 carbon atoms or a halogenated alkyl group of 1 to 5 carbon atoms; and X¹ represents an acid dissociable, dissolution inhibiting group.]

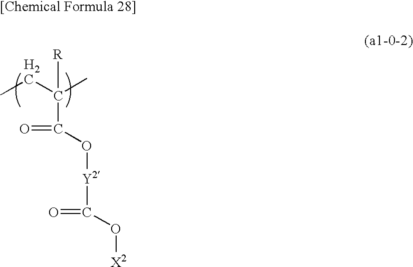

[In the formula, R represents a hydrogen atom, an alkyl group of 1 to 5 carbon atoms or a halogenated alkyl group of 1 to 5 carbon atoms; X² represents an acid dissociable, dissolution inhibiting group; and Y²′ represents a divalent linking group.]

In general formula (a1-0-1), R is the same as defined above for R¹ in formula (a5-1).

X¹ is not particularly limited as long as it is an acid dissociable, dissolution inhibiting group. Examples thereof include the aforementioned tertiary alkyl ester-type acid dissociable, dissolution inhibiting groups and acetal-type acid dissociable, dissolution inhibiting groups, and tertiary alkyl ester-type acid dissociable, dissolution inhibiting groups are preferable.

In general formula (a1-0-2), R is the same as defined above.

X² is the same as defined for X¹ in general formula (a1-0-1).

As the divalent linking group for Y²′, the same groups as those described for the aforementioned divalent linking group of the linkage portion connecting a plurality of core portions can be used.

As Y²′, the aforementioned alkylene group, a divalent aliphatic cyclic group or a divalent linking group containing a hetero atom is preferable. Among these, a divalent linking group containing a hetero atom is preferable, and a linear group containing an oxygen atom as a hetero atom, for example, a group containing an ester bond is particularly desirable.

More specifically, a group represented by the aforementioned formula -A-O—B— or -A-C(═O)—O—B— is preferable, and a group represented by the formula —(CH₂)ₓ—C(═O)—O—(CH₂)_{y}— is particularly desirable.

x represents an integer of 1 to 5, preferably 1 or 2, and most preferably 1.

y represents an integer of 1 to 5, preferably 1 or 2, and most preferably 1.

Specific examples of the structural unit (a1) include structural units represented by general formulas (a1-1) to (a1-4) shown below.

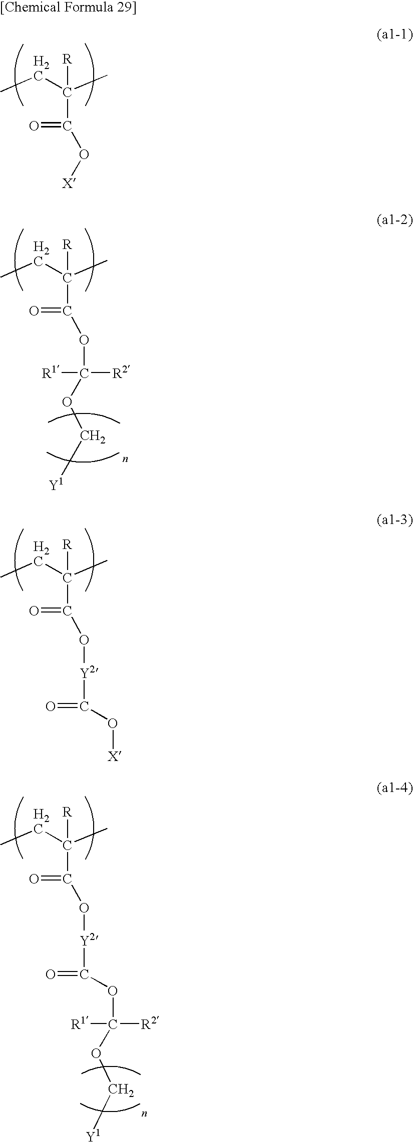

[In the formulas, X′ represents a tertiary alkyl ester-type acid dissociable, dissolution inhibiting group; Y¹ represents an alkyl group of 1 to 5 carbon atoms or an aliphatic cyclic group; n represents an integer of 0 to 3; Y²′ represents a divalent linking group; R is the same as defined above; and each of R¹′ and R²′ independently represents a hydrogen atom or an alkyl group of 1 to 5 carbon atoms.]

In the formulas above, examples of the tertiary alkyl ester-type acid dissociable, dissolution inhibiting group for X′ include the same tertiary alkyl ester-type acid dissociable, dissolution inhibiting groups as those described above for X¹.

As R¹′, R²′, n and Y¹, the same as defined for R¹′, R²′, n and Y¹ in general formula (p1) described above in connection with the “acetal-type acid dissociable, dissolution inhibiting group” can be used.

As examples of Y²′, the same groups as those described above for Y in general Y²′ in general formula (a1-0-2) can be given.

Specific examples of structural units represented by general formulas (a1-1) to (a1-4) above are shown below.

In the formulas shown below, R^{α} represents a hydrogen atom, a methyl group or a trifluoromethyl group.

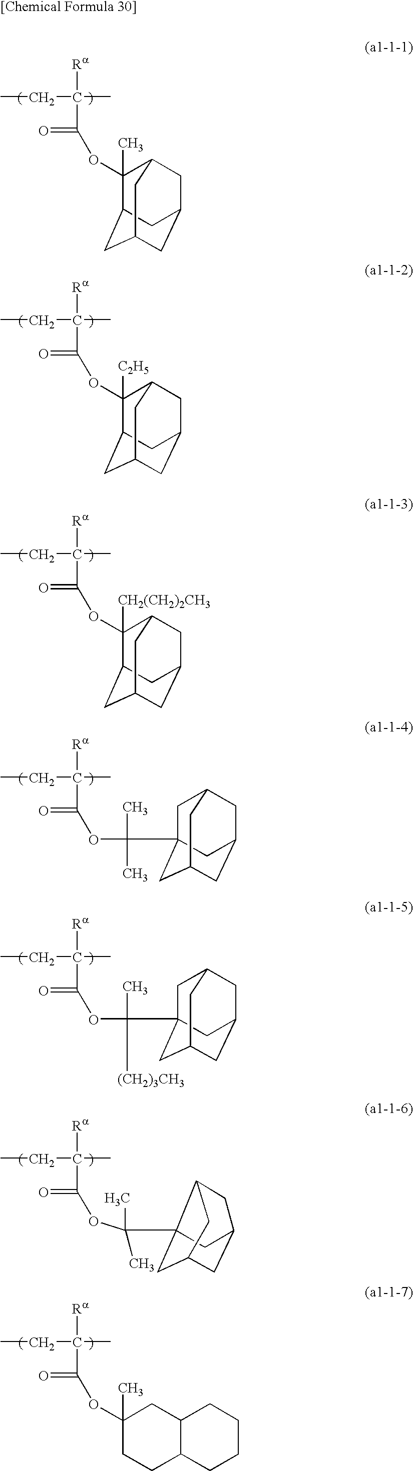

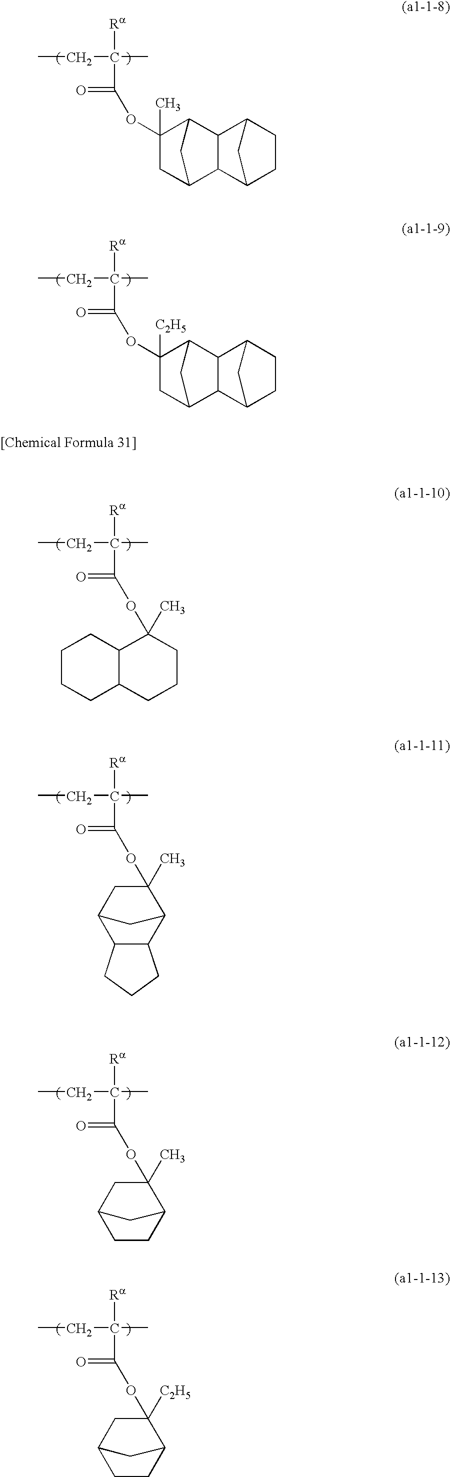

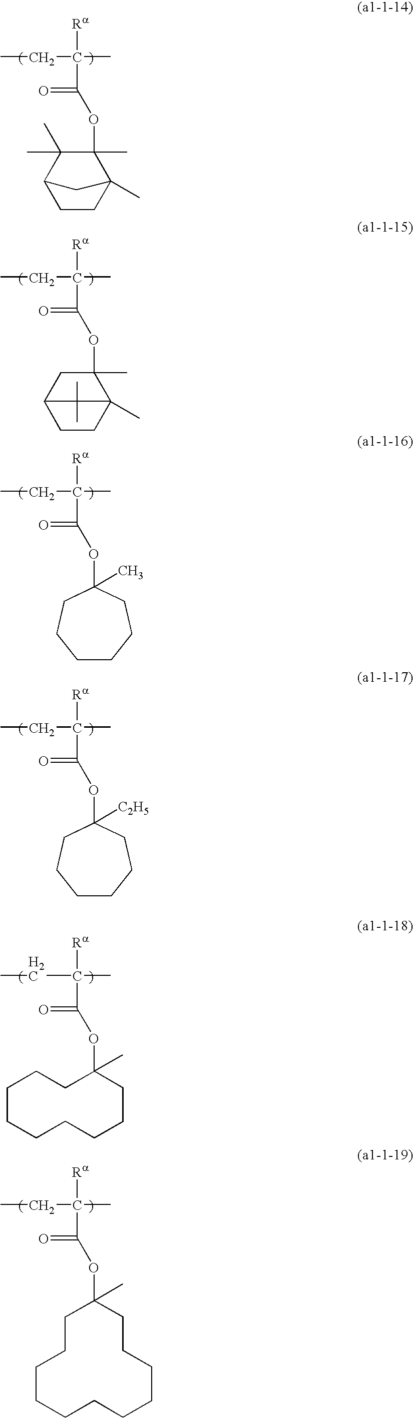

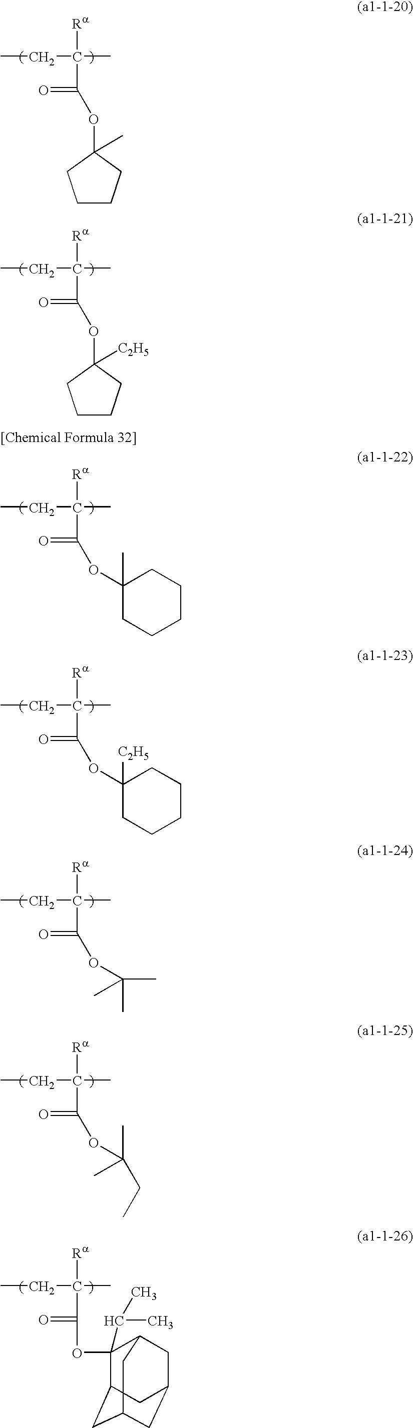

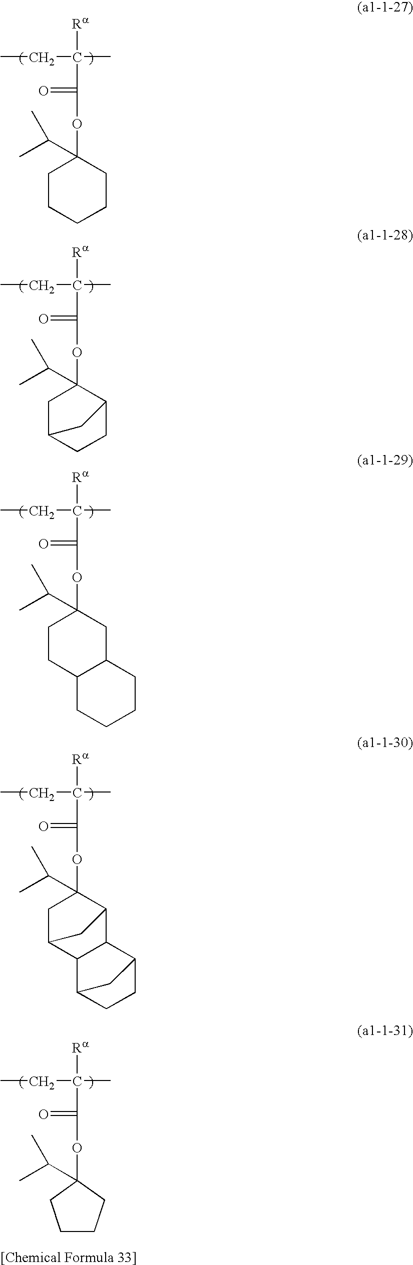

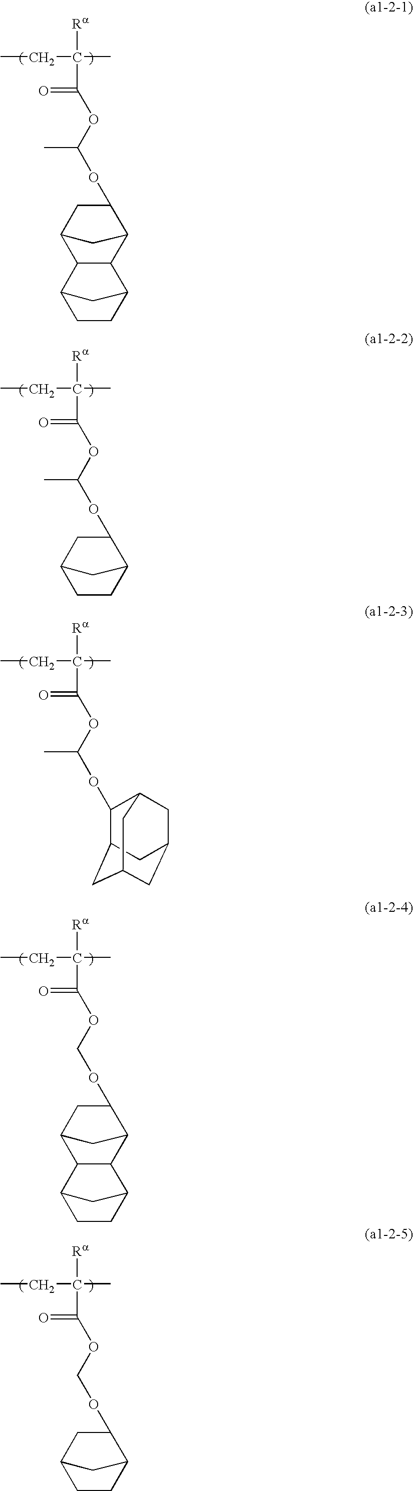

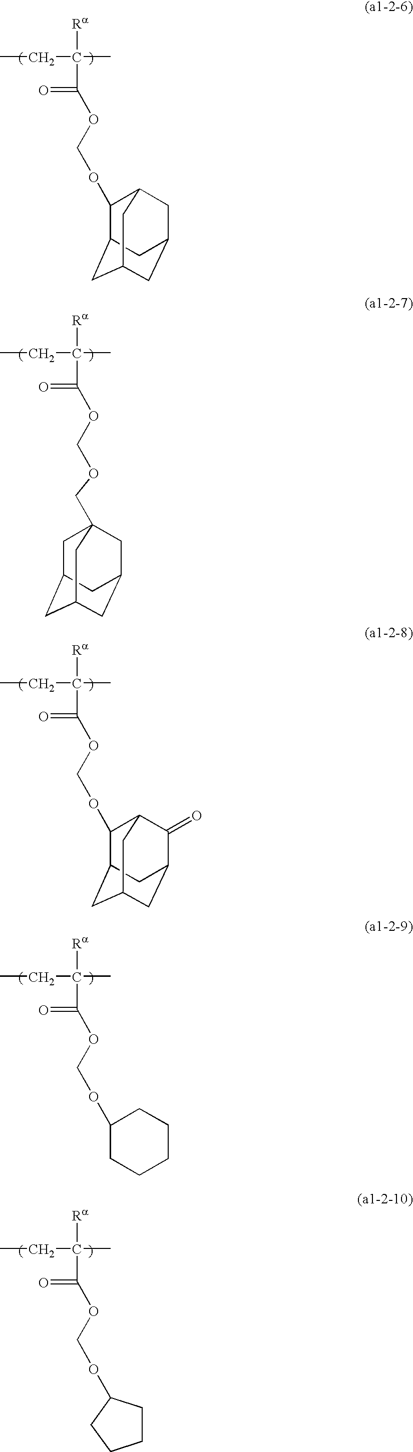

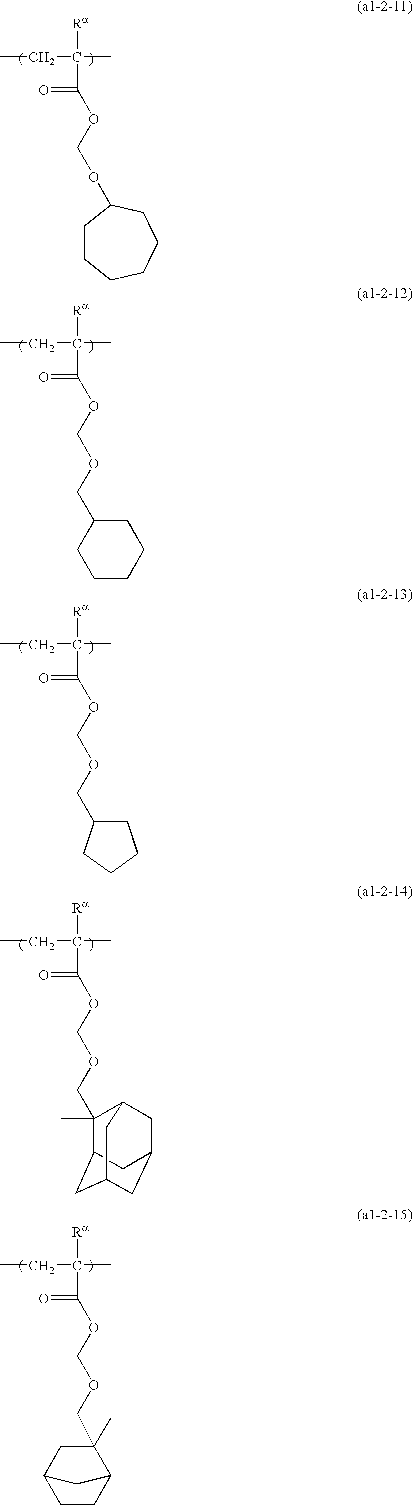

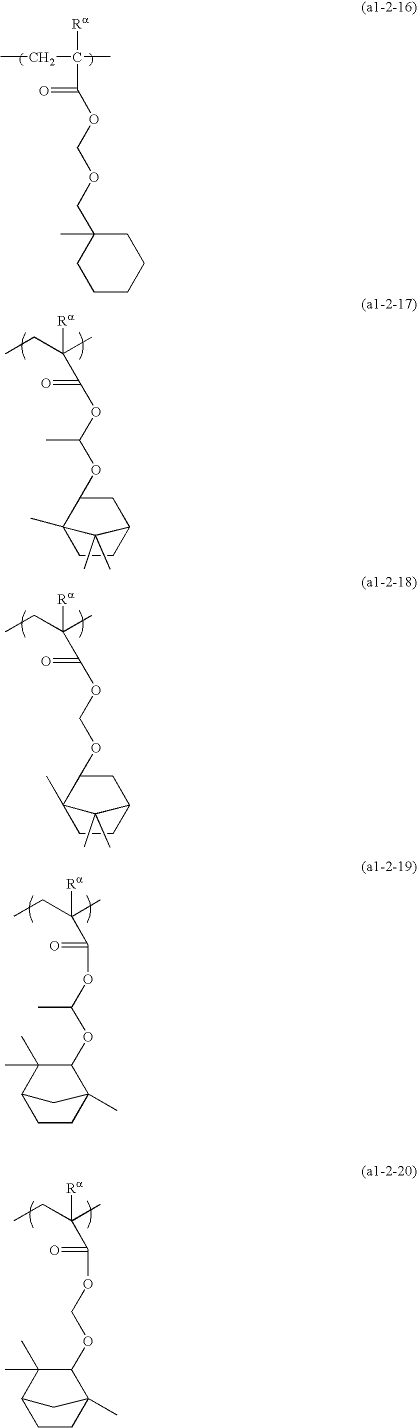

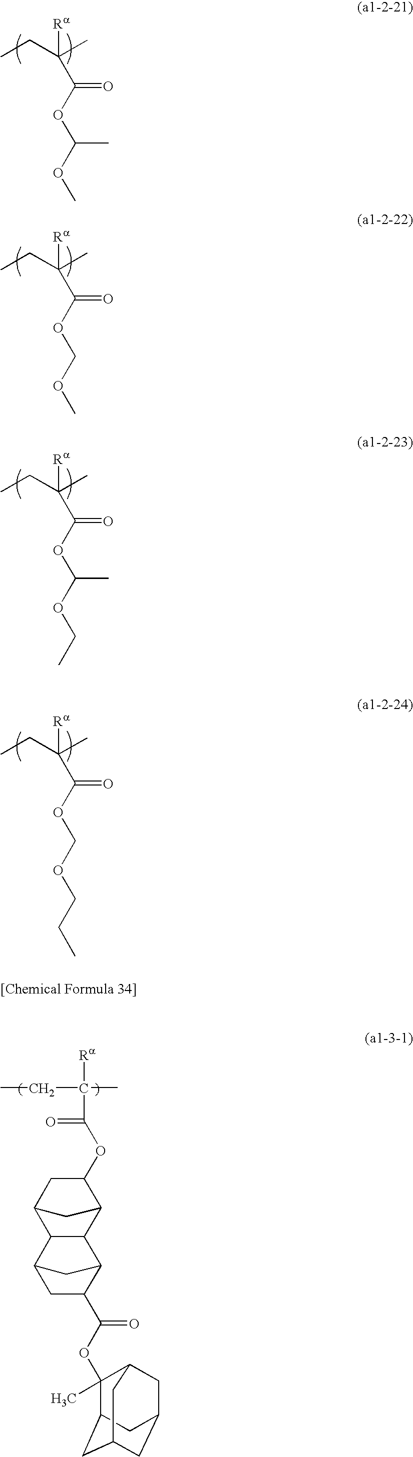

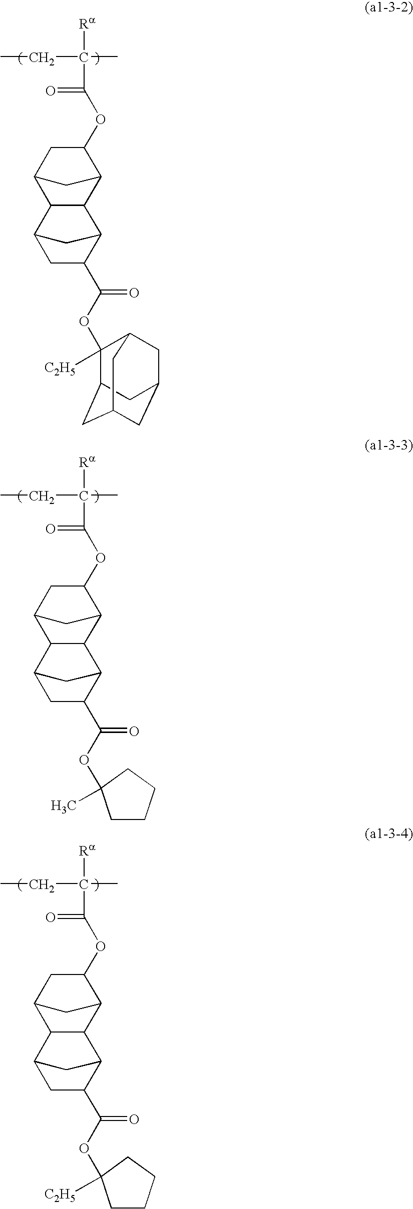

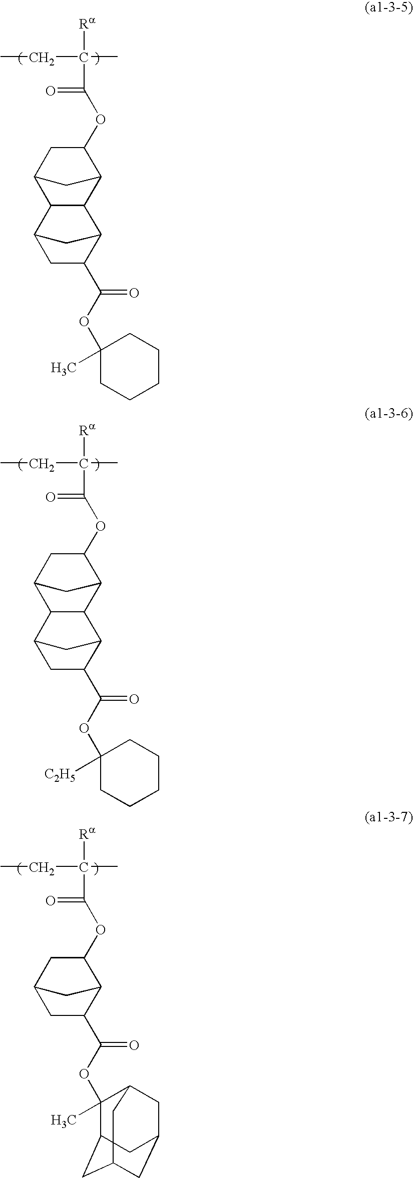

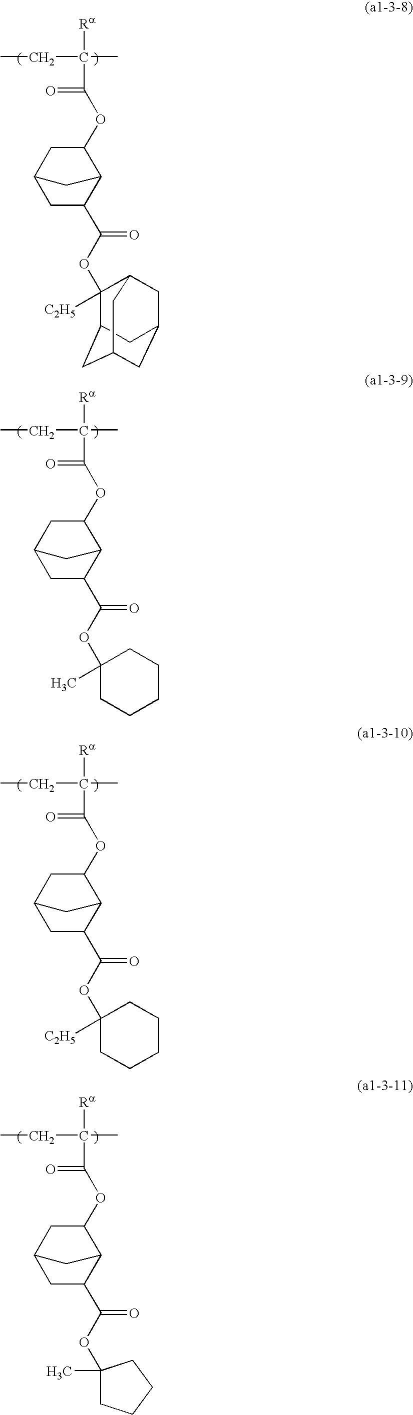

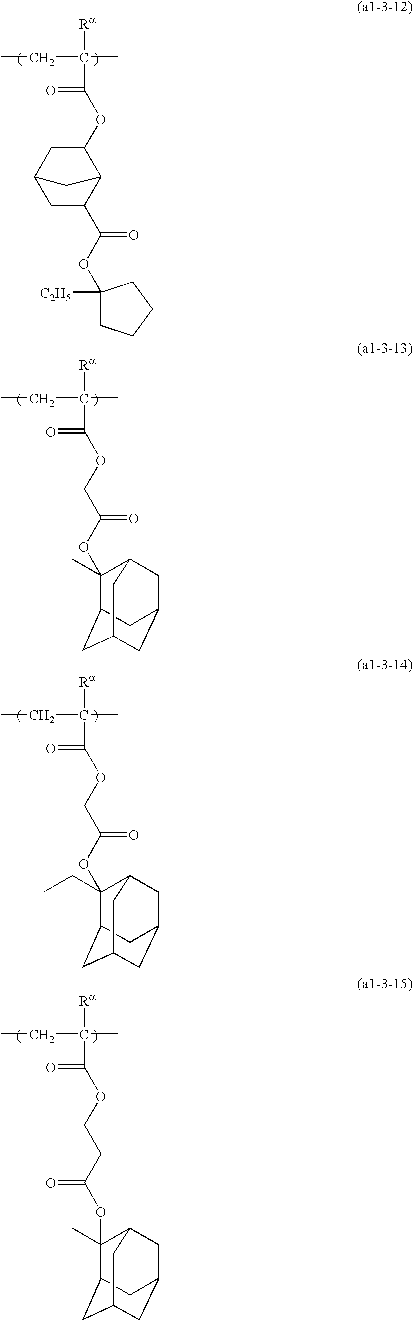

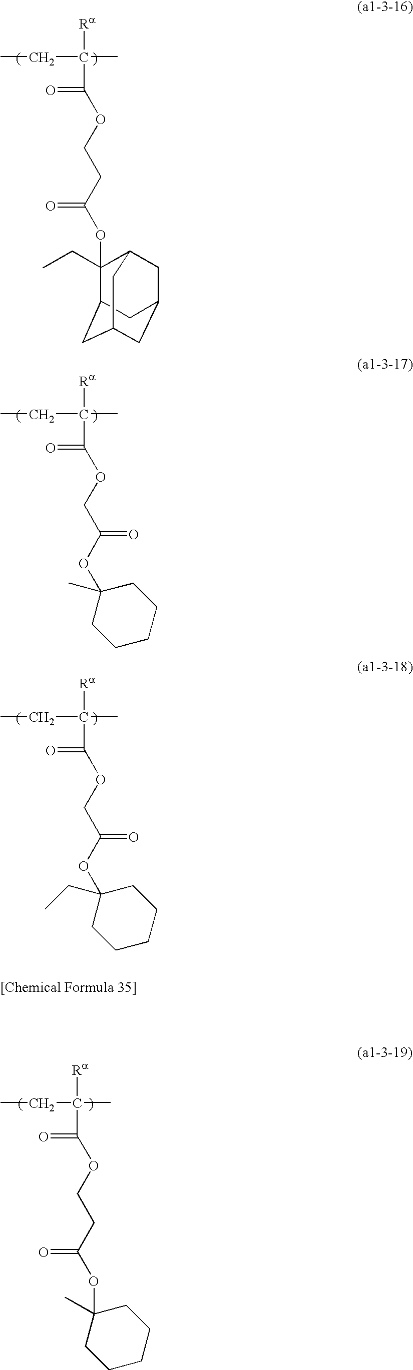

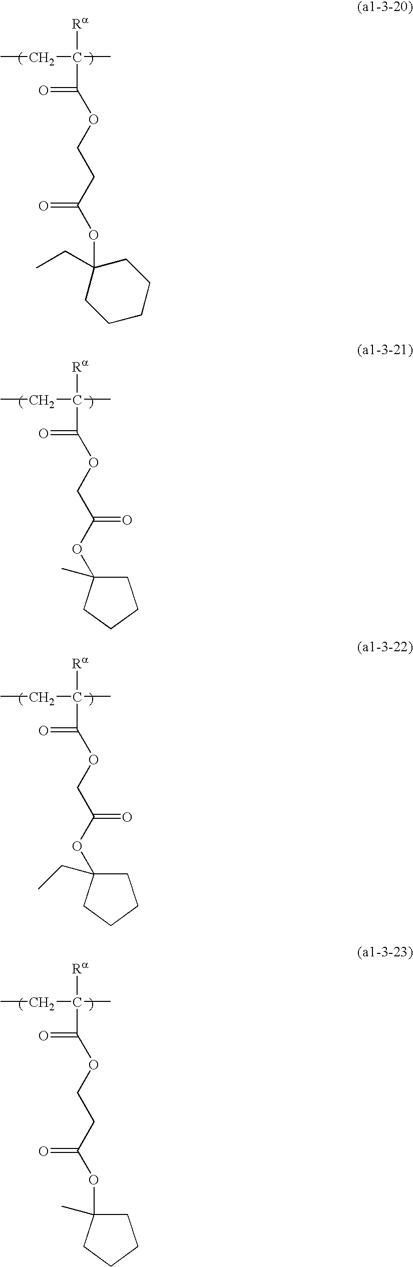

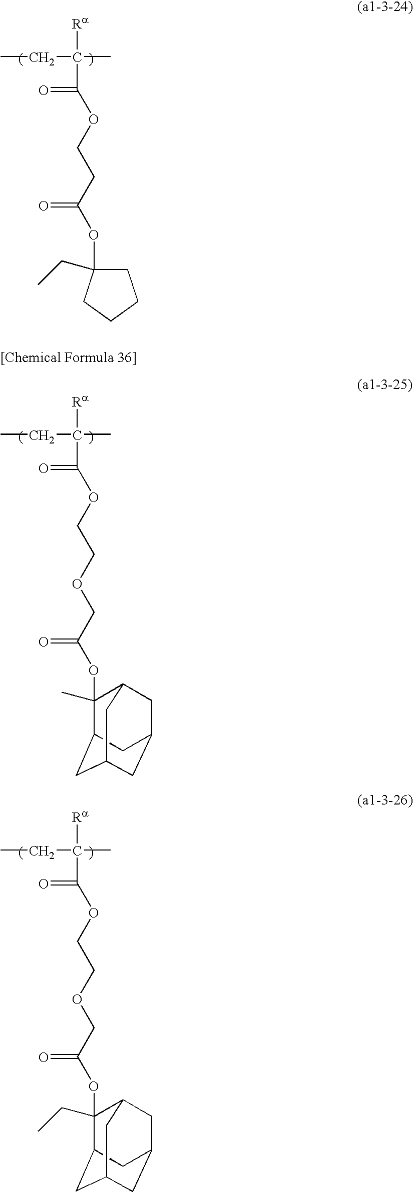

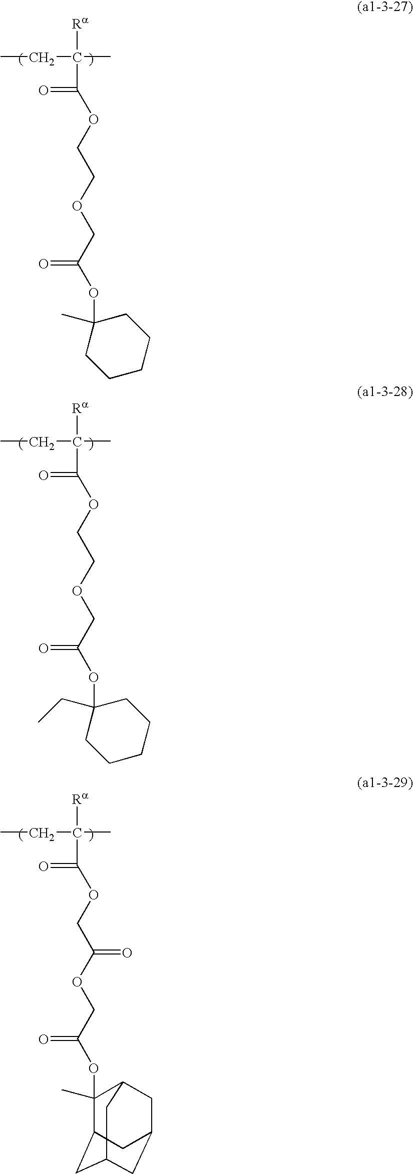

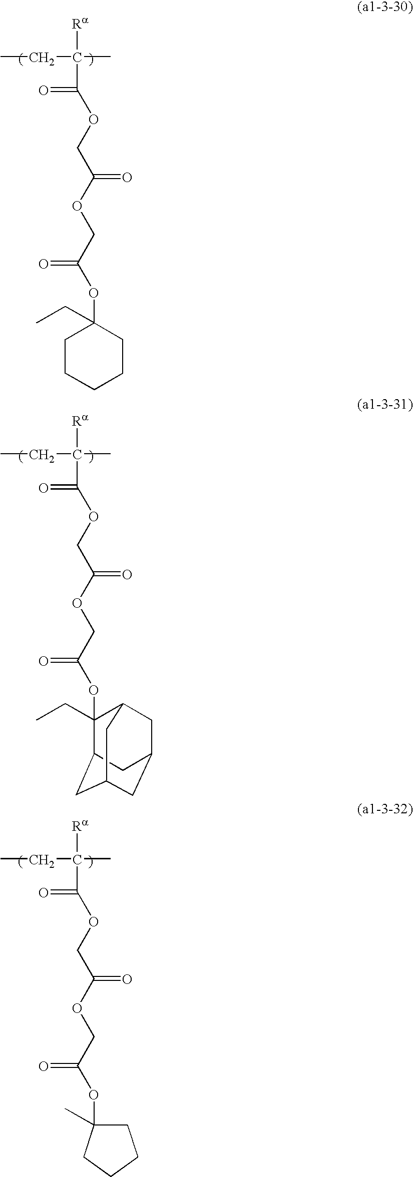

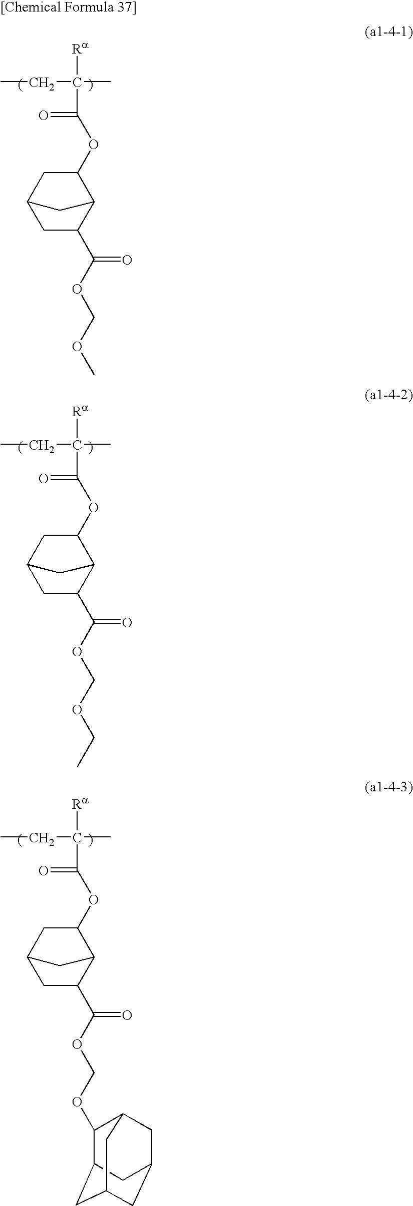

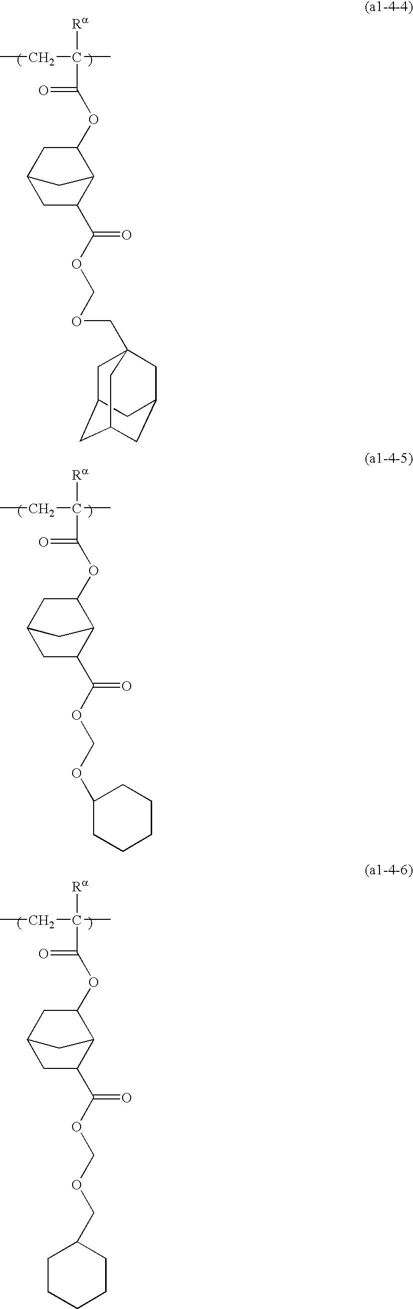

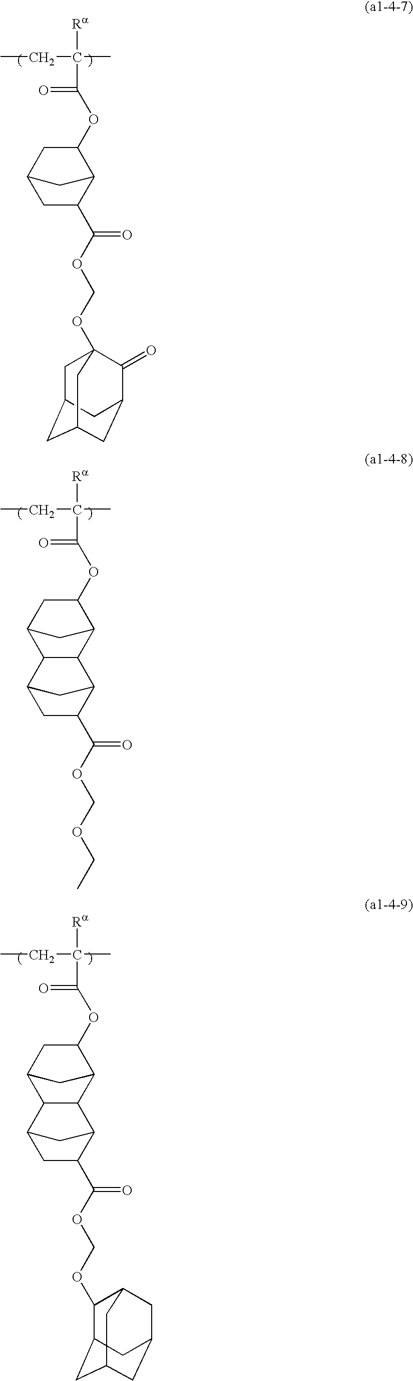

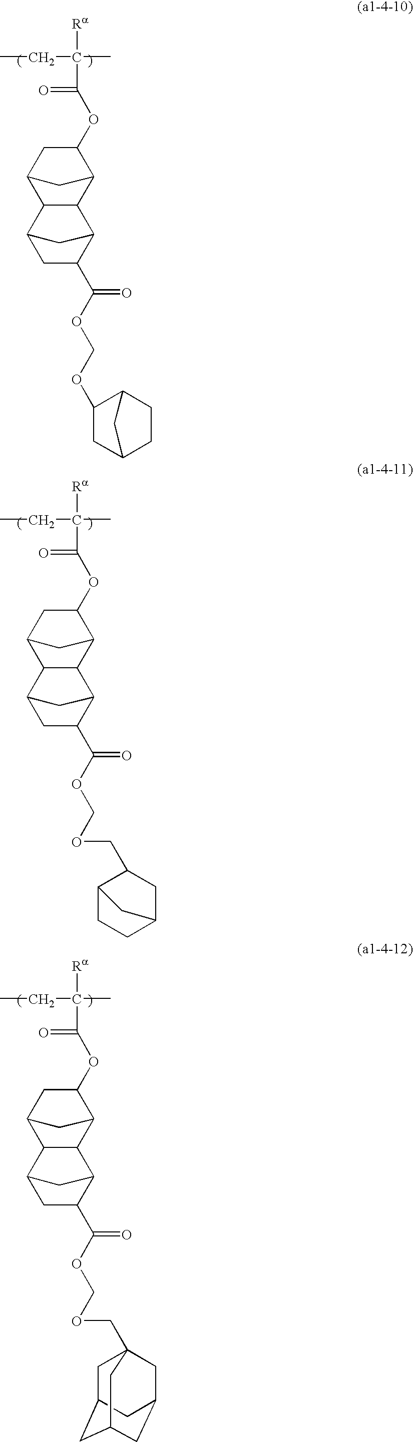

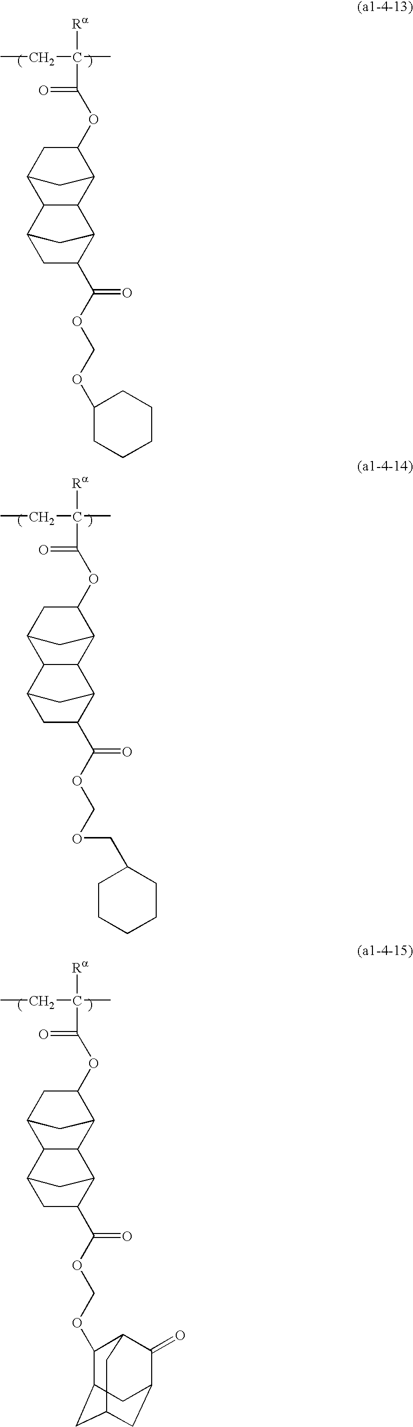

As the structural unit (a1), one type of structural unit may be used alone, or two or more types of structural units may be used in combination.

Among these, structural units represented by general formula (a1-1) or (a1-3) are preferable. More specifically, at least one structural unit selected from the group consisting of structural units represented by formulas (a1-1-1) to (a-1-1-4), (a1-1-20) to (a1-1-23), (a1-1-26), and (a1-3-25) to (a1-3-28) is more preferable.

Further, as the structural unit (a1), structural units represented by general formula (a1-1-01) shown below which includes the structural units represented by formulas (a1-1-1) to (a1-1-3), structural units represented by general formula (a1-1-02) shown below which includes the structural units represented by formulas (a1-1-16), (a1-1-17) and (a1-1-20) to (a1-1-23), structural units represented by general formula (a1-3-01) shown below which include the structural units represented by formulas (a1-3-25) and (a1-3-26), and structural units represented by general formula (a1-3-02) shown below which include the structural units represented by formulas (a1-3-27) to (a1-3-28) are also preferable.

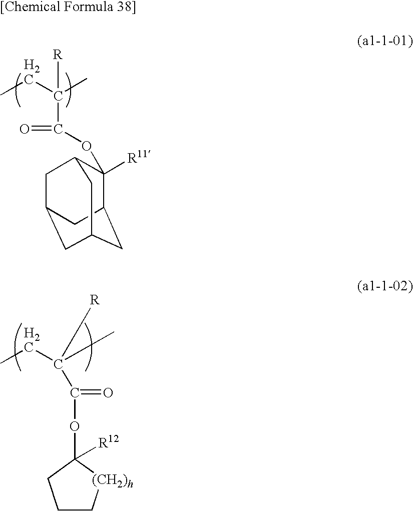

[In the formulas, each R represents a hydrogen atom, an alkyl group of 1 to 5 carbon atoms or a halogenated alkyl group of 1 to 5 carbon atoms; R¹¹′ represents an alkyl group of 1 to 5 carbon atoms; R¹² represents an alkyl group of 1 to 5 carbon atoms; and h represents an integer of 1 to 6.]

In general formula (a1-1-01), R is the same as defined above. The alkyl group of 1 to 5 carbon atoms for R¹¹′ is the same as the alkyl group of 1 to 5 carbon atoms for R¹ above, and is preferably a methyl group, an ethyl group or an isopropyl group.

In general formula (a1-1-02), R is the same as defined above. The alkyl group of 1 to 5 carbon atoms for R¹² is the same as the alkyl group of 1 to 5 carbon atoms for R¹ above, and is most preferably a methyl group, an ethyl group or an isopropyl group. h is particularly preferably 1 or 2.

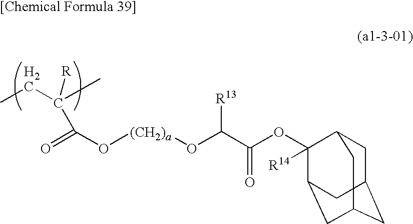

[In the formula, R represents a hydrogen atom, an alkyl group of 1 to 5 carbon atoms or a halogenated alkyl group of 1 to 5 carbon atoms; R¹⁴ represents an alkyl group of 1 to 5 carbon atoms; R¹³ represents a hydrogen atom or a methyl group; and a represents an integer of 1 to 10.]

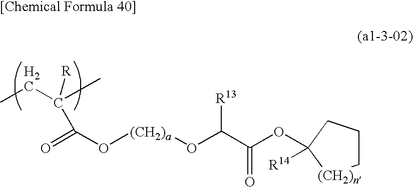

[In the formula, R represents a hydrogen atom, an alkyl group of 1 to 5 carbon atoms or a halogenated alkyl group of 1 to 5 carbon atoms; R¹⁴ represents an alkyl group of 1 to 5 carbon atoms; R¹³ represents a hydrogen atom or a methyl group; a represents an integer of 1 to 10; and n′ represents an integer of 1 to 6.]

In general formulas (a1-3-01) and (a1-3-02) above, R is the same as defined above.

R¹³ is preferably a hydrogen atom.

The alkyl group of 1 to 5 carbon atoms for R¹⁴ is the same as the alkyl group of 1 to 5 carbon atoms for R¹, and is preferably a methyl group or an ethyl group.

n′ is preferably 1 or 2, and most preferably 2.

a is preferably an integer of 1 to 8, more preferably an integer of 2 to 5, and most preferably 2.

In those cases where the structural unit (a1) is included in the polymer chain Y, in the polymer chain Y, the amount of the structural unit (a1) based on the combined total of all structural units constituting the polymer chain Y is preferably 10 to 80 mol %, more preferably 20 to 70 mol %, and still more preferably 25 to 60 mol %. By making the amount of the structural unit (a1) at least as large as the lower limit of the above-mentioned range, a pattern can be easily formed using a resist composition prepared from the polymer chain Y. On the other hand, by making the amount of the structural unit (a1) no more than the upper limit of the above-mentioned range, a good balance can be achieved with the other structural units.

(Structural Unit (a2))

The structural unit (a2) is a structural unit derived from an acrylate ester containing a lactone-containing cyclic group.

The term “lactone-containing cyclic group” refers to a cyclic group including one ring containing a —O—C(O)— structure (lactone ring). The term “lactone ring” refers to a single ring containing a —O—C(O)— structure, and this ring is counted as the first ring. A lactone-containing cyclic group in which the only ring structure is the lactone ring is referred to as a monocyclic group, and groups containing other ring structures are described as polycyclic groups regardless of the structure of the other rings.

When the polymer chain Y is used for forming a resist film, the lactone-containing cyclic group of the structural unit (a2) is effective in improving the adhesion between the resist film and the substrate, and increasing the compatibility with the developing solution containing water.

As the structural unit (a2), there is no particular limitation, and an arbitrary structural unit may be used.

Specific examples of lactone-containing monocyclic groups include a group in which one hydrogen atom has been removed from a 4- to 6-membered lactone ring, such as a group in which one hydrogen atom has been removed from β-propiolactone, a group in which one hydrogen atom has been removed from γ-butyrolactone, and a group in which one hydrogen atom has been removed from δ-valerolactone. Further, specific examples of lactone-containing polycyclic groups include groups in which one hydrogen atom has been removed from a lactone ring-containing bicycloalkane, tricycloalkane or tetracycloalkane.

More specifically, examples of the structural unit (a2) include structural units represented by general formulas (a2-1) to (a2-5) shown below.

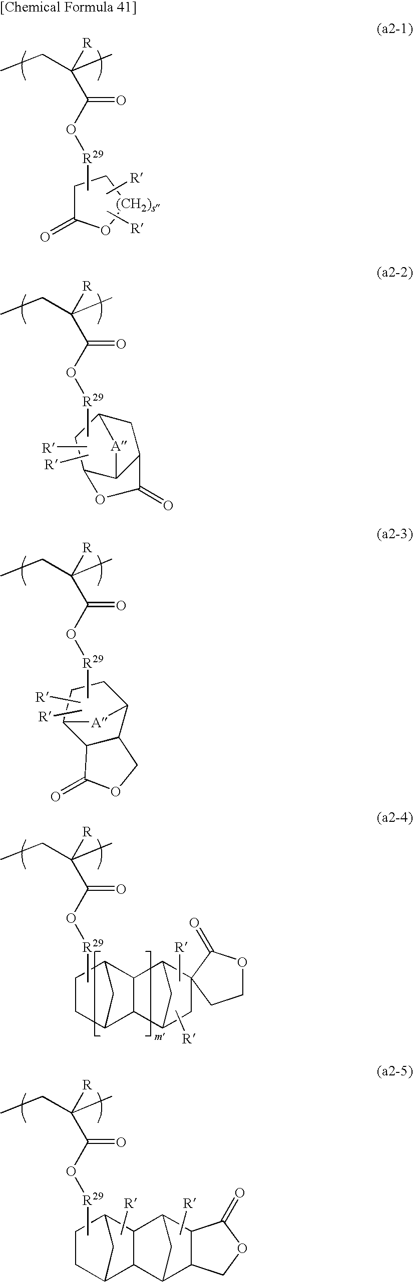

[In the formulas, R represents a hydrogen atom, an alkyl group of 1 to 5 carbon atoms or a halogenated alkyl group of 1 to 5 carbon atoms; each R′ independently represents a hydrogen atom, an alkyl group of 1 to 5 carbon atoms, an alkoxy group of 1 to 5 carbon atoms or —COOR″, wherein R″ represents a hydrogen atom or an alkyl group; R²⁹ represents a single bond or a divalent linking group; s″ represents an integer of 0 to 2; A″ represents an alkylene group of 1 to 5 carbon atoms which may contain an oxygen atom or a sulfur atom, an oxygen atom or a sulfur atom; and m′ represents 0 or 1.]

In general formulas (a2-1) to (a2-5), R is the same as R in the structural unit (a1).

Examples of the alkyl group of 1 to 5 carbon atoms for R′ include a methyl group, an ethyl group, a propyl group, an n-butyl group and a tert-butyl group.

Examples of the alkoxy group of 1 to 5 carbon atoms for R′ include a methoxy group, an ethoxy group, an n-propoxy group, an iso-propoxy group, an n-butoxy group and a tert-butoxy group.

In consideration of industrial availability, R′ is preferably a hydrogen atom.

When R″ is a linear or branched alkyl group, it preferably has 1 to 10 carbon atoms, more preferably 1 to 5 carbon atoms.

When R″ is a cyclic alkyl group, it preferably has 3 to 15 carbon atoms, more preferably 4 to 12 carbon atoms, and most preferably 5 to 10 carbon atoms. As examples of the cyclic alkyl group, groups in which one or more hydrogen atoms have been removed from a monocycloalkane or a polycycloalkane such as a bicycloalkane, tricycloalkane or tetracycloalkane, which may or may not be substituted with a fluorine atom or a fluorinated alkyl group, may be used. Specific examples of such groups include groups in which one or more hydrogen atoms have been removed from a monocycloalkane such as cyclopentane or cyclohexane; and groups in which one or more hydrogen atoms have been removed from a polycycloalkane such as adamantane, norbornane, isobornane, tricyclodecane or tetracyclododecane.

As A″, an alkylene group of 1 to 5 carbon atoms or —O— is preferable, more preferably an alkylene group of 1 to 5 carbon atoms, and most preferably a methylene group.

R²⁹ represents a single bond or a divalent linking group. Examples of divalent linking groups include the same divalent linking groups as those described above for Y²′ in general formula (a1-0-2). Among these, an alkylene group, an ester bond (—C(═O)—O—) or a combination thereof is preferable. The alkylene group as a divalent linking group for R²⁹ is preferably a linear or branched alkylene group. Specific examples include the same linear alkylene groups and branched alkylene groups as those described above for the aliphatic cyclic group A in Y²′.

s″ is preferably an integer of 1 or 2.

Specific examples of structural units represented by the above general formulas (a2-1) to (a2-5) are shown below. In the formulas shown below, R^{α} represents a hydrogen atom, a methyl group or a trifluoromethyl group.

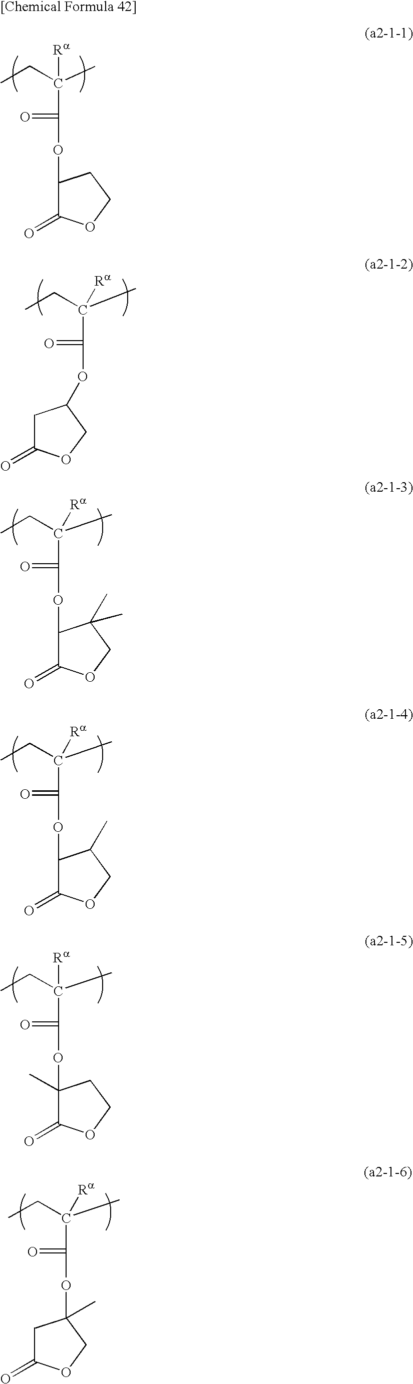

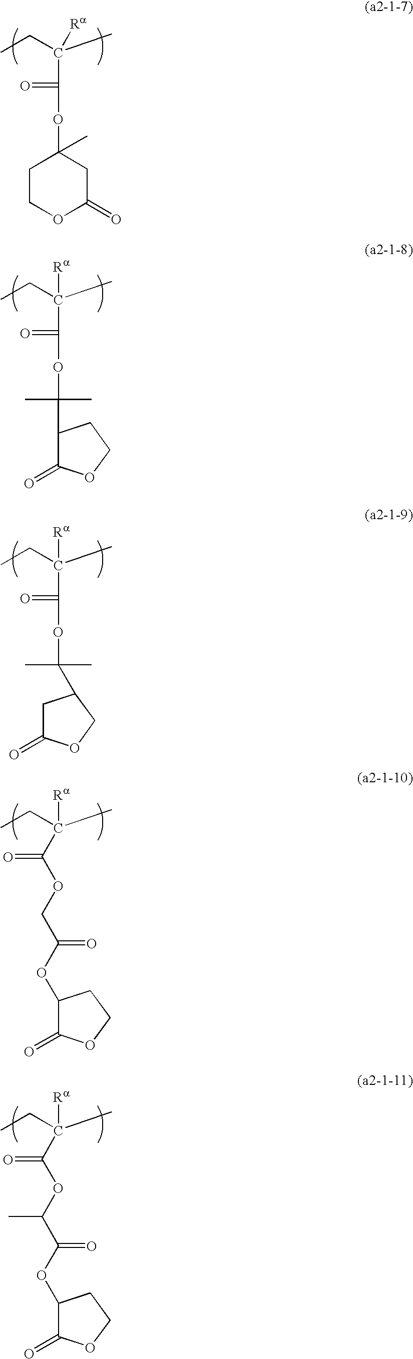

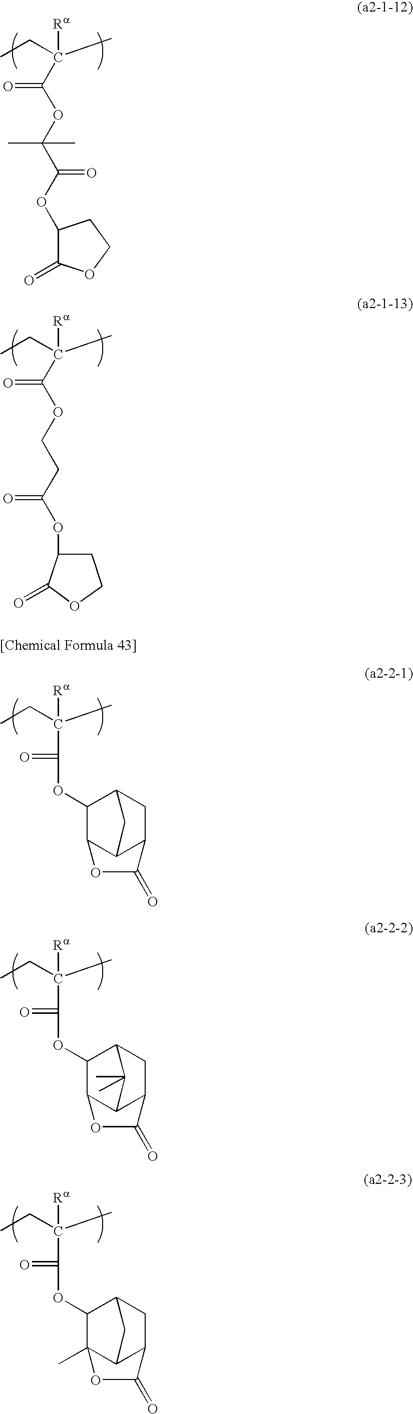

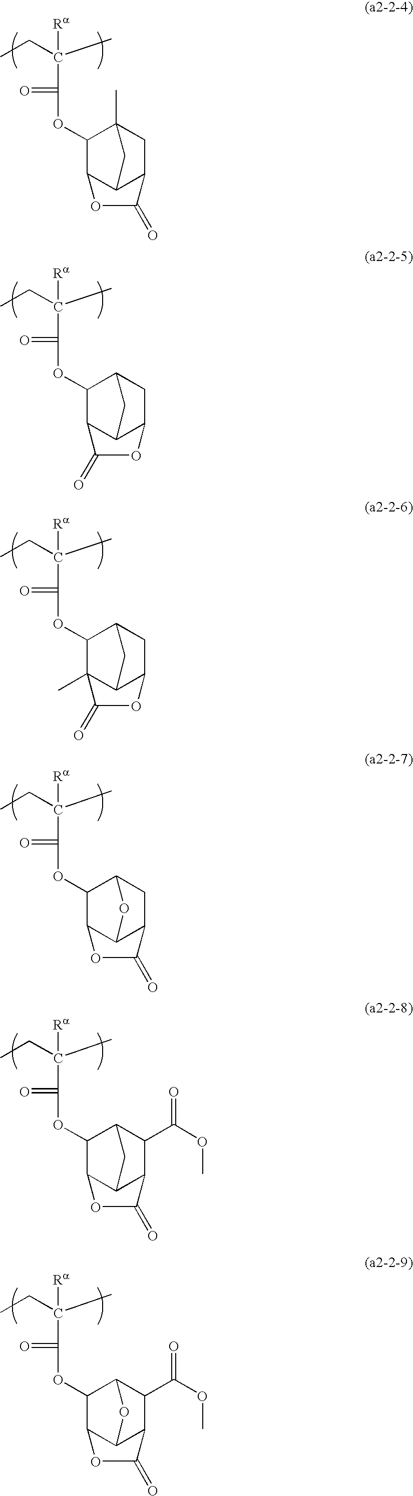

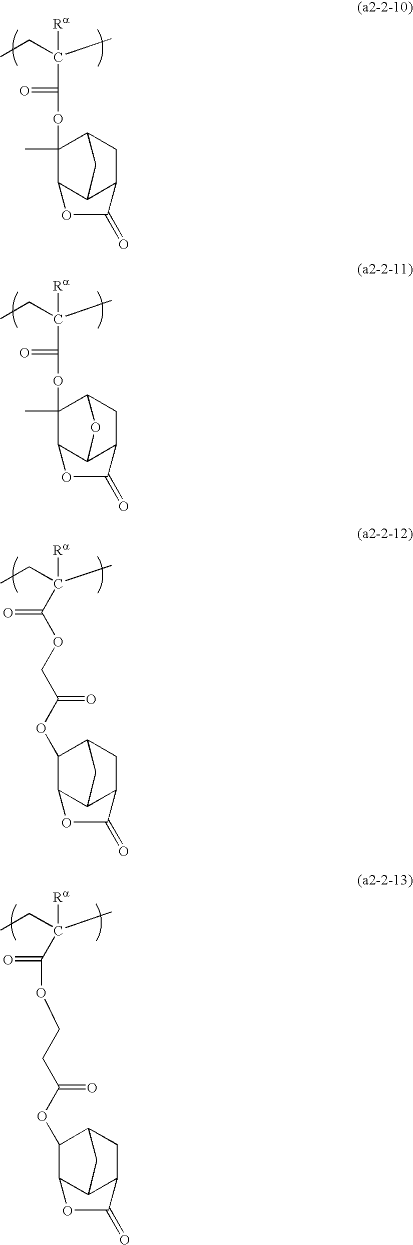

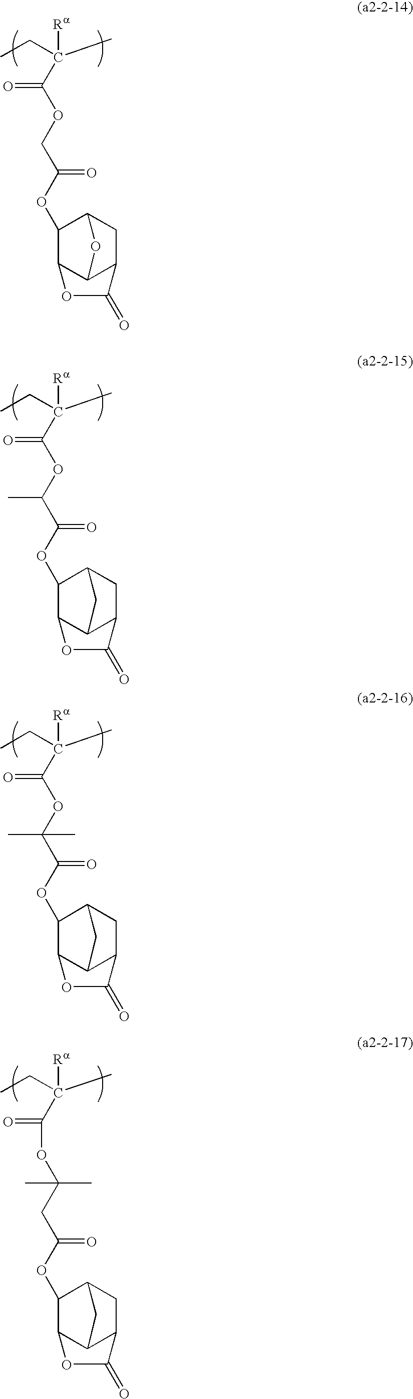

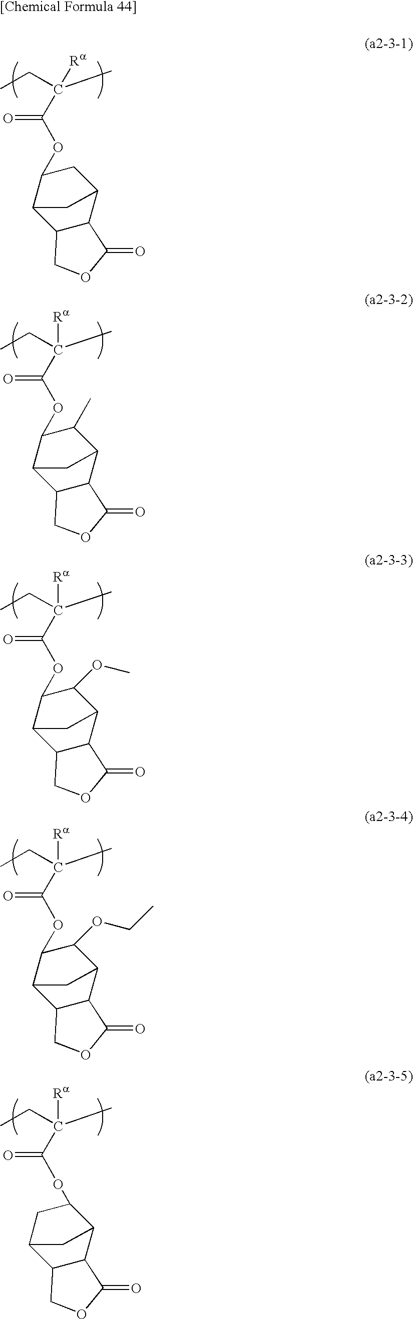

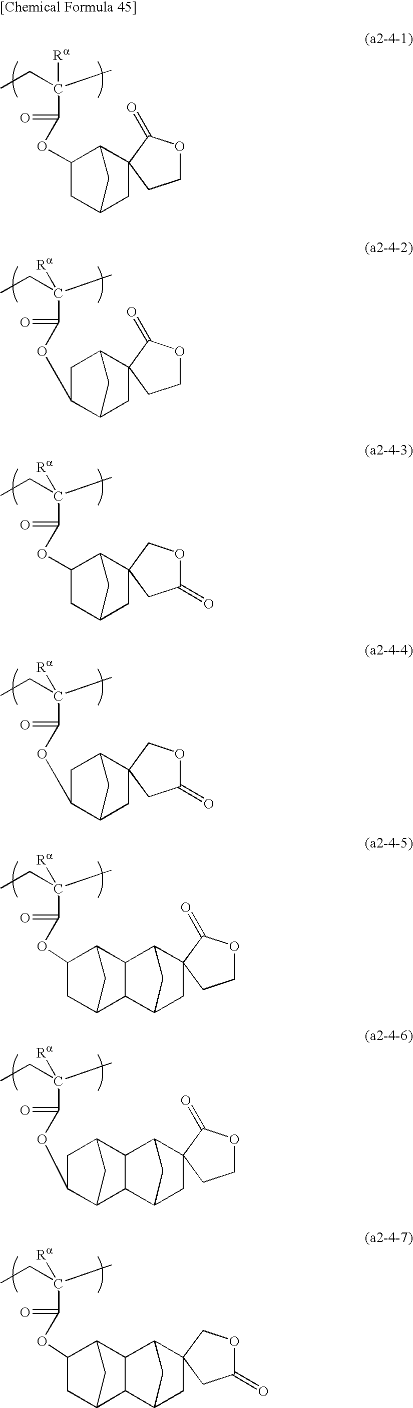

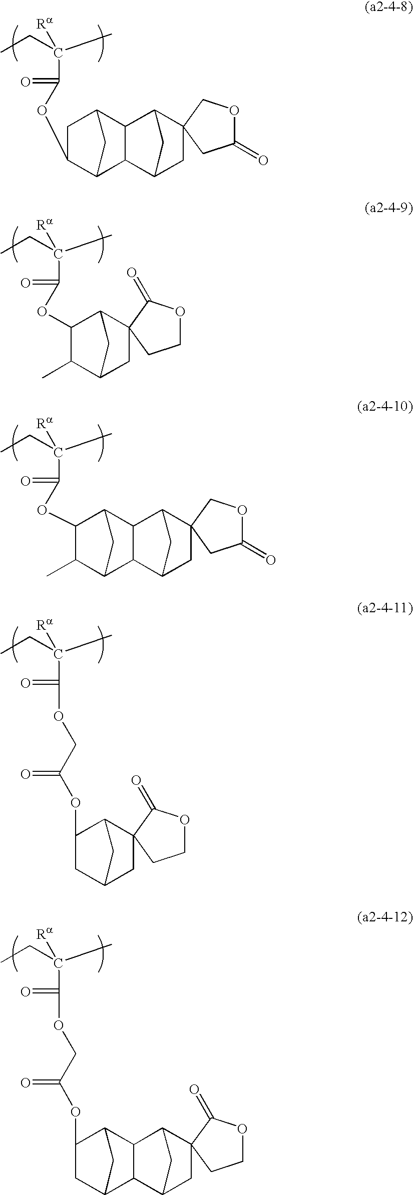

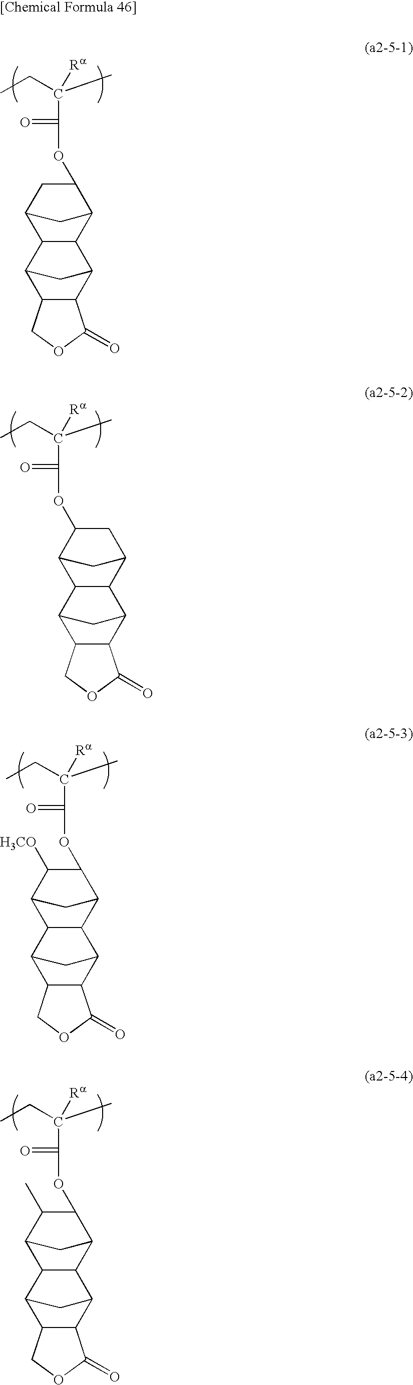

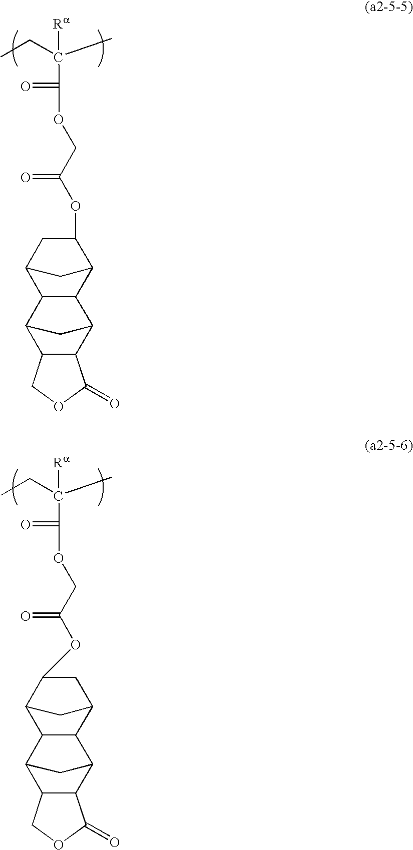

In the polymer chain Y, as the structural unit (a2), one type of structural unit may be used alone, or two or more types of structural units may be used in combination.

As the structural unit (a2), at least one structural unit selected from the group consisting of structural units represented by general formulas (a2-1) to (a2-5) is preferable, and at least one structural unit selected from the group consisting of structural units represented by general formulas (a2-1) to (a2-3) is more preferable. Of these, it is preferable to use at least one structural unit selected from the group consisting of structural units represented by chemical formulas (a2-1-1), (a2-2-1), (a2-2-7), (a2-3-1) and (a2-3-5).

In those cases where the structural unit (a2) is included in the polymer chain Y, in the polymer chain Y, in terms of improving the adhesion between a supporting material, such as a substrate, and a resist film formed using a positive resist composition containing the polymer chain Y, and increasing the compatibility with a developing solution, the amount of the structural unit (a2) based on the combined total of all structural units constituting the polymer chain Y is preferably 1 to 65 mol %, more preferably 5 to 60 mol %, and still more preferably 10 to 55 mol %.

(Structural Unit (a3))

The structural unit (a3) is a structural unit derived from an acrylate ester containing a polar group-containing hydrocarbon group.

When the polymer chain Y includes the structural unit (a3), the hydrophilicity of the polymer chain Y is improved, and hence, the compatibility of the polymer chain Y with the developing solution is improved. As a result, the alkali solubility of the exposed portions improves, which contributes to favorable improvements in the resolution.

Examples of the polar group include a hydroxyl group, a cyano group, a carboxyl group, or a hydroxyalkyl group in which some of the hydrogen atoms of the alkyl group have been substituted with fluorine atoms, although a hydroxyl group is particularly desirable.

Examples of the hydrocarbon group include linear or branched hydrocarbon groups (and preferably alkylene groups) of 1 to 10 carbon atoms, cyclic aliphatic hydrocarbon groups (cyclic groups), and the aforementioned aromatic hydrocarbon groups. These cyclic groups can be selected appropriately from the multitude of groups that have been proposed for the resins of resist compositions designed for use with ArF excimer lasers. Such a cyclic group is preferably a polycyclic group, and a polycyclic group of 7 to 30 carbon atoms is more preferable.

Of the various possibilities, structural units derived from an acrylate ester that includes an aliphatic polycyclic group containing a hydroxyl group, a cyano group, a carboxyl group or a hydroxyalkyl group in which some of the hydrogen atoms of the alkyl group have been substituted with fluorine atoms, and structural units derived from an acrylate ester that includes a phenolic group or a naphthol group are particularly desirable. Examples of polycyclic groups include groups in which two or more hydrogen atoms have been removed from a bicycloalkane, tricycloalkane, tetracycloalkane or the like. Specific examples include groups in which two or more hydrogen atoms have been removed from a polycycloalkane such as adamantane, norbornane, isobornane, tricyclodecane or tetracyclododecane. Of these polycyclic groups, groups in which two or more hydrogen atoms have been removed from adamantane, norbornane or tetracyclododecane are preferred industrially.

When the hydrocarbon group within the polar group-containing hydrocarbon group is a linear or branched hydrocarbon group of 1 to 10 carbon atoms, the structural unit (a3) is preferably a structural unit derived from a hydroxyethyl ester of acrylic acid. On the other hand, when the hydrocarbon group is a polycyclic group, structural units represented by formulas (a3-1), (a3-2) and (a3-3) shown below are preferable.

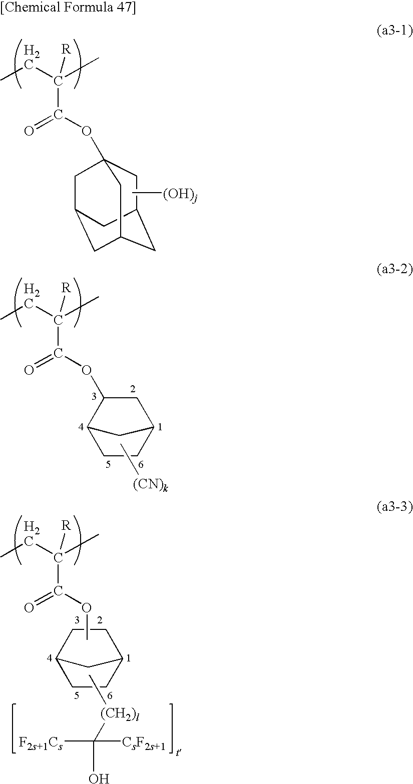

[In the formulas, R is the same as defined above; j is an integer of 1 to 3; k is an integer of 1 to 3; t′ is an integer of 1 to 3; l is an integer of 1 to 5; and s is an integer of 1 to 3.]

In formula (a3-1), j is preferably 1 or 2, and more preferably 1. When j is 2, it is preferable that the hydroxyl groups be bonded to the 3rd and 5th positions of the adamantyl group. When j is 1, it is preferable that the hydroxyl group be bonded to the 3rd position of the adamantyl group.

j is preferably 1, and it is particularly desirable that the hydroxyl group be bonded to the 3rd position of the adamantyl group.

In formula (a3-2), k is preferably 1. The cyano group is preferably bonded to the 5th or 6th position of the norbornyl group.

In formula (a3-3), t′ is preferably 1, l is preferably 1, and s is preferably 1. Further, in formula (a3-3), it is preferable that a 2-norbonyl group or 3-norbonyl group be bonded to the terminal of the carboxyl group of the acrylic acid. The fluorinated alkyl alcohol is preferably bonded to the 5th or 6th position of the norbornyl group.

As the structural unit (a3), one type of structural unit may be used alone, or two or more types of structural units may be used in combination.

In those cases where the structural unit (a3) is included in the polymer chain Y, in the polymer chain Y, the amount of the structural unit (a3) based on the combined total of all structural units constituting the polymer chain Y is preferably 5 to 50 mol %, more preferably 5 to 40 mol %, and still more preferably 5 to 25 mol %.

(Other Structural Units)

The polymer chain Y may also have another structural unit other than the above-mentioned structural units (a1), (a2), (a3), (a5), (a6) and (a7), as long as the effects of the present invention are not impaired.

As another structural unit, any other structural unit which cannot be classified as one of the above-mentioned structural units (a1), (a2), (a3), (a5), (a6) and (a7) can be used without any particular limitations, and any of the multitude of conventional structural units used within resist resins for ArF excimer lasers or KrF excimer lasers (and particularly for ArF excimer lasers) can be used.

For example, a structural unit derived from an acrylate ester containing a non-acid dissociable, aliphatic polycyclic group (hereafter, referred to as “structural unit (a4)”), a structural unit derived from a vinyl naphthalene monomer (more preferably a vinyl naphthol-based structural unit) or the like is preferable. Examples of this polycyclic group include the same groups as those described above in connection with the aforementioned structural unit (a1), and any of the multitude of conventional polycyclic groups used within the resin component of resist compositions for ArF excimer lasers or KrF excimer lasers (and particularly for ArF excimer lasers) can be used.

In consideration of industrial availability and the like, at least one polycyclic group selected from amongst a tricyclodecyl group, adamantyl group, tetracyclododecyl group, isobornyl group, and norbornyl group is particularly desirable. These polycyclic groups may be substituted with a linear or branched alkyl group of 1 to 5 carbon atoms.

Specific examples of the structural unit (a4) include units with structures represented by general formulas (a4-1) to (a4-5) shown below.

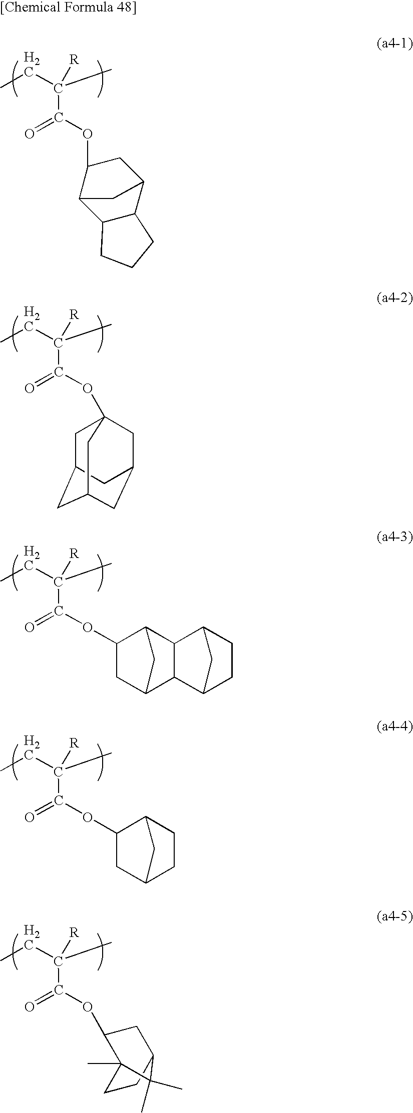

[In the formulas, R is the same as defined above.]

In those cases where the structural unit (a4) is included in the polymer chain Y, the amount of the structural unit (a4) based on the combined total of all structural units constituting the polymer chain Y is preferably within a range from 1 to 30 mol %, and more preferably from 10 to 20 mol %.

In the present invention, the polymer chain Y preferably includes the structural units (a5) and (a7), and may further include the structural units (a1), (a2), (a3) and (a6).

Examples of such copolymers include a copolymer composed of the structural units (a5) and (a7); and a copolymer composed of the structural units (a5), (a6) and (a7).

As the polymer chain Y, those that include two types of structural units represented by general formula (a-11) shown below are particularly desirable.

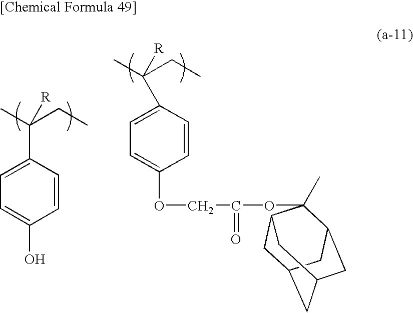

[In the formula, R is the same as defined above, and the plurality of R may be either the same or different from each other.]

In formula (a-11), R is the same as defined above.

The weight average molecular weight (Mw) (the polystyrene equivalent value determined by gel permeation chromatography) of the polymer chain Y in the arm portion of the component (A11) is not particularly limited, but is preferably 300 to 50,000, more preferably 500 to 3,000, and most preferably 500 to 1,500. By ensuring that the weight average molecular weight is no more than the upper limit of the above-mentioned range, the polymer chain Y exhibits satisfactory solubility in a resist solvent when used as a resist. On the other hand, by ensuring that the weight average molecular weight is at least as large as the lower limit of the above-mentioned range, dry etching resistance and cross-sectional shape of the resist pattern becomes satisfactory.

Further, the dispersity (Mw/Mn) is preferably 1.0 to 5.0, more preferably 1.0 to 3.0, and most preferably 1.2 to 2.5. Here, Mn is the number average molecular weight.

### [X: Divalent Linking Group]

In general formula (1), X represents a divalent linking group having an acid dissociable group.

As the acid dissociable group for X, a group in which one or more hydrogen atoms have been removed from a tertiary alkyl group-containing group or a group in which one or more hydrogen atoms have been removed from an alkoxyalkyl group can be used.

Examples of the group in which one or more hydrogen atoms have been removed from a tertiary alkyl group-containing group include a group in which one or more hydrogen atoms have been removed from the tertiary alkyl group-containing group described above for (a7); and a group in which one or more hydrogen atoms have been removed from the tertiary alkyl ester-type acid dissociable, dissolution inhibiting group described above for (a1).

More specifically,

a group in which one or more hydrogen atoms have been removed from the alkyl group for R²¹ to R²³ in the formula (III) above;

a group in which one or more hydrogen atoms have been removed from the aliphatic cyclic group for R^{C} in the formula (p0) or (p0-1) above;

a group in which one or more hydrogen atoms have been removed from adamantane in the formula (p0-1-1) above;

a group in which one or more hydrogen atoms have been removed from the aliphatic cyclic group in the formulas (11) to (24) above; or the like can be used.

Examples of the group in which one or more hydrogen atoms have been removed from an alkoxyalkyl group include a group in which one or more hydrogen atoms have been removed from the alkoxyalkyl group described above for (a7); and a group in which one or more hydrogen atoms have been removed from the acetal-type acid dissociable, dissolution inhibiting group described above for (a1).

More specifically,

a group in which one or more hydrogen atoms have been removed from X⁰ in the formula (VII-a) above;

a group in which one or more hydrogen atoms have been removed from X⁰ in the formula (VII-b) above; and

a group in which one or more hydrogen atoms have been removed from the aliphatic cyclic group in the formulas (p3-3) to (p3-12) above; or the like can be used.

Further, as the divalent linking group having an acid dissociable group for X in the arm portion of the component (A11), an acid dissociable group as mentioned above, and the same divalent linking group as the aforementioned divalent linking group of the linkage portion connecting the plurality of core portions may be used in combination.

Further, the degree of dispersion (Mw/Mn) of the component (A1) is preferably from 1.01 to 5.00, and more preferably from 1.01 to 2.00. By ensuring that the degree of dispersion (Mw/Mn) of the component (A1) is no more than the upper limit of the above-mentioned range, the component (A1) exhibits satisfactory solubility in a resist solvent when used for a resist.

The Mn of the component (A1) is preferably from 1,000 to 1,000,000, more preferably from 1,500 to 500,000, still more preferably from 1,500 to 50,000, and particularly preferably from 2,000 to 20,000. When the Mn of the component (A1) is within the above-mentioned range, the effects of the present invention are improved.

Further, the degree of dispersion (Mw/Mn) of the component (A11) is preferably from 1.01 to 5.00, and more preferably from 1.01 to 2.00. By ensuring that the degree of dispersion (Mw/Mn) of the component (A11) is no more than the upper limit of the above-mentioned range, the component (A11) exhibits satisfactory solubility in a resist solvent when used for a resist.

The Mn of the component (A11) is preferably from 1,000 to 1,000,000, more preferably from 1,500 to 500,000, still more preferably from 1,500 to 50,000, and particularly preferably from 2,000 to 20,000. When the Mn of the component (A11) is within the above-mentioned range, the effects of the present invention are improved.

In the component (A1), as the component (A11), one type may be used alone, or two or more types may be used in combination.

In those cases where the component (A1) includes the component (A11), the amount of the component (A11) within the component (A1) based on the total weight of the component (A1) is preferably 10% by weight or more, more preferably 15% by weight or more, still more preferably 20% by weight or more, and may be even 100% by weight. When the amount of the component (A11) is 10% by weight or more, the effects of the present invention such as the lithography properties are improved.

### [Component (A12)]

### <<Core Portion>>

In the component (A12) of the present invention, the core portion is constituted of a polymer having a molecular weight within a range from 500 to 20,000 (hereafter, referred to as a “core polymer P”).

The component (A12) is constituted of the core polymer P to which at least one —(X)—Y moiety represented by general formula (1) above is introduced. In other words, the core polymer P can be obtained by removing the —(X)—Y moieties represented by general formula (1) from the component (A12).

As the core polymer P, there is no particular limitation, and any of the known polymers typically used as a base material component for a chemically amplified resist can be used.

The core polymer P preferably includes a structural unit (ap1) represented by general formula (ap1) shown below.

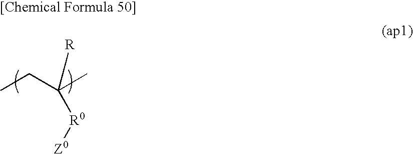

[In the formula, R represents a hydrogen atom, an alkyl group of 1 to 5 carbon atoms or a halogenated alkyl group of 1 to 5 carbon atoms; R¹ represents a divalent linking group; and Z¹ represents —OH, —COOH, or a linking arm in the formula (1) above.]
(Structural Unit (ap1))

In formula (ap1), R is the same as defined above, and is preferably a hydrogen atom or a methyl group.

In formula (ap1), R⁰ represents a divalent linking group, examples thereof include the same groups as those described for the aforementioned divalent linking group of the linkage portion connecting the plurality of core portions.

In the present invention, as the divalent linking group for R⁰, a divalent aromatic group or a divalent linking group containing a hetero atom is preferable, a divalent aromatic group, a combination of a divalent linking group and —C(═O)—O—, or —C(═O)— is more preferable, and a divalent aromatic group (for example, an aromatic hydrocarbon group in which one hydrogen atom has been removed from a phenyl group, or an aromatic hydrocarbon group in which one hydrogen atom has been removed from a naphthyl group) is most preferable.

In formula (ap1) above, Z⁰ represents —OH, —COOH, or a linking arm in the formula (1) above, and is preferably —OH or a linking arm in the formula (1) above.

As the structural unit (ap1), one type of structural unit may be used alone, or two or more types of structural units may be used in combination.

In the core polymer P, the amount of structural unit (ap1) based on the combined total of all structural units constituting the core polymer P is preferably 5 to 100 mol %.

In those cases where Z⁰ of the structural unit (ap1) in the core polymer P represents a linkage in the formula (1) above, the amount of structural unit (ap1) in the core polymer P is preferably 5 mol % or more, more preferably 10 mol % or more, still more preferably 25 mol % or more, and may be even 100 mol %.

The core polymer P may also have another structural unit other than the structural unit (ap1), as long as the effects of the present invention are not impaired.

As such structural units, structural units (a1) to (a4), (a6), (a7) and the like to be described above can be used (excluding those that correspond to the structural unit (ap1)).

In the component (A12) of the present invention, the core polymer P is preferably a polymer that includes a structural unit (ap1), more preferably a polymer that includes a structural unit represented by general formula (P1) or (P2) shown below, and most preferably a polymer that includes a structural unit represented by general formula (P11) or (P21) shown below.

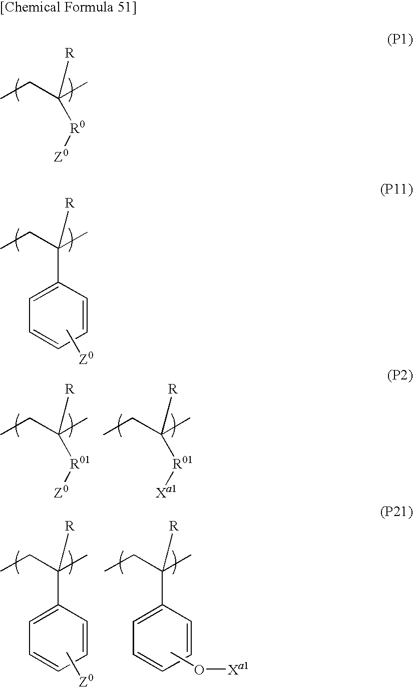

[In the formulas, R and Z⁰ are the same as defined above; R⁰¹ represents a divalent aromatic group; and X^{a1} represents an acid dissociable, dissolution inhibiting group described in the aforementioned structural unit (a1).]

In the formulas (P1) and (P2), the divalent aromatic group for R⁰¹ is the same as the aromatic group for R⁰ defined above, and an aromatic hydrocarbon group in which one hydrogen atom has been removed from a phenyl group, or an aromatic hydrocarbon group in which one hydrogen atom has been removed from a naphthyl group is particularly desirable.

In the formulas (P2) and (P21), preferable examples of X^{a1} include those represented by the aforementioned formulas (p0), (p0-1), (p1), (p1-1) and (p2).

The weight average molecular weight (Mw) (the polystyrene equivalent value determined by gel permeation chromatography) of the core polymer P is from 500 to 20,000, preferably from 500 to 10,000, and more preferably from 500 to 4,000. When the weight average molecular weight is no more than the upper limit of the above-mentioned range, the core polymer P exhibits a satisfactory solubility in a resist solvent when used for a resist. On the other hand, when the weight average molecular weight is at least as large as the lower limit of the above-mentioned range, dry etching resistance and the cross-sectional shape of the resist pattern becomes satisfactory.

Further, the degree of dispersion (Mw/Mn) of the core polymer P is not particularly limited, but is preferably from 1.0 to 5.0, and more preferably from 1.0 to 3.5. Here, Mn is the number average molecular weight.

### <<Arm Portion>>

In the component (A12) of the present invention, the arm portion is bonded to the core portion and is also represented by general formula (1) above.

As the divalent linking group having an acid dissociable group for X in the arm portion of the component (A12), the same groups as those described above for X in the arm portion of the component (A11) can be used. Among these, it is particularly desirable that X include a group in which one or more hydrogen atoms have been removed from an alkoxyalkyl group.

As the polymer chain Y in the arm portion of the component (A12), the same groups as those described above for the polymer chain Y in the arm portion of the component (A11) can be used. In a plurality of arm portions in the component (A12), the polymer chains Y may be the same with each other or may be different from each other, and preferably be the same with each other, as the effects of the present invention become particularly excellent.

The weight average molecular weight (Mw) (the polystyrene equivalent value determined by gel permeation chromatography) of the polymer chain Y in the arm portion of the component (A12) is preferably from 100 to 5,000, more preferably from 300 to 3,000, and still more preferably from 500 to 2,000. When the weight average molecular weight is no more than the upper limit of the above-mentioned range, the polymer chain Y exhibits a satisfactory solubility in a resist solvent when used for a resist. On the other hand, when the weight average molecular weight is at least as large as the lower limit of the above-mentioned range, dry etching resistance and the cross-sectional shape of the resist pattern becomes satisfactory.

Further, the degree of dispersion (Mw/Mn) of the polymer chain Y is not particularly limited, but is preferably from 1.0 to 5.0, and more preferably from 1.0 to 3.5. Here, Mn is the number average molecular weight.

In the present invention, as the polymeric compound (A12), a polymeric compound represented by general formula (A12-1) shown below is preferable.

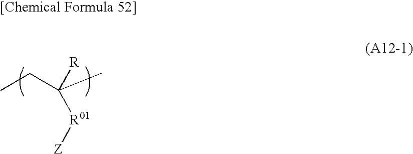

[In formula, R and R⁰¹ are the same as defined above; Z represents —OH, —COOH, a group represented by the formula (1) above, or a group in which the hydrogen atom in —OH or —COOH has been replaced with an acid dissociable, dissolution inhibiting group (excluding the group represented by the formula (1) above); with the proviso that in a plurality of arm portions within the polymeric compound (A12), R and Z may be the same with each other or may be different from each other, and one or more Z is a group represented by the formula (1) above.]

In a plurality of arm portions within the polymeric compound (A12), in those cases where each Z represents a different group and both of —OH and —COOH groups are included, part or all of the hydrogen atoms of only one of these groups may be replaced with an acid dissociable, dissolution inhibiting group, or part or all of the hydrogen atoms of both of these groups may be replaced with an acid dissociable, dissolution inhibiting group.

More specifically, as the polymeric compound represented by general formula (A12-1) above, a polymeric compound having a structural unit represented by general formulas (A12-11) and (A12-12) shown below is preferable.

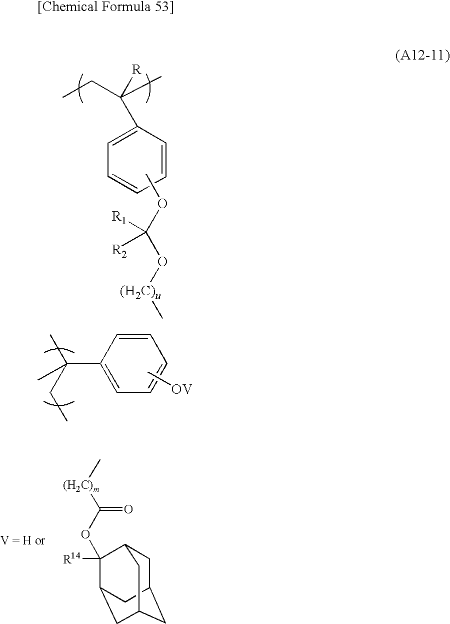

[In the formula, R, R⁵³, R⁵⁴, m and R¹⁴ are the same as defined above; u represents an integer of 0 to 10; V is as shown in the formula; and the plurality of R in the formula may be either the same or different from each other.]

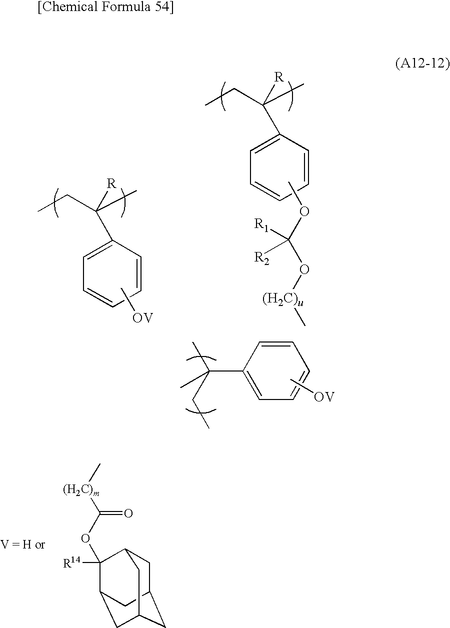

[In the formula, R, R⁵³, R⁵⁴, m and R¹⁴ are the same as defined above; u represents an integer of 0 to 10; V is as shown in the formula; and the plurality of R in the formula may be either the same or different from each other.]

In formulas (A12-11) and (A12-12), u represents an integer of 0 to 10, preferably an integer of 0 to 5, and more preferably an integer of 0 to 2.

The component (A12) may have an acid dissociable, dissolution inhibiting group in the core portion, or may have an acid dissociable, dissolution inhibiting group in the polymer chain Y in the arm portion. It is preferable that the component (A12) either have an acid dissociable, dissolution inhibiting group in the polymer chain Y in the arm portion, or have an acid dissociable, dissolution inhibiting group in both the core portion and the polymer chain Y in the arm portion. In the component (A12), the amount of the structural unit have an acid dissociable, dissolution inhibiting group based on the combined total of all structural units constituting the component (A12) is preferably 5 to 50 mol %, more preferably 10 to 40 mol %, still more preferably 12 to 40 mol %, and most preferably 14 to 35 mol %. By ensuring that the amount of the above-mentioned structural unit is at least as large as the lower limit of the above-mentioned range, a pattern can be easily formed using a positive resist composition prepared from the component (A12). On the other hand, by ensuring that the amount of the structural unit is no more than the upper limit of the above-mentioned range, a good balance can be achieved with the other structural units.

The component (A12) may have an OH-containing group in the core portion, or may have an OH-containing group in the polymer chain Y in the arm portion. It is preferable that the component (A12) either have an OH-containing group in the polymer chain Y in the arm portion, or have an OH-containing group in both the core portion and the polymer chain Y in the arm portion. In the component (A12), the amount of the structural unit having an OH-containing group (i.e., the structural unit (ap1) in which Z⁰ represents either —OH or —COOH; the structural unit (a3) in which a polar group represents —OH; and the structural unit (a5)) based on the combined total of all structural units constituting the component (A12) is preferably 50 to 90 mol %, more preferably 55 to 90 mol %, and still more preferably 60 to 88 mol %. By making the amount of the structural unit having an OH-containing group at least as large as the lower limit of the above-mentioned range, an adequate level of alkali solubility can be achieved. On the other hand, when the amount of the structural unit having an OH-containing group is no more than the upper limit of the above-mentioned range, a good balance can be achieved with the other structural units.

The weight average molecular weight (Mw) (the polystyrene equivalent value determined by gel permeation chromatography) of the component (A12) is not particularly limited, but is preferably 1,000 to 50,000, more preferably 1,500 to 30,000, and most preferably 2,500 to 20,000. When the weight average molecular weight is no more than the upper limit of the above-mentioned range, the component (A12) exhibits a satisfactory solubility in a resist solvent when used for a resist. On the other hand, when the weight average molecular weight is at least as large as the lower limit of the above-mentioned range, dry etching resistance and the cross-sectional shape of the resist pattern becomes satisfactory.

Further, the dispersity (Mw/Mn) of the component (A12) is not particularly limited, but is preferably 1.0 to 5.0, more preferably 1.0 to 3.0, and most preferably 1.0 to 2.5. Here, Mn is the number average molecular weight.

In the component (A1), as the component (A12), one type may be used alone, or two or more types may be used in combination.

In those cases where the component (A1) includes the component (A12), the amount of the component (A12) within the component (A1) based on the total weight of the component (A1) is preferably 25% by weight or more, more preferably 50% by weight or more, still more preferably 75% by weight or more, and may be even 100% by weight. When the amount of the component (A12) is 25% by weight or more, the effects of the present invention such as the lithography properties are improved.

As a component included in the component (A1) other than the components (A11) and (A12) described above, a linear type, polymeric compound component (A13) (hereafter, frequently referred to as “component (A13)”) which includes none of the core portions described above can be used.

The component (A13) is a resin component containing an acid dissociable, dissolution inhibiting group. Examples thereof include a resin component having any one of the structural units selected from the group of structural units (a5), (a7), (a6), (a1), (a2), (a3) and (a4) described above in relation to the polymer chain Y, and a copolymer constituted of the structural units (a5) and (a7) is preferable. In the copolymer, the structural unit (a7) has an acid dissociable, dissolution inhibiting group.

In those cases where the component (A1) includes the component (A13), the amount of the component (A13) within the component (A1) based on the total weight of the component (A1) is preferably 25% by weight or more, and more preferably 50% by weight or more. When the amount of the component (A13) is 25% by weight or more, the effects of the present invention such as the lithography properties are improved.

In the present invention, the component (A1) preferably includes the component (A11) or the component (A12), and may further include the component (A13). Preferable examples of the component (A1) include those constituted only of the component (A11); those constituted only of the component (A12); those constituted of the components (A11) and (A13); and those constituted of the components (A12) and (A13).

In the component (A), as the polymeric compound (A1), one type of compound may be used alone, or two or more types of compounds may be used in combination.

The proportion of the polymeric compound (A1) within the component (A) is preferably 50% by weight or more, more preferably 70% by weight or more, still more preferably 80% by weight or more, and most preferably 100% by weight.

### [Component (A2)]

As the component (A2), it is preferable to use a low molecular weight compound that has a molecular weight of at least 500 and less than 4,000, contains a hydrophilic group, and also contains an acid dissociable, dissolution inhibiting group described above in connection with the component (A1). Specific examples include compounds containing a plurality of phenol skeletons in which a part of the hydrogen atoms within hydroxyl groups have been substituted with the aforementioned acid dissociable, dissolution inhibiting groups.

Examples of the component (A2) include low molecular weight phenolic compounds in which a portion of the hydroxyl group hydrogen atoms have been substituted with an aforementioned acid dissociable, dissolution inhibiting group, and these types of compounds are known, for example, as sensitizers or heat resistance improvers for use in non-chemically amplified g-line or i-line resists.

Examples of these low molecular weight phenolic compounds include bis(4-hydroxyphenyl)methane, bis(2,3,4-trihydroxyphenyl)methane, 2-(4-hydroxyphenyl)-2-(4′-hydroxyphenyl)propane, 2-(2,3,4-trihydroxyphenyl)-2-(2′,3′,4′-trihydroxyphenyl)propane, tris(4-hydroxyphenyl)methane, bis(4-hydroxy-3,5-dimethylphenyl)-2-hydroxyphenylmethane, bis(4-hydroxy-2,5-dimethylphenyl)-2-hydroxyphenylmethane, bis(4-hydroxy-3,5-dimethylphenyl)-3,4-dihydroxyphenylmethane, bis(4-hydroxy-2,5-dimethylphenyl)-3,4-dihydroxyphenylmethane, bis(4-hydroxy-3-methylphenyl)-3,4-dihydroxyphenylmethane, bis(3-cyclohexyl-4-hydroxy-6-methylphenyl)-4-hydroxyphenylmethane, bis(3-cyclohexyl-4-hydroxy-6-methylphenyl)-3,4-dihydroxyphenylmethane, 1-[1-(4-hydroxyphenyl)isopropyl]-4-[1,1-bis(4-hydroxyphenyl)ethyl]benzene, and dimers to hexamers of formalin condensation products of phenols such as phenol, m-cresol, p-cresol and xylenol. It goes without saying that the low molecular weight phenolic compound is not limited to these examples. Among these, in terms of achieving excellent resolution and line width roughness (LWR), a phenolic compound having 2 to 6 triphenylmethane skeletons is particularly desirable.

Also, there are no particular limitations on the acid dissociable, dissolution inhibiting group, and suitable examples include the groups described above.

As the component (A2), one type of compound may be used alone, or two or more types of compounds may be used in combination.

In the resist composition of the present invention, as the component (A), one type may be used alone, or two or more types may be used in combination.

Of the examples shown above, the component (A) preferably includes the component (A1), and more preferably includes the component (A11) or (A12).

In the resist composition of the present invention, the amount of the component (A) can be appropriately adjusted depending on the thickness of the resist film to be formed, and the like.

### (Method of Producing Component (A12))

The method of producing the component (A12) is not particularly limited and examples thereof include a method in which, using a polymer (hereafter, referred to as “polymer (P0)”) which serves as a coupling agent for anionic polymerization as a material for providing the core portion described above, the polymer (P0) is reacted with a polymer (hereafter, referred to as “polymer (Y0)”) for providing arm portions to synthesize a polymer (A12′), and all or some of the protecting groups which protect phenolic hydroxy groups in the polymer (A12′) are eliminated and, preferably, an acid dissociable, dissolution inhibiting group is introduced to produce the component (A12).

Such a method is preferable since it is easy to control each reaction and to control the structure of the component (A12).

More specifically, as the polymer (P0), a polymer that includes a structural unit represented by general formula (P00) shown below is preferable since the polymer exhibits an excellent reactivity with the polymer (Y0), which makes it easy to produce the component (A12).

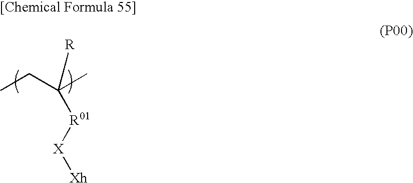

[In formula (P00), R, R⁰¹ and X are the same as defined above, respectively; and Xh represents a halogen atom or an epoxy group represented by general formula (6) shown below.]

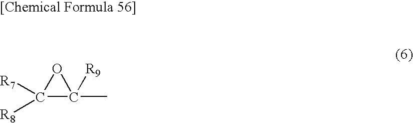

[In formula (6), each of R₇, R₈ and R₉ independently represents a hydrogen atom or an alkyl group of 1 to 12 carbon atoms.]

Xh represents a halogen atom or an epoxy group represented by the general formula (6) above. Examples of the halogen atom include a chlorine atom, a bromine atom and an iodine atom. Of these, a chlorine atom or a bromine atom is preferable, and a bromine atom is particularly desirable.

In general formula (6) above, it is preferable that each of R₇, R₈ and R₉ independently represent a hydrogen atom or an alkyl group of 1 to 5 carbon atoms.

A method of producing a polymer that includes a structural unit represented by general formula (P00) above is not particularly limited and, for example, the polymer can be produced by reacting polyhydroxystyrene with a chloromethyl halogen-substituted alkylether. Thereafter, if necessary, a Cl atom may be replaced with a Br atom, or an ethoxyethyl group may be introduced with respect to unsubstituted hydroxystyrene.

Preferable examples of the polymers that include a structural unit represented by general formula (P00) above include polymers represented by formulas (P0-1) to (P0-3) shown below.

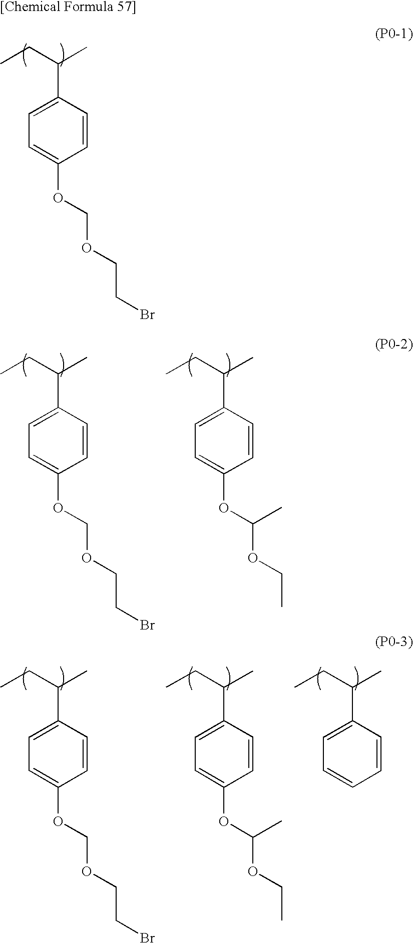

Next, as the polymer (Y0), there are no particular limitations. However, for example, a polymer obtained by an anionic polymerization reaction of a monomer (hydroxystyrene derivative compound) that provides the structural unit (a5) and, if desired, an anionically polymerizable monomer that provides other structural units in the presence of an anionic polymerization initiator.

Examples of the anionic polymerization initiator include an alkali metal atom or an organic alkali metal compound.

Examples of the alkali metal atom include lithium, sodium, potassium and cesium atoms.

As the organic alkali metal compound, alkylated, allylated and arylated compounds of the above alkali metal atoms can be used. Specific examples thereof include ethyl lithium, n-butyl lithium, s-butyl lithium, t-butyl lithium, ethyl sodium, lithium biphenyl, lithium naphthalene, lithium triphenyl, sodium naphthalene, a-methylstyrene sodium dianion, 1,1-diphenylhexyl lithium and 1,1-diphenyl-3-methylpentyl lithium.

An anionic polymerization method of synthesizing the polymer (Y0) that provides arm portions can be conducted either by a method of dropwise adding an anionic polymerization initiator to a monomer solution or a monomer mixed solution, or by a method of dropwise adding a monomer solution or a monomer mixed solution to a solution containing an anionic polymerization initiator. Of these methods, a method of dropwise adding a monomer solution or a monomer mixed solution to a solution containing an anionic polymerization initiator is preferable, as it is easy to control the molecular weight and molecular weight distribution.

The anionic polymerization method of synthesizing the polymer (Y0) is preferably conducted under an atmosphere of an inert gas such as nitrogen or argon in an organic solvent at a temperature of −100 to 50° C., and more preferably at a temperature of −100 to 40° C.

Examples of the organic solvent used in the anionic polymerization method of synthesizing the polymer (Y0) include organic solvents typically used in an anionic polymerization method, for example, aliphatic hydrocarbons such as n-hexane and n-heptane; alicyclic hydrocarbons such as cyclohexane and cyclopentane; aromatic hydrocarbons such as benzene and toluene; ethers such as diethylether, tetrahydrofuran (THF) and dioxane; anisole, hexamethylphosphoramide and the like. Of these, toluene, n-hexane and THF are preferable.

These organic solvents can be used individually, or in combination as a mixed solvent.

When the polymer (Y0) that provides arm portions is a copolymer, the polymer can be in any polymer form such as a random copolymer, a partial block copolymer or a complete block copolymer. These polymers can be appropriately synthesized by selecting the method of adding a monomer used for polymerization.

The reaction of linking the polymer (Y0) with the polymer (P0) to synthesize the polymer (A12′) can be conducted by adding the polymer (P0) in the polymerization reaction solution after completion of the anionic polymerization of synthesizing the polymer (Y0).

Such a reaction is preferably conducted under an atmosphere of an inert gas such as nitrogen or argon in an organic solvent at a temperature of −100 to 50° C., and more preferably at a temperature of −80 to 40° C. As a result, the structure of the polymer (A12′) can be controlled and also a polymer having a narrow molecular weight distribution can be obtained.

Further, the synthesis reaction of the polymer (A12′) can be continuously conducted in an organic solvent used in the anionic polymerization reaction of synthesizing the polymer (Y0) that provides arm portions, and also can be conducted after changing the composition by newly adding a solvent, or replacing the solvent with another solvent. The solvent, which can be used herein, may be the same organic solvent as that used in the anionic polymerization reaction of synthesizing the polymer (Y0) that provides arm portions.

The reaction of removing the protecting groups that protect the phenolic hydroxy groups or the like from the polymer (A12′) obtained in this manner is preferably conducted in the presence of a single solvent or a mixed solvent of two or more solvents selected from the solvents mentioned above in the polymerization reaction; alcohols such as methanol and ethanol; ketones such as acetone, methyl ethyl ketone and methyl isobutyl ketone (MIBK); polyhydric alcohol derivatives such as methyl cellosolve and ethyl cellosolve; and water, at a temperature within a range from room temperature to 150° C. using an acidic reagent as a catalyst, such as hydrochloric acid, sulfuric acid, oxalic acid, hydrogen chloride gas, hydrobromic acid, p-toluenesulfonic acid, 1,1,1-trifluoroacetic acid, and bisulfates represented by LiHSO₄, NaHSO₄ or KHSO₄. All or some of the protecting groups that protect the phenolic hydroxy groups can be removed by appropriately combining the types and concentrations of solvents, the types and added amounts of catalysts, and the reaction temperatures and reaction times in this reaction.

When the arm portions of the polymer (A12′) include a structural unit derived from an acrylate ester, ester groups of the structural unit can be converted into carboxy groups by hydrolysis.

The hydrolysis can be conducted by a method known in the relevant technical field and, for example, conducted by acid hydrolysis under the same conditions as those mentioned above for removing the protecting groups. The hydrolysis of the ester groups is preferably conducted simultaneously with the removal of the protecting groups of phenolic hydroxyl groups. The polymer (A12′) obtained in this manner which includes a structural unit derived from an acrylate ester in the arm portion is particularly suitable as a resist material since it exhibits a high level of alkali solubility.

Furthermore, after removing the protecting groups that protect the phenolic hydroxy groups from the polymer (A12′), protecting groups such as the acid dissociable, dissolution inhibiting groups mentioned above in connection with the explanation of the structural unit (a1) may be newly introduced.

These protecting groups can be introduced by a known method (for example, a method of reacting a protecting group precursor compound containing a halogen atom in the presence of a basic catalyst).

The polymer (A12′) obtained by the above method can be used without being purified, or may be used after purification, if necessary.

The purification can be conducted by a method typically used in the relevant technical field and can be conducted, for example, by a fractional reprecipitation method. In the fractional reprecipitation method, reprecipitation is preferably conducted using a mixed solvent of a solvent exhibiting a high level of polymer solubility and a solvent exhibiting a low level of polymer solubility. For example, purification can be conducted by a method of dissolving the polymer (A12′) with heating in a mixed solvent, followed by cooling, or by a method of dissolving the polymer (A12′) in a solvent exhibiting a high level of polymer solubility, followed by the addition of a solvent exhibiting a low level of polymer solubility thereto to precipitate the polymer (A12′).

### <Component (B)>

As the component (B), there is no particular limitation, and any of the known acid generators used in conventional chemically amplified resist compositions can be used. Examples of these acid generators are numerous, and include onium salt-based acid generators such as iodonium salts and sulfonium salts; oxime sulfonate-based acid generators; diazomethane-based acid generators such as bisalkyl or bisaryl sulfonyl diazomethanes and poly(bis-sulfonyl)diazomethanes; nitrobenzylsulfonate-based acid generators; iminosulfonate-based acid generators; and disulfone-based acid generators.

As an onium salt-based acid generator, for example, a compound represented by general formula (b-1) or (b-2) shown below can be used.

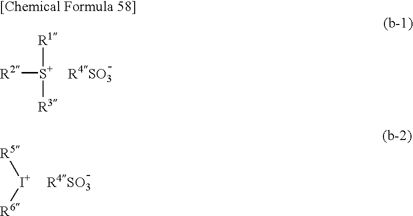

In the formulas above, R¹″ to R³″, R⁵″ and R⁶″ each independently represents an aryl group or alkyl group, wherein two of R¹″ to R³″ in formula (b-1) may be bonded to each other to form a ring with the sulfur atom in the formula; and R⁴″ represents an alkyl group, a halogenated alkyl group, an aryl group or an alkenyl group which may have a substituent, with the proviso that at least one of R¹″ to R³″ represents an aryl group, and at least one of R⁵″ and R6″ represents an aryl group.

In formula (b-1), R¹″ to R³″ each independently represents an aryl group or an alkyl group. In formula (b-1), two of R¹″ to R³″ may be bonded to each other to form a ring with the sulfur atom in the formula.

Further, among R¹″ to R³″, at least one group represents an aryl group. Among R¹″ to R³″, two or more groups are preferably aryl groups, and it is particularly desirable that all of R¹″ to R³″ are aryl groups.

R″ The aryl group for R^{1″} to R^{3″} is not particularly limited. For example, an aryl group having 6 to 20 carbon atoms may be used in which part or all of the hydrogen atoms of the aryl group may or may not be substituted with alkyl groups, alkoxy groups, halogen atoms or hydroxyl groups.

The aryl group is preferably an aryl group having 6 to 10 carbon atoms because it can be synthesized at a low cost. Specific examples thereof include a phenyl group and a naphthyl group.

The alkyl group, with which hydrogen atoms of the aryl group may be substituted, is preferably an alkyl group having 1 to 5 carbon atoms, and most preferably a methyl group, an ethyl group, a propyl group, an n-butyl group, or a tert-butyl group.

The alkoxy group, with which hydrogen atoms of the aryl group may be substituted, is preferably an alkoxy group having 1 to 5 carbon atoms, more preferably a methoxy group, an ethoxy group, an n-propoxy group, an iso-propoxy group, an n-butoxy group or a tert-butoxy group, and most preferably a methoxy group or an ethoxy group.

The halogen atom, with which hydrogen atoms of the aryl group may be substituted, is preferably a fluorine atom.

The alkyl group for R^{1″} to R^{3″} is not particularly limited and includes, for example, a linear, branched or cyclic alkyl group having 1 to 10 carbon atoms. In terms of achieving excellent resolution, the alkyl group preferably has 1 to 5 carbon atoms. Specific examples thereof include a methyl group, an ethyl group, a n-propyl group, an isopropyl group, a n-butyl group, an isobutyl group, a n-pentyl group, a cyclopentyl group, a hexyl group, a cyclohexyl group, a nonyl group, and a decyl group, and a methyl group is most preferable because it is excellent in resolution and can be synthesized at a low cost.

When two of R¹″ to R³″ in formula (b-1) are bonded to each other to form a ring with the sulfur atom in the formula, it is preferable that the two of R¹″ to R³″ form a 3 to 10-membered ring including the sulfur atom, and it is particularly desirable that the two of R¹″ to R³″ form a 5 to 7-membered ring including the sulfur atom.

When two of R¹″ to R³″ in formula (b-1) are bonded to each other to form a ring with the sulfur atom in the formula, the remaining one of R¹″ to R³″ is preferably an aryl group. As examples of the aryl group, the same as the above-mentioned aryl groups for R¹″ to R³″ can be given.

As preferable examples of the cation moiety for the compound represented by general formula (b-1), those represented by formulas (I-1-1) to (I-1-10) shown below can be given. Among these, a cation moiety having a triphenylmethane skeleton, such as a cation moiety represented by any one of formulas (I-1-1) to (I-1-8) shown below is particularly desirable.

As the cation moiety of onium salt-based acid generators, the cation moiety represented by formulas (I-1-9) and (I-1-10) shown below is also preferable.

In formulas (I-1-9) and (I-1-10), each of R⁹ and R¹⁰ independently represents a phenyl group or naphthyl group which may have a substituent, an alkyl group of 1 to 5 carbon atoms, an alkoxy group or a hydroxy group.

u′ is an integer of 1 to 3, and most preferably 1 or 2.

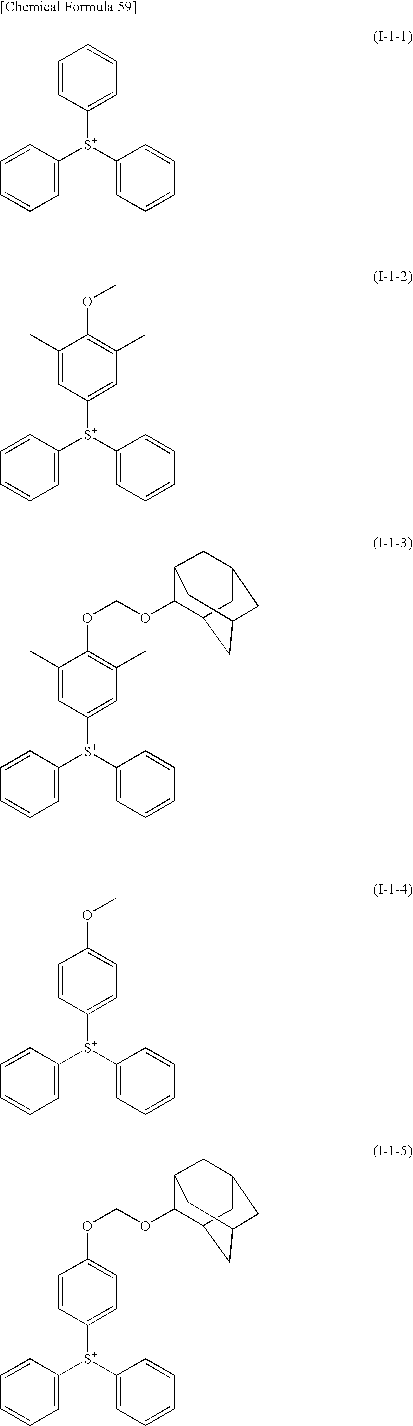

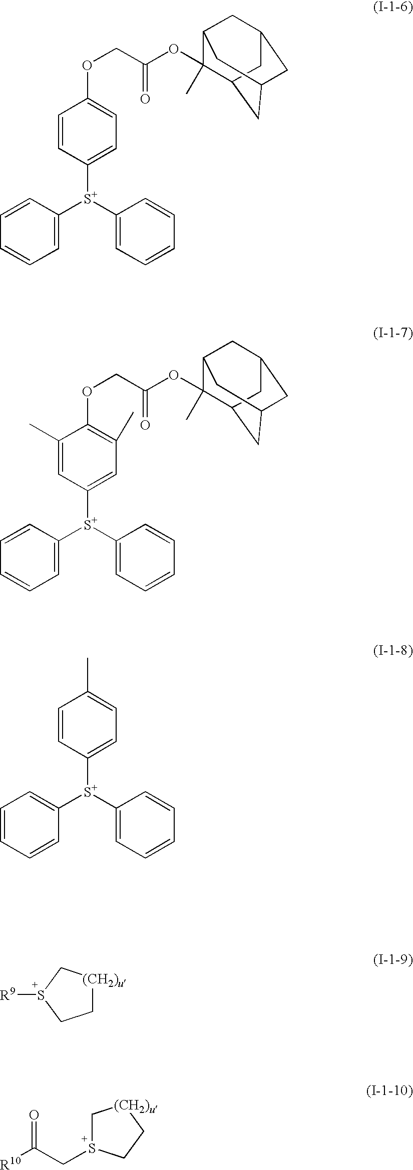

R⁴″ represents an alkyl group, a halogenated alkyl group, an aryl group or an alkenyl group which may have a substituent.

The alkyl group for R⁴″ may be any of linear, branched or cyclic.

The linear or branched alkyl group preferably has 1 to 10 carbon atoms, more preferably 1 to 8 carbon atoms, and most preferably 1 to 4 carbon atoms.

The cyclic alkyl group preferably has 4 to 15 carbon atoms, more preferably 4 to 10 carbon atoms, and most preferably 6 to 10 carbon atoms.

As an example of the halogenated alkyl group for R⁴″, a group in which part of or all of the hydrogen atoms of the aforementioned linear, branched or cyclic alkyl group have been substituted with halogen atoms can be given. Examples of the aforementioned halogen atom include a fluorine atom, a chlorine atom, a bromine atom and an iodine atom, and a fluorine atom is preferable.

In the halogenated alkyl group, the percentage of the number of halogen atoms based on the total number of halogen atoms and hydrogen atoms (halogenation ratio (%)) is preferably 10 to 100%, more preferably 50 to 100%, and most preferably 100%. Higher halogenation ratio is preferable because the acid strength increases.

The aryl group for R⁴″ is preferably an aryl group of 6 to 20 carbon atoms.

The alkenyl group for R⁴″ is preferably an alkenyl group of 2 to 10 carbon atoms.

With respect to R⁴″, the expression “may have a substituent” means that part of or all of the hydrogen atoms within the aforementioned linear, branched or cyclic alkyl group, halogenated alkyl group, aryl group or alkenyl group may be substituted with substituents (atoms other than hydrogen atoms, or groups).

R⁴″ may have one substituent, or two or more substituents.

Examples of the substituent include a halogen atom, a hetero atom, an alkyl group, and a group represented by the formula X^{a}-Q¹- (in the formula, Q¹ represents a divalent linking group containing an oxygen atom; and X^{a} represents a hydrocarbon group of 3 to 30 carbon atoms which may have a sub stituent).

Examples of halogen atoms and alkyl groups as substituents for R^{4″} include the same halogen atoms and alkyl groups as those described above with respect to the halogenated alkyl group for R⁴″.

Examples of the hetero atoms include an oxygen atom, a nitrogen atom, and a sulfur atom.

In the group represented by formula X^{a}-Q¹-, Q¹ represents a divalent linking group containing an oxygen atom.

Q¹ may contain an atom other than an oxygen atom. Examples of atoms other than an oxygen atom include a carbon atom, a hydrogen atom, a sulfur atom and a nitrogen atom.

Examples of divalent linking groups containing an oxygen atom include non-hydrocarbon, oxygen atom-containing linking groups such as an oxygen atom (an ether bond; —O—), an ester bond (—C(═O)—O—), an amide bond (—C(═O)—NH—), a carbonyl group (—C(═O)—) and a carbonate group (—O—C(═O)—O—); and combinations of the aforementioned non-hydrocarbon, oxygen atom-containing linking groups with an alkylene group.

Specific examples of the combinations of the aforementioned non-hydrocarbon, oxygen atom-containing linking groups and an alkylene group include —R⁹¹—O—, —R⁹²—O—C(═O)— and —C(═O)—O—R⁹³—O—C(═O)— (in the formulas, each of R⁹¹ to R⁹³ independently represents an alkylene group).

The alkylene group for R⁹¹ to R⁹³ is preferably a linear or branched alkylene group, and preferably has 1 to 12 carbon atoms, more preferably 1 to 5 carbon atoms, and most preferably 1 to 3 carbon atoms.

Specific examples of alkylene groups include a methylene group [—CH₂—]; alkylmethylene groups such as —CH(CH₃)—, —CH(CH₂CH₃)—, —C(CH₃)₂—, —C(CH₃)(CH₂CH₃)—, —C(CH₃)(CH₂CH₂CH₃)— and —C(CH₂CH₃)₂—; an ethylene group [—CH₂CH₂-]; alkylethylene groups such as —CH(CH₃)CH₂—, —CH(CH₃)CH(CH₃)—, —C(CH₃)₂CH₂— and —CH(CH₂CH₃)CH₂—; a trimethylene group (n-propylene group) [—CH₂CH₂CH₂—]; alkyltrimethylene groups such as —CH(CH₃)CH₂CH₂— and —CH₂CH(CH₃)CH₂—; a tetramethylene group [—CH₂CH₂CH₂CH₂—]; alkyltetramethylene groups such as —CH(CH₃)CH₂CH₂CH₂— and —CH₂CH(CH₃)CH₂CH₂—; and a pentamethylene group [—CH₂CH₂CH₂CH₂CH₂—].

Q¹ is preferably a divalent linking group containing an ester bond or ether bond, and more preferably a group of —R⁹¹—O—, —R⁹²—O—C(═O)— or —C(═O)—O—R⁹³—O—C(═O)—.

In the group represented by the formula X^{a}-Q¹-, the hydrocarbon group for X^{a} may be either an aromatic hydrocarbon group or an aliphatic hydrocarbon group.

The aromatic hydrocarbon group is a hydrocarbon group having an aromatic ring. The aromatic hydrocarbon ring preferably has 3 to 30 carbon atoms, more preferably 5 to 30 carbon atoms, still more preferably 5 to 20 carbon atoms, still more preferably 6 to 15 carbon atoms, and most preferably 6 to 12 carbon atoms. Here, the number of carbon atoms within a substituent(s) is not included in the number of carbon atoms of the aromatic hydrocarbon group.

Specific examples of aromatic hydrocarbon groups include an aryl group which is an aromatic hydrocarbon ring having one hydrogen atom removed therefrom, such as a phenyl group, a biphenyl group, a fluorenyl group, a naphthyl group, an anthryl group or a phenanthryl group; and an alkylaryl group such as a benzyl group, a phenethyl group, a 1-naphthylmethyl group, a 2-naphthylmethyl group, a 1-naphthylethyl group, or a 2-naphthylethyl group. The alkyl chain within the arylalkyl group preferably has 1 to 4 carbon atom, more preferably 1 or 2 carbon atoms, and most preferably 1 carbon atom.

The aromatic hydrocarbon group may have a substituent. For example, a part of the carbon atoms constituting the aromatic ring within the aromatic hydrocarbon group may be substituted with a hetero atom, or a hydrogen atom bonded to the aromatic ring within the aromatic hydrocarbon group may be substituted with a substituent.

In the former example, a heteroaryl group in which a part of the carbon atoms constituting the ring within the aforementioned aryl group has been substituted with a hetero atom such as an oxygen atom, a sulfur atom or a nitrogen atom, and a heteroarylalkyl group in which a part of the carbon atoms constituting the aromatic hydrocarbon ring within the aforementioned arylalkyl group has been substituted with the aforementioned hetero atom can be used.

In the latter example, as the sub stituent for the aromatic hydrocarbon group, an alkyl group, an alkoxy group, a halogen atom, a halogenated alkyl group, a hydroxyl group, an oxygen atom (═O) or the like can be used.

The alkyl group as the substituent for the aromatic hydrocarbon group is preferably an alkyl group of 1 to 5 carbon atoms, and a methyl group, an ethyl group, a propyl group, an n-butyl group or a tert-butyl group is particularly desirable.

The alkoxy group as the sub stituent for the aromatic hydrocarbon group is preferably an alkoxy group having 1 to 5 carbon atoms, more preferably a methoxy group, an ethoxy group, a n-propoxy group, an iso-propoxy group, a n-butoxy group or a tert-butoxy group, and most preferably a methoxy group or an ethoxy group.

Examples of the halogen atom as the substituent for the aromatic hydrocarbon group include a fluorine atom, a chlorine atom, a bromine atom and an iodine atom, and a fluorine atom is preferable.

Example of the halogenated alkyl group as the substituent for the aromatic hydrocarbon group includes a group in which a part or all of the hydrogen atoms within the aforementioned alkyl group have been substituted with the aforementioned halogen atoms.

The aliphatic hydrocarbon group for X^{a} may be either a saturated aliphatic hydrocarbon group, or an unsaturated aliphatic hydrocarbon group. Further, the aliphatic hydrocarbon group may be linear, branched or cyclic.

In the aliphatic hydrocarbon group for X^{a}, a part of the carbon atoms constituting the aliphatic hydrocarbon group may be substituted with a substituent group containing a hetero atom, or a part or all of the hydrogen atoms constituting the aliphatic hydrocarbon group may be substituted with a sub stituent group containing a hetero atom.

As the “hetero atom” for X^{a}, there is no particular limitation as long as it is an atom other than a carbon atom and a hydrogen atom. Examples of hetero atoms include a halogen atom, an oxygen atom, a sulfur atom and a nitrogen atom. Examples of halogen atoms include a fluorine atom, a chlorine atom, an iodine atom and a bromine atom.

The substituent group containing a hetero atom may consist of a hetero atom, or may be a group containing a group or atom other than a hetero atom.

Specific examples of the substituent group for substituting a part of the carbon atoms include —O—, —C(═O)—O—, —C(═O)—, —O—C(═O)—O—, —C(═O)—NH—, —NH— (the H may be replaced with a substituent such as an alkyl group or an acyl group), —S—, —S(═O)₂— and —S(═O)₂—O—. When the aliphatic hydrocarbon group is cyclic, the aliphatic hydrocarbon group may contain any of these sub stituent groups in the ring structure.

Examples of the substituent group for substituting a part or all of the hydrogen atoms include an alkoxy group, a halogen atom, a halogenated alkyl group, a hydroxyl group, an oxygen atom (═O) and a cyano group.

The aforementioned alkoxy group is preferably an alkoxy group having 1 to 5 carbon atoms, more preferably a methoxy group, an ethoxy group, a n-propoxy group, an iso-propoxy group, a n-butoxy group or a tert-butoxy group, and most preferably a methoxy group or an ethoxy group.

Examples of the aforementioned halogen atom include a fluorine atom, a chlorine atom, a bromine atom and an iodine atom, and a fluorine atom is preferable.

Example of the aforementioned halogenated alkyl group includes a group in which a part or all of the hydrogen atoms within an alkyl group of 1 to 5 carbon atoms (e.g., a methyl group, an ethyl group, a propyl group, a n-butyl group or a tert-butyl group) have been substituted with the aforementioned halogen atoms.

As the aliphatic hydrocarbon group, a linear or branched saturated hydrocarbon group, a linear or branched monovalent unsaturated hydrocarbon group, or a cyclic aliphatic hydrocarbon group (aliphatic cyclic group) is preferable.

The linear saturated hydrocarbon group (alkyl group) preferably has 1 to 20 carbon atoms, more preferably 1 to 15 carbon atoms, and most preferably 1 to 10 carbon atoms. Specific examples include a methyl group, an ethyl group, a propyl group, a butyl group, a pentyl group, a hexyl group, a heptyl group, an octyl group, a nonyl group, a decyl group, an undecyl group, a dodecyl group, a tridecyl group, an isotridecyl group, a tetradecyl group, a pentadecyl group, a hexadecyl group, an isohexadecyl group, a heptadecyl group, an octadecyl group, a nonadecyl group, an icosyl group, a henicosyl group and a docosyl group.

The branched saturated hydrocarbon group (alkyl group) preferably has 3 to 20 carbon atoms, more preferably 3 to 15 carbon atoms, and most preferably 3 to 10 carbon atoms. Specific examples include a 1-methylethyl group, a 1-methylpropyl group, a 2-methylpropyl group, a 1-methylbutyl group, a 2-methylbutyl group, a 3-methylbutyl group, a 1-ethylbutyl group, a 2-ethylbutyl group, a 1-methylpentyl group, a 2-methylpentyl group, a 3-methylpentyl group and a 4-methylpentyl group.

The unsaturated hydrocarbon group preferably has 2 to 10 carbon atoms, more preferably 2 to 5 carbon atoms, still more preferably 2 to 4 carbon atoms, and most preferably 3 carbon atoms. Examples of linear monovalent unsaturated hydrocarbon groups include a vinyl group, a propenyl group (an allyl group) and a butynyl group. Examples of branched monovalent unsaturated hydrocarbon groups include a 1-methylpropenyl group and a 2-methylpropenyl group.

Among the above-mentioned examples, as the unsaturated hydrocarbon group, a propenyl group is particularly desirable.

The aliphatic cyclic group may be either a monocyclic group or a polycyclic group. The aliphatic cyclic group preferably has 3 to 30 carbon atoms, more preferably 5 to 30 carbon atoms, still more preferably 5 to 20 carbon atoms, still more preferably 6 to 15 carbon atoms, and most preferably 6 to 12 carbon atoms.

As the aliphatic cyclic group, a group in which one or more hydrogen atoms have been removed from a monocycloalkane or a polycycloalkane such as a bicycloalkane, tricycloalkane or tetracycloalkane can be used. Specific examples include groups in which one or more hydrogen atoms have been removed from a monocycloalkane such as cyclopentane or cyclohexane; and groups in which one or more hydrogen atoms have been removed from a polycycloalkane such as adamantane, norbornane, isobornane, tricyclodecane or tetracyclododecane.

When the aliphatic cyclic group does not contain a hetero atom-containing sub stituent group in the ring structure thereof, the aliphatic cyclic group is preferably a polycyclic group, more preferably a group in which one or more hydrogen atoms have been removed from a polycycloalkane, and a group in which one or more hydrogen atoms have been removed from adamantane is particularly desirable.

When the aliphatic cyclic group contains a hetero atom-containing substituent group in the ring structure thereof, the hetero atom-containing substituent group is preferably —O—, —C(═O)—O—, —S—, —S(═O)₂— or —S(═O)₂—O—. Specific examples of such aliphatic cyclic groups include groups represented by formulas (L1) to (L5) and (S1) to (S4) shown below.

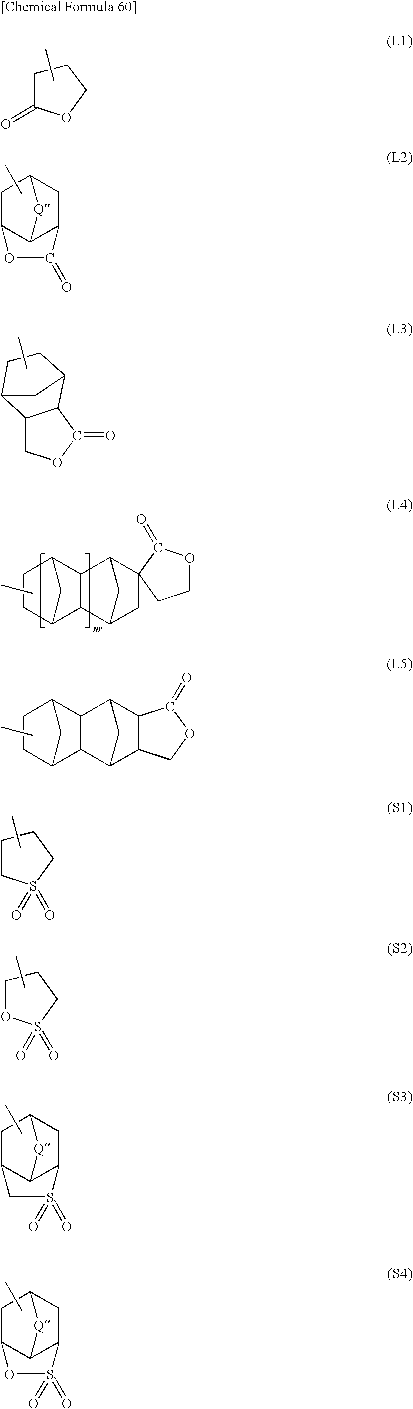

[In the formula, Q″ represents an alkylene group of 1 to 5 carbon atoms, —O—, —S—, —O—R⁹⁴— or —S—R⁹⁵— (wherein each of R⁹⁴ and R⁹⁵ independently represents an alkylene group of 1 to 5 carbon atoms); and m′ represents an integer of 0 or 1.]

In the formula, as the alkylene group for Q″, R⁹⁴ and R⁹⁵, the same alkylene groups as those described above for R⁹¹ to R⁹³ can be used. In these aliphatic cyclic groups, a part of the hydrogen atoms boned to the carbon atoms constituting the ring structure may be substituted with a substituent. Examples of sub stituents include an alkyl group, an alkoxy group, a halogen atom, a halogenated alkyl group, a hydroxyl group and an oxygen atom (═O).

As the alkyl group, an alkyl group of 1 to 5 carbon atoms is preferable, and a methyl group, an ethyl group, a propyl group, a n-butyl group or a tert-butyl group is particularly desirable.

As the alkoxy group and the halogen atom, the same groups as the aforementioned substituent groups for substituting a part or all of the hydrogen atoms can be used.

In the present invention, as X^{a}, a cyclic group which may have a sub stituent is preferable. The cyclic group may be either an aromatic hydrocarbon group which may have a substituent, or an aliphatic cyclic group which may have a substituent, and an aliphatic cyclic group which may have a substituent is preferable.

As the aromatic hydrocarbon group, a naphthyl group which may have a substituent, or a phenyl group which may have a substituent is preferable.

As the aliphatic cyclic group which may have a substituent, an aliphatic polycyclic group which may have a substituent is preferable. As the aliphatic polycyclic group, the aforementioned group in which one or more hydrogen atoms have been removed from a polycycloalkane, and groups represented by formulas (L2) to (L5), (S3) and (S4) are preferable.

In the present invention, R⁴″ preferably has X^{a}-Q¹- as a substituent. In such a case, R⁴″ is preferably a group represented by the formula X^{a}-Q¹-Y^{1a}— (in the formula, Q¹ and X^{a} are the same as defined above; and Y^{1a} represents an alkylene group of 1 to 4 carbon atoms which may have a substituent, or a fluorinated alkylene group of 1 to 4 carbon atoms which may have a substituent).

In the group represented by the formula X^{a}-Q¹-Y^{1a}—, as the alkylene group for Y^{1a}, the same alkylene group as those described above for Q¹ in which the number of carbon atoms is 1 to 4 can be used.

As the fluorinated alkylene group for Y^{1a}, the aforementioned alkylene group in which a part or all of the hydrogen atoms in the alkylene group have been substituted with fluorine atoms can be used.

Specific examples of Y^{1a} include —CF₂—, —CF₂CF₂—, —CF₂CF₂CF₂—, —CF(CF₃)CF₂—, —CF(CF₂CF₃)—, —C(CF₃)₂—, —CF₂CF₂CF₂CF₂—, —CF(CF₃)CF₂CF₂—, —CF₂CF(CF₃)CF₂—, —CF(CF₃)CF(CF₃)—, —C(CF₃)₂CF₂—, —CF(CF₂CF₃)CF₂—, —CF(CF₂CF₂CF₃)—, —C(CF₃)(CF₂CF₃)—, —CHF—, —CH₂CF₂—, —CH₂CH₂CF₂—, —CH₂CF₂CF₂—, —CH(CF₃)CH₂—, —CH(CF₂CF₃)—, —C(CH₃)(CF₃)—, —CH₂CH₂CH₂CF₂—, —CH₂CH₂CF₂CF₂—, —CH(CF₃)CH₂CH₂—, —CH₂CH(CF₃)CH₂—, —CH(CF₃)CH(CF₃)—, —C(CF₃)₂CH₂—; —CH₂—, —CH₂CH₂—, —CH₂CH₂CH₂—, —CH(CH₃)CH₂—, —CH(CH₂CH₃)—, —C(CH₃)₂—, —CH₂CH₂CH₂CH₂—, —CH(CH₃)CH₂CH₂—, —CH₂CH(CH₃)CH₂—, —CH(CH₃)CH(CH₃)—, —C(CH₃)₂CH₂—, —CH(CH₂CH₃)CH₂—, —CH(CH₂CH₂CH₃)—, and —C(CH₃)(CH₂CH₃)—.

Y^{1a} is preferably a fluorinated alkylene group, and particularly preferably a fluorinated alkylene group in which the carbon atom bonded to the adjacent sulfur atom is fluorinated. Examples of such fluorinated alkylene groups include —CF₂—, —CF₂CF₂—, —CF₂CF₂CF₂—, —CF(CF₃)CF₂—, —CF₂CF₂CF₂CF₂—, —CF(CF₃)CF₂CF₂—, —CF₂CF(CF₃)CF₂—, —CF(CF₃)CF(CF₃)—, —C(CF₃)₂CF₂—, —CF(CF₂CF₃)CF₂—; —CH₂CF₂—, —CH₂CH₂CF₂—, —CH₂CF₂CF₂—; —CH₂CH₂CH₂CF₂—, —CH₂CH₂CF₂CF₂—, and —CH₂CF₂CF₂CF₂—.

Of these, —CF₂—, —CF₂CF₂—, —CF₂CF₂CF₂— or CH₂CF₂CF₂— is preferable, —CF₂—, —CF₂CF₂— or —CF₂CF₂CF₂— is more preferable, and —CF₂— is particularly desirable.

The alkylene group or fluorinated alkylene group may have a substituent. The alkylene group or fluorinated alkylene group “has a substituent” means that part or all of the hydrogen atoms or fluorine atoms in the alkylene group or fluorinated alkylene group has been substituted with groups other than hydrogen atoms and fluorine atoms.

Examples of sub stituents which the alkylene group or fluorinated alkylene group may have include an alkyl group of 1 to 4 carbon atoms, an alkoxy group of 1 to 4 carbon atoms, and a hydroxyl group.

In formula (b-2), R⁵″ and R⁶″ each independently represents an aryl group or an alkyl group. At least one of R⁵″ and R⁶″ represents an aryl group. It is preferable that both of R⁵″ and R⁶″ represent an aryl group.

As the aryl group for R⁵″ and R⁶″, the same as the aryl groups for R¹″ to R³″ can be used.

As the alkyl group for R⁵″ and R⁶″, the same as the alkyl groups for R¹″ to R³″ can be used.

It is particularly desirable that both of R⁵″ and R⁶″ represents a phenyl group.

As R⁴″ in formula (b-2), the same groups as those mentioned above for R⁴″ in formula (b-1) can be used.

Specific examples of suitable onium salt acid generators represented by formula (b-1) or (b-2) include diphenyliodonium trifluoromethanesulfonate or nonafluorobutanesulfonate; bis(4-tert-butylphenyl)iodonium trifluoromethanesulfonate or nonafluorobutanesulfonate; triphenylsulfonium trifluoromethanesulfonate, heptafluoropropanesulfonate or nonafluorobutanesulfonate; tri(4-methylphenyl)sulfonium trifluoromethanesulfonate, heptafluoropropanesulfonate or nonafluorobutanesulfonate; dimethyl(4-hydroxynaphthyl)sulfonium trifluoromethanesulfonate, heptafluoropropanesulfonate or nonafluorobutanesulfonate; monophenyldimethylsulfonium trifluoromethanesulfonate, heptafluoropropanesulfonate or nonafluorobutanesulfonate; diphenylmonomethylsulfonium trifluoromethanesulfonate, heptafluoropropanesulfonate or nonafluorobutanesulfonate; (4-methylphenyl)diphenylsulfonium trifluoromethanesulfonate, heptafluoropropanesulfonate or nonafluorobutanesulfonate; (4-methoxyphenyl)diphenylsulfonium trifluoromethanesulfonate, heptafluoropropanesulfonate or nonafluorobutanesulfonate; tri(4-tert-butyl)phenylsulfonium trifluoromethanesulfonate, heptafluoropropanesulfonate or nonafluorobutanesulfonate; diphenyl(1-(4-methoxy)naphthyl)sulfonium trifluoromethanesulfonate, heptafluoropropanesulfonate or nonafluorobutanesulfonate; di(1-naphthyl)phenylsulfonium trifluoromethanesulfonate, heptafluoropropanesulfonate or nonafluorobutanesulfonate; 1-phenyltetrahydrothiophenium trifluoromethanesulfonate, heptafluoropropanesulfonate or nonafluorobutanesulfonate; 1-(4-methylphenyl)tetrahydrothiophenium trifluoromethanesulfonate, heptafluoropropanesulfonate or nonafluorobutanesulfonate; 1-(3,5-dimethyl-4-hydroxyphenyl)tetrahydrothiophenium trifluoromethanesulfonate, heptafluoropropanesulfonate or nonafluorobutanesulfonate; 1-(4-methoxynaphthalene-1-yl)tetrahydrothiophenium trifluoromethanesulfonate, heptafluoropropanesulfonate or nonafluorobutanesulfonate; 1-(4-ethoxynaphthalene-1-yl)tetrahydrothiophenium trifluoromethanesulfonate, heptafluoropropanesulfonate or nonafluorobutanesulfonate; 1-(4-n-butoxynaphthalene-1-yl)tetrahydrothiophenium trifluoromethanesulfonate, heptafluoropropanesulfonate or nonafluorobutanesulfonate; 1-phenyltetrahydrothiopyranium trifluoromethanesulfonate, heptafluoropropanesulfonate or nonafluorobutanesulfonate; 1-(4-hydroxyphenyl)tetrahydrothiopyranium trifluoromethanesulfonate, heptafluoropropanesulfonate or nonafluorobutanesulfonate; 1-(3,5-dimethyl-4-hydroxyphenyl)tetrahydrothiopyranium trifluoromethanesulfonate, heptafluoropropanesulfonate or nonafluorobutanesulfonate; and 1-(4-methylphenyl)tetrahydrothiopyranium trifluoromethanesulfonate, heptafluoropropanesulfonate or nonafluorobutanesulfonate.

It is also possible to use onium salts in which the anion moiety of these onium salts are replaced by an alkylsulfonate such as methanesulfonate, n-propanesulfonate, n-butanesulfonate, or n-octanesulfonate.

Furthermore, onium salts in which the anion moiety of these onium salts are replaced by an anion moiety represented by any one of formulas (b1) to (b8) shown below can also be used.

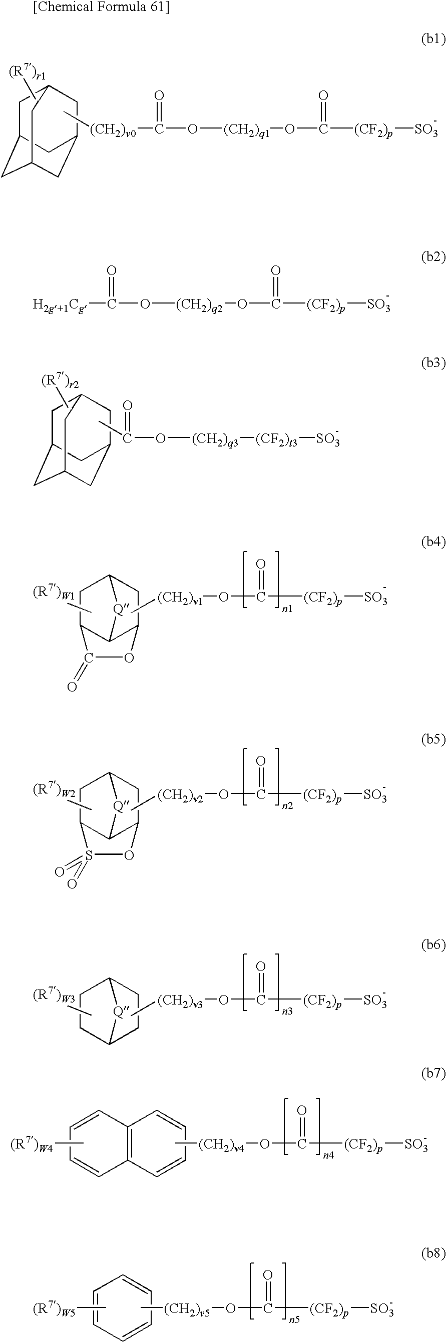

[In the formulas, p independently represents an integer of 1 to 3; each of q1 and q2 independently represents an integer of 1 to 5; q3 represents an integer of 1 to 12; t3 represents an integer of 1 to 3; each of r1 and r2 independently represents an integer of 0 to 3; g′ represents an integer of 1 to 20; R⁷′ represents a substituent; each of n1 to n5 independently represents 0 or 1; each of v0 to v5 independently represents an integer of 0 to 3; each of w1 to w5 independently represents an integer of 0 to 3; and Q″ is the same as defined above.]

As the substituent for R⁷′, the same groups as those which the aforementioned aliphatic hydrocarbon group or aromatic hydrocarbon group for X^{a} may have as a sub stituent can be used.

If there are two or more of the R⁷′ group, as indicated by the values r1 and r2 and w1 to w5, then the two or more of the R⁷′ groups may be the same or different from each other.

Further, onium salt-based acid generators in which the anion moiety in general formula (b-1) or (b-2) is replaced by an anion moiety represented by general formula (b-3) or (b-4) shown below (the cation moiety is the same as (b-1) or (b-2)) may be used.

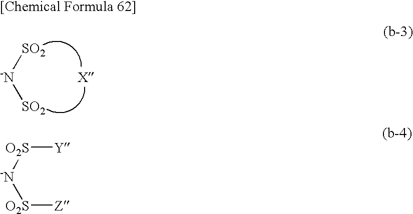

[In formulas (b-3) and (b-4) above, X″ represents an alkylene group of 2 to 6 carbon atoms in which at least one hydrogen atom has been substituted with a fluorine atom; and each of Y″ and Z″ independently represents an alkyl group of 1 to 10 carbon atoms in which at least one hydrogen atom has been substituted with a fluorine atom.]

X″ represents a linear or branched alkylene group in which at least one hydrogen atom has been substituted with a fluorine atom, and the alkylene group has 2 to 6 carbon atoms, preferably 3 to 5 carbon atoms, and most preferably 3 carbon atoms.

Each of Y″ and Z″ independently represents a linear or branched alkyl group in which at least one hydrogen atom has been substituted with a fluorine atom, and the alkyl group has 1 to 10 carbon atoms, preferably 1 to 7 carbon atoms, and most preferably 1 to 3 carbon atoms.

The smaller the number of carbon atoms of the alkylene group for X″ or those of the alkyl group for Y″ and Z″ within the above-mentioned range of the number of carbon atoms, the more the solubility in a resist solvent is improved.

Further, in the alkylene group for X″ or the alkyl group for Y″ and Z″, it is preferable that the number of hydrogen atoms substituted with fluorine atoms is as large as possible because the acid strength increases and the transparency to high energy radiation of 200 nm or less or electron beam is improved. The fluorination ratio of the alkylene group or alkyl group is preferably from 70 to 100%, more preferably from 90 to 100%, and it is particularly desirable that the alkylene group or alkyl group be a perfluoroalkylene group or perfluoroalkyl group in which all hydrogen atoms are substituted with fluorine atoms.

Furthermore, as an onium salt-based acid generator, a sulfonium salt having a cation moiety represented by general formula (b-5) or (b-6) shown below may be used.

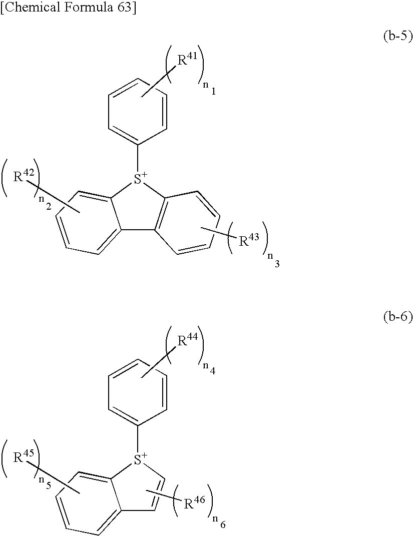

[In formulas (b-5) and (b-6) above, each of R⁴¹ to R⁴⁶ independently represents an alkyl group, an acetyl group, an alkoxy group, a carboxy group, a hydroxyl group or a hydroxyalkyl group; each of n₁ to n₅ independently represents an integer of 0 to 3; and n₆ represents an integer of 0 to 2.]

With respect to R⁴¹ to R⁴⁶, the alkyl group is preferably an alkyl group of 1 to 5 carbon atoms, more preferably a linear or branched alkyl group, and most preferably a methyl group, an ethyl group, a propyl group, an isopropyl group, a n-butyl group or a tert butyl group.

The alkoxy group is preferably an alkoxy group of 1 to 5 carbon atoms, more preferably a linear or branched alkoxy group, and most preferably a methoxy group or an ethoxy group.

The hydroxyalkyl group is preferably the aforementioned alkyl group in which one or more hydrogen atoms have been substituted with hydroxy groups, and examples thereof include a hydroxymethyl group, a hydroxyethyl group and a hydroxypropyl group.

If there are two or more of an individual R⁴¹ to R⁴⁶ group, as indicated by the corresponding value of n₁ to n₆, then the two or more of the individual R⁴¹ to R⁴⁶ group may be the same or different from each other.

n₁ is preferably 0 to 2, more preferably 0 or 1, and still more preferably 0.

It is preferable that n₂ and n₃ each independently represent 0 or 1, and more preferably 0.

n₄ is preferably 0 to 2, and more preferably 0 or 1.

n₅ is preferably 0 or 1, and more preferably 0.

n₆ is preferably 0 or 1, and more preferably 1.

The anion moiety of the sulfonium salt having a cation moiety represented by general formula (b-5) or (b-6) is not particularly limited, and the same anion moieties for onium salt-based acid generators which have been proposed may be used. Examples of such anion moieties include fluorinated alkylsulfonic acid ions such as anion moieties (R^{4″}SO₃⁻) for onium salt-based acid generators represented by general formula (b-1) or (b-2) shown above; and anion moieties represented by general formula (b-3) or (b-4) shown above.

In the present description, an oximesulfonate-based acid generator is a compound having at least one group represented by general formula (B-1) shown below, and has a feature of generating acid by irradiation. Such oximesulfonate acid generators are widely used for a chemically amplified resist composition, and can be appropriately selected.

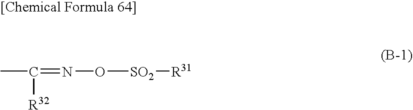

[In formula (B-1), each of R³¹ and R³² independently represents an organic group.]

The organic group for R³¹ and R³² refers to a group containing a carbon atom, and may include atoms other than carbon atoms (e.g., a hydrogen atom, an oxygen atom, a nitrogen atom, a sulfur atom, a halogen atom (such as a fluorine atom and a chlorine atom) and the like).

As the organic group for R³¹, a linear, branched, or cyclic alkyl group or aryl group is preferable. The alkyl group or the aryl group may have a substituent. The substituent is not particularly limited, and examples thereof include a fluorine atom and a linear, branched, or cyclic alkyl group having 1 to 6 carbon atoms. The alkyl group or the aryl group “has a sub stituent” means that part or all of the hydrogen atoms of the alkyl group or the aryl group is substituted with a substituent.

The alkyl group preferably has 1 to 20 carbon atoms, more preferably 1 to 10 carbon atoms, still more preferably 1 to 8 carbon atoms, still more preferably 1 to 6 carbon atoms, and most preferably 1 to 4 carbon atoms. As the alkyl group, a partially or completely halogenated alkyl group (hereinafter, sometimes referred to as a “halogenated alkyl group”) is particularly desirable. The “partially halogenated alkyl group” refers to an alkyl group in which part of the hydrogen atoms are substituted with halogen atoms and the “completely halogenated alkyl group” refers to an alkyl group in which all of the hydrogen atoms are substituted with halogen atoms. Examples of the halogen atom include a fluorine atom, a chlorine atom, a bromine atom and an iodine atom, and a fluorine atom is particularly desirable. In other words, the halogenated alkyl group is preferably a fluorinated alkyl group.

The aryl group preferably has 4 to 20 carbon atoms, more preferably 4 to 10 carbon atoms, and most preferably 6 to 10 carbon atoms. As the aryl group, partially or completely halogenated aryl group is particularly desirable. The “partially halogenated aryl group” refers to an aryl group in which some of the hydrogen atoms are substituted with halogen atoms and the “completely halogenated aryl group” refers to an aryl group in which all of hydrogen atoms are substituted with halogen atoms.

As R³¹, an alkyl group of 1 to 4 carbon atoms which has no substituent or a fluorinated alkyl group of 1 to 4 carbon atoms is particularly desirable.

As the organic group for R³², a linear, branched, or cyclic alkyl group, aryl group, or cyano group is preferable. Examples of the alkyl group and the aryl group for R³² include the same alkyl groups and aryl groups as those described above for R³¹.

As R³², a cyano group, an alkyl group of 1 to 8 carbon atoms having no substituent or a fluorinated alkyl group of 1 to 8 carbon atoms is particularly desirable.

Preferable examples of the oxime sulfonate-based acid generator include compounds represented by general formula (B-2) or (B-3) shown below.

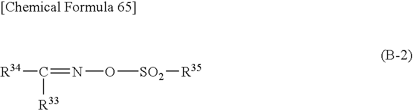

[In formula (B-2), R³³ represents a cyano group, an alkyl group having no substituent or a halogenated alkyl group; R³⁴ represents an aryl group; and R³⁵ represents an alkyl group having no substituent or a halogenated alkyl group.]

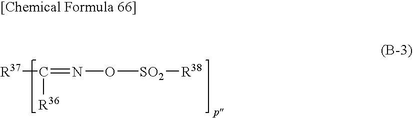

[In formula (B-3), R³⁶ represents a cyano group, an alkyl group having no substituent or a halogenated alkyl group; R³⁷ represents a divalent or trivalent aromatic hydrocarbon group; R³⁸ represents an alkyl group having no substituent or a halogenated alkyl group; and p″ represents 2 or 3.]

In general formula (B-2), the alkyl group having no substituent or the halogenated alkyl group for R³³ preferably has 1 to 10 carbon atoms, more preferably 1 to 8 carbon atoms, and most preferably 1 to 6 carbon atoms.

As R³³, a halogenated alkyl group is preferable, and a fluorinated alkyl group is more preferable.

The fluorinated alkyl group for R³³ preferably has 50% or more of the hydrogen atoms thereof fluorinated, more preferably 70% or more, and most preferably 90% or more.

Examples of the aryl group for R³⁴ include groups in which one hydrogen atom has been removed from an aromatic hydrocarbon ring, such as a phenyl group, a biphenyl group, a fluorenyl group, a naphthyl group, an anthryl group, and a phenanthryl group, and heteroaryl groups in which some of the carbon atoms constituting the ring(s) of these groups are substituted with hetero atoms such as an oxygen atom, a sulfur atom, and a nitrogen atom. Of these, a fluorenyl group is preferable.

The aryl group for R³⁴ may have a substituent such as an alkyl group of 1 to 10 carbon atoms, a halogenated alkyl group, or an alkoxy group. The alkyl group and halogenated alkyl group as the substituent preferably has 1 to 8 carbon atoms, and more preferably 1 to 4 carbon atoms. Further, the halogenated alkyl group is preferably a fluorinated alkyl group.

The alkyl group having no sub stituent or the halogenated alkyl group for R³⁵ preferably has 1 to 10 carbon atoms, more preferably 1 to 8 carbon atoms, and most preferably 1 to 6 carbon atoms.

As R³⁵, a halogenated alkyl group is preferable, and a fluorinated alkyl group is more preferable.

In terms of enhancing the strength of the acid generated, the fluorinated alkyl group for R³⁵ preferably has 50% or more of the hydrogen atoms fluorinated, more preferably 70% or more, still more preferably 90% or more. A completely fluorinated alkyl group in which 100% of the hydrogen atoms are substituted with fluorine atoms is particularly desirable.

In general formula (B-3), as the alkyl group having no substituent and the halogenated alkyl group for R³⁶, the same alkyl group having no substituent and the halogenated alkyl group described above for R³³ can be used.

Examples of the divalent or trivalent aromatic hydrocarbon group for R³⁷ include groups in which one or two hydrogen atoms have been removed from the aryl group for R³⁴.

As the alkyl group having no substituent or the halogenated alkyl group for R³⁸, the same one as the alkyl group having no substituent or the halogenated alkyl group for R³⁵ can be used.

p″ is preferably 2.

Specific examples of suitable oxime sulfonate acid generators include α-(p-toluenesulfonyloxyimino)-benzyl cyanide, α-(p-chlorobenzenesulfonyloxyimino)-benzyl cyanide, α-(4-nitrobenzenesulfonyloxyimino)-benzyl cyanide, α-(4-nitro-2-trifluoromethylbenzenesulfonyloxyimino)-benzyl cyanide, α-(benzenesulfonyloxyimino)-4-chlorobenzyl cyanide, α-(benzenesulfonyloxyimino)-2,4-dichlorobenzyl cyanide, α-(benzenesulfonyloxyimino)-2,6-dichlorobenzyl cyanide, α-(benzenesulfonyloxyimino)-4-methoxybenzyl cyanide, α-(2-chlorobenzenesulfonyloxyimino)-4-methoxybenzyl cyanide, α-(benzenesulfonyloxyimino)-thien-2-yl acetonitrile, α-(4-dodecylbenzenesulfonyloxyimino)benzyl cyanide, α-[(p-toluenesulfonyloxyimino)-4-methoxyphenyl]acetonitrile, α-[(dodecylbenzenesulfonyloxyimino)-4-methoxyphenyl]acetonitrile, α-(tosyloxyimino)-4-thienyl cyanide, α-(methylsulfonyloxyimino)-1-cyclopentenyl acetonitrile, α-(methylsulfonyloxyimino)-1-cyclohexenyl acetonitrile, α-(methylsulfonyloxyimino)-1-cycloheptenyl acetonitrile, α-(methylsulfonyloxyimino)-1-cyclooctenyl acetonitrile, α-(trifluoromethylsulfonyloxyimino)-1-cyclopentenyl acetonitrile, α-(trifluoromethylsulfonyloxyimino)-cyclohexyl acetonitrile, α-(ethylsulfonyloxyimino)-ethyl acetonitrile, α-(propylsulfonyloxyimino)-propyl acetonitrile, α-(cyclohexylsulfonyloxyimino)-cyclopentyl acetonitrile, α-(cyclohexylsulfonyloxyimino)-cyclohexyl acetonitrile, α-(cyclohexylsulfonyloxyimino)-1-cyclopentenyl acetonitrile, α-(ethylsulfonyloxyimino)-1-cyclopentenyl acetonitrile, α-(isopropylsulfonyloxyimino)-1-cyclopentenyl acetonitrile, α-(n-butylsulfonyloxyimino)-1-cyclopentenyl acetonitrile, α-(ethylsulfonyloxyimino)-1-cyclohexenyl acetonitrile, α-(isopropylsulfonyloxyimino)-1-cyclohexenyl acetonitrile, α-(n-butylsulfonyloxyimino)-1-cyclohexenyl acetonitrile, α-(methylsulfonyloxyimino)-phenyl acetonitrile, α-(methylsulfonyloxyimino)-p-methoxyphenyl acetonitrile, α-(trifluoromethylsulfonyloxyimino)-phenyl acetonitrile, α-(trifluoromethylsulfonyloxyimino)-p-methoxyphenyl acetonitrile, α-(ethylsulfonyloxyimino)-p-methoxyphenyl acetonitrile, α-(propylsulfonyloxyimino)-p-methylphenyl acetonitrile, and α-(methylsulfonyloxyimino)-p-bromophenyl acetonitrile.

Further, oxime sulfonate-based acid generators disclosed in Japanese Unexamined Patent Application, First Publication No. Hei 9-208554 (Chemical Formulas 18 and 19 shown in paragraphs [0012] to [0014]) and oxime sulfonate-based acid generators disclosed in WO 2004/074242A2 (Examples 1 to 40 described at pages 65 to 85) may be preferably used.

Furthermore, as preferable examples, the following can be used.

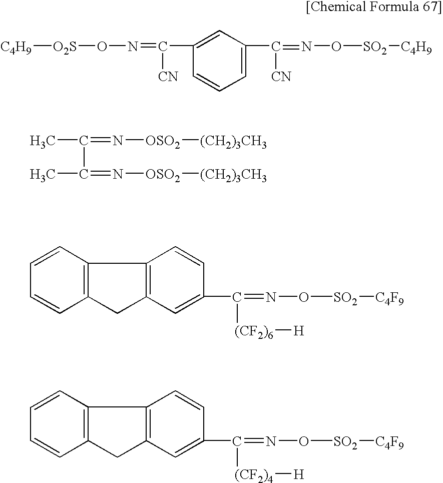

Of the aforementioned diazomethane-based acid generators, specific examples of suitable bisalkyl or bisaryl sulfonyl diazomethanes include bis(isopropylsulfonyl)diazomethane, bis(p-toluenesulfonyl)diazomethane, bis(1,1-dimethylethylsulfonyl)diazomethane, bis(cyclohexylsulfonyl)diazomethane, and bis(2,4-dimethylphenylsulfonyl)diazomethane.

Further, diazomethane-based acid generators disclosed in Japanese Unexamined Patent Application, First Publication No. Hei 11-035551, Japanese Unexamined Patent Application, First Publication No. Hei 11-035552 and Japanese Unexamined Patent Application, First Publication No. Hei 11-035573 may be preferably used.

Furthermore, as examples of poly(bis-sulfonyl)diazomethanes, those disclosed in Japanese Unexamined Patent Application, First Publication No. Hei 11-322707, including 1,3-bis(phenylsulfonyldiazomethylsulfonyl)propane, 1,4-bis(phenylsulfonyldiazomethylsulfonyl)butane, 1,6-bis(phenylsulfonyldiazomethylsulfonyl)hexane, 1,10-bis(phenylsulfonyldiazomethylsulfonyl)decane, 1,2-bis(cyclohexylsulfonyldiazomethylsulfonyl)ethane, 1,3-bis(cyclohexylsulfonyldiazomethylsulfonyl)propane, 1,6-bis(cyclohexylsulfonyldiazomethylsulfonyl)hexane, and 1,10-bis(cyclohexylsulfonyldiazomethylsulfonyl)decane, may be given.

As the component (B), one type of acid generator may be used alone, or two or more types of acid generators may be used in combination.

In the present invention, as the component (B), it is preferable to use an onium salt-based acid generator having a fluorinated alkylsulfonic acid ion as the anion moiety.

In the positive resist composition of the present invention, the amount of the component (B) relative to 100 parts by weight of the component (A) is preferably 0.5 to 50 parts by weight, and more preferably 1 to 40 parts by weight. By ensuring that the amount of the component (B) is within the above-mentioned range, formation of a resist pattern can be satisfactorily performed. Further, by virtue of the above-mentioned range, a uniform solution can be obtained and the storage stability becomes satisfactory.

### <Optional Components>

The positive resist composition of the present invention may further contain a nitrogen-containing organic compound (D) (hereafter referred to as the component (D)) as an optional component.

As the component (D), there is no particular limitation as long as it functions as an acid diffusion control agent, i.e., a quencher which traps the acid generated from the component

(B) upon exposure. A multitude of these components (D) have already been proposed, and any of these known compounds may be used, although an aliphatic amine, and particularly a secondary aliphatic amine or tertiary aliphatic amine is preferable. An aliphatic amine is an amine having one or more aliphatic groups, and the aliphatic groups preferably have 1 to 20 carbon atoms.

Examples of these aliphatic amines include amines in which at least one hydrogen atom of ammonia (NH₃) has been substituted with an alkyl group or hydroxyalkyl group of no more than 20 carbon atoms (i.e., alkylamines or alkylalcoholamines), and cyclic amines.

Specific examples of alkylamines and alkylalcoholamines include monoalkylamines such as n-hexylamine, n-heptylamine, n-octylamine, n-nonylamine, and n-decylamine; dialkylamines such as diethylamine, di-n-propylamine, di-n-heptylamine, di-n-octylamine, and dicyclohexylamine; trialkylamines such as trimethylamine, triethylamine, tri-n-propylamine, tri-n-butylamine, tri-n-hexylamine, tri-n-pentylamine, tri-n-heptylamine, tri-n-octylamine, tri-n-nonylamine, tri-n-decylamine, and tri-n-dodecylamine; and alkyl alcohol amines such as diethanolamine, triethanolamine, diisopropanolamine, triisopropanolamine, di-n-octanolamine, tri-n-octanolamine, stearyldiethanolamine and laurildiethanolamine. Among these, trialkylamines and/or alkylalcoholamines are preferable.

Examples of the cyclic amine include heterocyclic compounds containing a nitrogen atom as a hetero atom. The heterocyclic compound may be a monocyclic compound (aliphatic monocyclic amine), or a polycyclic compound (aliphatic polycyclic amine).

Specific examples of the aliphatic monocyclic amine include piperidine, and piperazine.

The aliphatic polycyclic amine preferably has 6 to 10 carbon atoms, and specific examples thereof include 1,5-diazabicyclo[4.3.0]-5-nonene, 1,8-diazabicyclo[5.4.0]-7-undecene, hexamethylenetetramine, and 1,4-diazabicyclo[2.2.2]octane.

Examples of aromatic amines include aniline, pyridine, 4-dimethylaminopyridine, pyrrole, indole, pyrazole, imidazole and derivatives thereof, as well as diphenylamine, triphenylamine and tribenzylamine.

Examples of other aliphatic amines include tris(2-methoxymethoxyethyl)amine, tris{2-(2-methoxyethoxy)ethyl}amine, tris{2-(2-methoxyethoxymethoxy)ethyl}amine, tris{2-(1-methoxyethoxy)ethyl}amine, tris{2-(1-ethoxyethoxy)ethyl}amine, tris{2-(1-ethoxypropoxy)ethyl}amine and tris[2-{2-(2-hydroxyethoxy)ethoxy}ethyl]amine.

These compounds can be used either alone, or in combinations of two or more different compounds.

The component (D) is typically used in an amount within a range from 0.01 to 5.0 parts by weight, relative to 100 parts by weight of the component (A). By ensuring that the amount of the component (D) is within the above-mentioned range, the shape of the resist pattern and the post exposure stability of the latent image formed by the pattern-wise exposure of the resist layer are improved.

Furthermore, in the positive resist composition of the present invention, for preventing any deterioration in sensitivity, and improving the resist pattern shape and the post exposure stability of the latent image formed by the pattern-wise exposure of the resist layer, at least one compound (E) (hereafter referred to as the component (E)) selected from the group consisting of an organic carboxylic acid, or a phosphorus oxo acid or derivative thereof can be added as an optional component.

Examples of suitable organic carboxylic acids include acetic acid, malonic acid, citric acid, malic acid, succinic acid, benzoic acid, and salicylic acid.

Examples of phosphorus oxo acids or derivatives thereof include phosphoric acid, phosphonic acid and phosphinic acid. Among these, phosphonic acid is particularly desirable.

Examples of oxo acid derivatives include esters in which a hydrogen atom within the above-mentioned oxo acids is substituted with a hydrocarbon group. Examples of the hydrocarbon group include an alkyl group of 1 to 5 carbon atoms and an aryl group of 6 to 15 carbon atoms.

Examples of phosphoric acid derivatives include phosphoric acid esters such as di-n-butyl phosphate and diphenyl phosphate.

Examples of phosphonic acid derivatives include phosphonic acid esters such as dimethyl phosphonate, di-n-butyl phosphonate, phenylphosphonic acid, diphenyl phosphonate and dibenzyl phosphonate.

Examples of phosphinic acid derivatives include phosphinic acid esters such as phenylphosphinic acid.

As the component (E), one type may be used alone, or two or more types may be used in combination.

The component (E) is typically used in an amount within a range from 0.01 to 5.0 parts by weight, relative to 100 parts by weight of the component (A).

If desired, other miscible additives can also be added to the positive resist composition of the present invention. Examples of such miscible additives include additive resins for improving the performance of the resist film, surfactants for improving the applicability, dissolution inhibitors, plasticizers, stabilizers, colorants, halation prevention agents, and dyes.

The positive resist composition of the present invention can be prepared by dissolving the materials for the resist composition in an organic solvent (hereafter, frequently referred to as “component (S)”).

The component (S) may be any organic solvent which can dissolve the respective components to give a uniform solution, and one or more kinds of any organic solvent can be appropriately selected from those which have been conventionally known as solvents for a chemically amplified resist.

Examples thereof include lactones such as y-butyrolactone; ketones such as acetone, methyl ethyl ketone, cycloheptanone, cyclohexanone, methyl-n-pentyl ketone, methyl isopentyl ketone, and 2-heptanone; polyhydric alcohols, such as ethylene glycol, diethylene glycol, propylene glycol and dipropylene glycol; compounds having an ester bond, such as ethylene glycol monoacetate, diethylene glycol monoacetate, propylene glycol monoacetate, and dipropylene glycol monoacetate; polyhydric alcohol derivatives including compounds having an ether bond, such as a monoalkylether (e.g., monomethylether, monoethylether, monopropylether or monobutylether) or monophenylether of any of these polyhydric alcohols or compounds having an ester bond (among these, propylene glycol monomethyl ether acetate (PGMEA) and propylene glycol monomethyl ether (PGME) are preferable); cyclic ethers such as dioxane; esters such as methyl lactate, ethyl lactate (EL), methyl acetate, ethyl acetate, butyl acetate, methyl pyruvate, ethyl pyruvate, methyl methoxypropionate, and ethyl ethoxypropionate; and aromatic organic solvents such as anisole, ethylbenzylether, cresylmethylether, diphenylether, dibenzylether, phenetole, butylphenylether, ethylbenzene, diethylbenzene, pentylbenzene, isopropylbenzene, toluene, xylene, cymene and mesitylene.

These solvents may be used individually, or as a mixed solvent containing two or more different solvents.

Among these, propylene glycol monomethyl ether acetate (PGMEA), propylene glycol monomethyl ether (PGME) and ethyl lactate (EL) are preferable.

Further, among the mixed solvents, a mixed solvent obtained by mixing PGMEA with a polar solvent is preferable. The mixing ratio (weight ratio) of the mixed solvent can be appropriately determined, taking into consideration the compatibility of the PGMEA with the polar solvent, but is preferably in the range of 1:9 to 9:1, more preferably from 2:8 to 8:2.

Specifically, when EL is mixed as the polar solvent, the PGMEA:EL weight ratio is preferably from 1:9 to 9:1, and more preferably from 2:8 to 8:2. Alternatively, when PGME is mixed as the polar solvent, the PGMEA:PGME is preferably from 1:9 to 9:1, more preferably from 2:8 to 8:2, and still more preferably 3:7 to 7:3.

Further, as the component (S), a mixed solvent of at least one of PGMEA and EL with y-butyrolactone is also preferable. The mixing ratio (former:latter) of such a mixed solvent is preferably from 70:30 to 95:5.

The amount of the organic solvent is not particularly limited, and is appropriately adjusted to a concentration which enables coating of a coating solution to a substrate, depending on the thickness of the coating film. In general, the organic solvent is used in an amount such that the solid content of the resist composition becomes within the range from 1 to 20% by weight, and preferably from 2 to 15% by weight.

The positive resist composition of the present invention exhibits excellent lithography properties, and can be used for forming a resist pattern having an excellent shape in terms of line width roughness (LWR) or the like. LWR refers to the phenomenon in which the line widths of a line pattern becomes heterogeneous when a resist pattern is formed using a resist composition, and improvement in the level of LWR becomes an important issue as pattern miniaturization progresses.

The positive resist composition of the present invention is characterized in that the “Tf” is at least 100° C., and also the “Tf′” is lower than the “Tf” by at least 18° C. This m that the heat resistance of a resist film deteriorates following the exposure. It is thought that since the acid generated upon exposure is more readily diffused when the heat resistance of a film is reduced, which makes it possible to promote the acid dissociation reaction in the component (A), the positive resist composition of the present invention is particularly useful in the lithography process using EUV and EB, and can be used for forming a high-resolution resist pattern having an excellent shape.

Furthermore, it is thought that when the component (A11) in the present invention includes the polymer (A11) or (A12) that is cleaved in the linking group of the arm portion, the molecular weight of the exposed portion becomes much smaller than the molecular weight of the unexposed portion, which increases the effect of lowering the resist softening point after exposure in the exposed portion, and thereby increasing the gap (the difference) between the resist softening points in the exposed portion and unexposed portion. In view of increasing the difference between the molecular weight of the exposed portion and the molecular weight of the unexposed portion, the more the number of arm portions branched in the component (A11) or (A12), the better.

From the reasons described above, it is assumed that the positive resist composition of the present invention is effective in forming a high-resolution resist pattern having an excellent shape.

### <<Method of Forming a Resist Pattern>>

The method of forming a resist pattern according to the present invention includes: applying a positive resist composition of the present invention to a substrate to form a resist film on the substrate; conducting exposure of the resist film; and developing the resist film to form a resist pattern.

More specifically, the method for forming a resist pattern according to the present invention can be performed, for example, as follows.

Firstly, a positive resist composition according to the present invention is applied onto a substrate using a spinner or the like, and a prebake (post applied bake (PAB)) is conducted at a temperature of 80 to 150° C. for 40 to 120 seconds, preferably 60 to 90 seconds, to form a resist film. Following selective exposure of the thus formed resist film, either by exposure through a mask pattern using an exposure apparatus such as an ArF exposure apparatus, an electron beam lithography apparatus or an EUV exposure apparatus, or by patterning via direct irradiation with an electron beam without using a mask pattern, PEB (post exposure baking) is conducted under temperature conditions of 80 to 150° C. for 40 to 120 seconds, and preferably 60 to 90 seconds. Subsequently, developing is conducted using an alkali developing solution such as a 0.1 to 10% by weight aqueous solution of tetramethylammonium hydroxide (TMAH), preferably followed by rinsing with pure water, and drying. If desired, bake treatment (post bake) can be conducted following the developing. In this manner, a resist pattern that is faithful to the mask pattern can be obtained.

The substrate is not specifically limited and a conventionally known substrate can be used. For example, substrates for electronic components, and such substrates having wiring patterns formed thereon can be used. Specific examples of the material of the substrate include a silicon wafer; metals such as copper, chromium, iron and aluminum; and glass. Suitable materials for the wiring pattern include copper, aluminum, nickel, and gold.

Further, as the substrate, any one of the above-mentioned substrates provided with an inorganic and/or organic film on the surface thereof may be used. As the inorganic film, an inorganic antireflection film (inorganic BARC) can be used. As the organic film, an organic antireflection film (organic BARC) can be used.

The wavelength to be used for exposure is not particularly limited and the exposure can be conducted using radiations such as ArF excimer laser, KrF excimer laser, F₂ excimer laser, extreme ultraviolet rays (EUV), vacuum ultraviolet rays (VUV), electron beam (EB), X-rays, and soft X-rays. The positive resist composition of the present invention is effective to KrF excimer laser, ArF excimer laser, EB and EUV, and particularly effective to ArF excimer laser.

The exposure of the resist film can be either a general exposure (dry exposure) conducted in air or an inert gas such as nitrogen, or immersion exposure (liquid immersion lithography).

The liquid immersion exposure is an exposure method in which the region between the resist film and the lens at the lowermost point of the exposure apparatus is pre-filled with a solvent (immersion medium) that has a larger refractive index than the refractive index of air, and the exposure (immersion exposure) is conducted in this state.

The immersion medium preferably exhibits a refractive index larger than the refractive index of air but smaller than the refractive index of the resist film to be exposed. The refractive index of the immersion medium is not particularly limited as long at it satisfies the above-mentioned requirements.

Examples of this immersion medium which exhibits a refractive index that is larger than the refractive index of air but smaller than the refractive index of the resist film include water, fluorine-based inert liquids, silicon-based solvents and hydrocarbon-based solvents.

Specific examples of the fluorine-based inert liquids include liquids containing a fluorine-based compound such as C₃HCl₂F₅, C₄F₉OCH₃, C₄F₉OC₂H₅ or C₅H₃F₇ as the main component, which have a boiling point within a range from 70 to 180° C. and preferably from 80 to 160° C. A fluorine-based inert liquid having a boiling point within the above-mentioned range is advantageous in that the removal of the immersion medium after the exposure can be conducted by a simple method.

As a fluorine-based inert liquid, a perfluoroalkyl compound in which all of the hydrogen atoms of the alkyl group are substituted with fluorine atoms is particularly desirable.

Examples of these perfluoroalkyl compounds include perfluoroalkylether compounds and perfluoroalkylamine compounds.

Specifically, one example of a suitable perfluoroalkylether compound is perfluoro(2-butyl-tetrahydrofuran) (boiling point: 102° C.), and an example of a suitable perfluoroalkylamine compound is perfluorotributylamine (boiling point: 174° C.).

As the immersion medium, water is preferably used in terms of cost, safety, environmental friendliness and versatility.

### Examples

As follows is a more detailed description of the present invention based on a series of examples, although the scope of the present invention is in no way limited by these examples.

The polymers used in Examples and Comparative Examples were synthesized in accordance with the following synthesis examples.

### Synthesis Example 1

### Synthesis of Polymer (A)-1

### Synthesis Example 1-1

### Synthesis of a Coupling Agent for Anionic Polymerization for Providing a Core Portion

### (i) Synthesis of pentaerythritol-tetra(2-chloroethoxymethyl)ether

Under a nitrogen atmosphere, to 13.0 g of pentaerythritol, 247.0 g of acetone, 80.2 g of diisopropylethylamine and 80.1 g of 2-chloroethyl chloromethyl ether were added, followed by stirring for 4 hours while maintaining the temperature at 30° C. Thereafter, ethyl acetate was added to the reaction mixture, and the resulting organic layer was washed four times with an aqueous oxalic acid solution and ion exchanged water. Then, the obtained organic layer was concentrated under reduced pressure, thereby yielding 47.4 g (yield: 98%) of pentaerythritol-tetra(2-chloroethoxymethyl)ether.

### (ii) Synthesis of pentaerythritol-tetra(2-bromoethoxymethyl)ether

Under a nitrogen atmosphere, to 11.2 g of the pentaerythritol-tetra(2-chloroethoxymethyl)ether obtained in the synthesis (i) described above, 560.0 g of hexamethyl phosphoric acid triamide, 144.7 g of bromoethane and 1.8 g of sodium bromide were added, followed by stirring for 24 hours while maintaining the temperature at 80° C. Thereafter, the reaction mixture was cooled to room temperature, and the reaction mixture was concentrated under reduced pressure. To the obtained concentrated mixture, methyl t-butyl ether was added, and the resulting organic layer was washed four times with ion exchanged water. Then, the organic layer was dried by adding anhydrous magnesium sulfate thereto. After filtration, the filtrate was concentrated under reduced pressure, thereby yielding 12.3 g (yield: 81%) of pentaerythritol-tetra(2-bromoethoxymethyl)ether.

### Synthesis Example 1-2

### Synthesis of Monodisperse Polymer (a) that Provides Arm Portions (Polymer Chain)

Under a nitrogen atmosphere, 119.5 g of tetrahydrofuran (hereinafter abbreviated as “THF”) was cooled to −60° C. Thereafter, 15 mmol of s-butyl lithium was added thereto with continuous stirring while maintaining the temperature at −60° C. Then, 24.5 g of p-(1-ethoxyethoxy)styrene (hereafter, abbreviated as “PEES”) was dropwise added thereto over 50 minutes with continuous stirring while maintaining the temperature at −60° C., and the reaction was further continued for 1 hour. At this stage, a small amount of the reaction solution was collected, and the reaction was terminated by the addition of methanol. Then, an analysis was conducted by gel permeation chromatography (hereinafter abbreviated as “GPC”). As a result, the obtained PEES polymer was a monodisperse polymer (a) having Mn=1,450 and Mw/Mn=1.20 (in terms of the polystyrene equivalent values).

### Synthesis Example 1-3

### Reaction of Coupling Agent for Anionic Polymerization with Monodisperse Polymer (a)

Subsequently, while maintaining the temperature of the reaction system of Synthesis Example 1-2 at −60° C., 3.2 g of pentaerythritol-tetra(2-bromoethoxymethyl)ether obtained in Synthesis Example 1-1 was dropwise added thereto over 10 minutes, and the reaction was further continued for 1 hour. Then, the reaction was terminated by adding methanol to the reaction system, followed by an analysis conducted by GPC. As a result, the obtained acid decomposable polymer was a monodisperse polymer (A1′) having Mn=3,670 and Mw/Mn=1.24 (in terms of the polystyrene equivalent values).

Since an increase in the molecular weight was observed while the polymer retained a monodisperse state before and after the reaction of pentaerythritol-tetra(2-bromoethoxymethyl)ether, it was confirmed that a monodisperse polymer (A1′) having a star shape was obtained as designed.

### Synthesis Example 1-4

### Hydrolysis of Monodisperse Polymer (A1′) (Removal of Protecting Group of Arm Portions)

To the polymerization solution obtained in Synthesis Example 1-3, methyl isobutyl ketone (hereinafter abbreviated as “MIBK”) was added, and the resulting organic layer was washed twice with ion exchanged water. Thereafter, the organic layer was subjected to a concentration operation under reduced pressure to prepare an MIBK solution containing 40% by weight of a polymer, and the resulting solution was further prepared into a solution containing 20% by weight of a polymer by the addition of isopropyl alcohol (hereinafter abbreviated as “IPA”).

To 100 parts by weight of this solution, 1 part by weight of oxalic acid dihydrate and 2 parts by weight of ion exchanged water were added, followed by heating to 50° C. Thereafter, the reaction was further continued for 6 hours with continuous stirring while maintaining the temperature at 50° C.

In this reaction, analytical results of the polymer by ¹³C-NMR obtained before and after the reaction were compared. An absorption attributed to a PEES polymer observed at about 117 ppm disappeared after the reaction, and an absorption attributed to a p-hydroxystyrene polymer was newly observed at about 115 ppm. Furthermore, it was confirmed that a peak attributed to the O—CH₂—O bond observed at about 96 ppm was retained before and after hydrolysis.

Further, a measurement was conducted by GPC with respect to the polymer after the reaction. As a result, Mn was 2,560 (in terms of the polystyrene equivalent value), and no great change in the peak shape was observed before and after the reaction.

From the observations described above, the hydrolysis reaction was conducted as designed to obtain an alkenylphenol-type polymer containing a p-hydroxystyrene (hereinafter abbreviated as “PHS”) segment as a main skeleton. Furthermore, it was also confirmed that the O—CH₂—O bond introduced into the main chain skeleton was retained, thereby retaining the star shape.

### Synthesis Example 1-5

### Introduction of a 2-Adamantyloxymethyl Group

MIBK was added to the polymer solution obtained in Synthesis Example 1-4, and the resulting organic layer was washed three times with ion exchanged water. Thereafter, the organic layer was subjected to a concentration operation under reduced pressure to prepare a solution containing 50% by weight of a polymer, and then the resulting solution was further prepared into a solution containing 10% by weight a polymer by the addition of THF.

To 130.5 g of the obtained polymer solution, 2.2 g of 60% sodium hydride was added, and the resulting mixture was maintained at room temperature for 30 minutes with continuous stirring. Then, 4.8 g of 2-(chloromethoxy)adamantane was dropwise added thereto over 5 minutes, and the reaction was further continued at room temperature for 12 hours.

After the reaction was terminated by adding an aqueous oxalic acid solution to the reaction system, MIBK was added thereto, and the resulting organic layer was washed three times with ion exchanged water. Then, the organic layer was replaced with a propylene glycol monomethyl ether acetate (hereinafter abbreviated as “PGMEA”) solution through a concentration operation under reduced pressure.

The obtained polymer was analyzed by ¹³C-NMR. As a result, absorptions attributed to a unit (hereinafter, abbreviated as “PHS-MOAd”) in which a 2-adamantyloxymethyl group was introduced into PHS were newly observed at about 82 ppm, 93 ppm and 116 ppm. Further, the ratio of the PHS unit to PHS-MOAd was 75/25. Furthermore, it was confirmed that a peak attributed to the O—CH₂—O bond introduced into the main chain skeleton at about 96 ppm was retained.

Further, a measurement was conducted by GPC with respect to the polymer after the reaction. As a result, the polymer was a monodisperse polymer having Mn=2,790 and Mw/Mn=1.3 (in terms of the polystyrene equivalent values), and no change in the peak shape was observed before and after the reaction.

From the observations described above, it was confirmed that the introduction of 2-adamantyloxymethyl groups was conducted as designed to obtain an alkenylphenol-type polymer containing a PHS/PHS-MOAd segment as a main skeleton, and that the O—CH₂—O bond introduced into the main chain skeleton was retained, thereby retaining the star shape.

The structure of the polymer (A)-1 synthesized by the above synthesis method is shown below.

In chemical formulas shown below, each of the subscript numerals at the lower right of the brackets indicate the amount (mol %; composition ratio) of the respective structural units, based on the combined total of all structural units constituting the polymer chain as arm portions of the polymer (A)-1, and each amount was calculated by ¹³C-NMR.

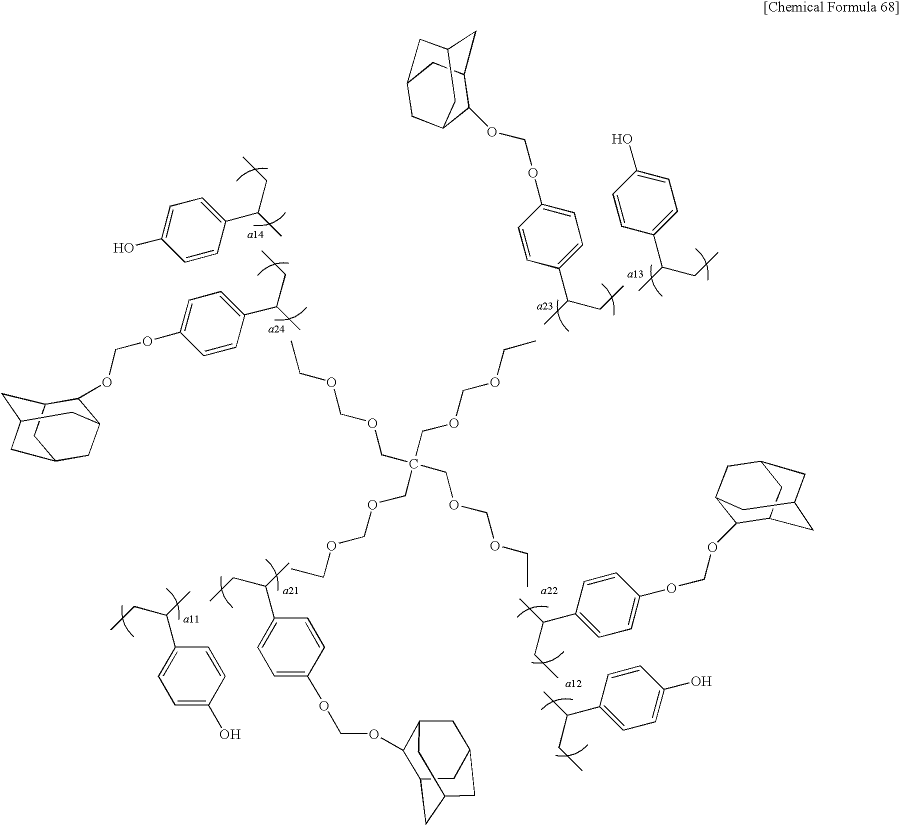

[(a11+a12+a13+a14)/(a21+a22+a23+a24)=75/25 (molar ratio); Mn=2,790, Mw/Mn=1.3]

### Synthesis Example 2

### Synthesis of Polymer (A)-2

10 g of poly-4-hydroxystyrene (Mw=4,000, Mw/Mn=1.1) was dissolved in 100 ml of THF, and 0.92 g of sodium hydride was then added thereto. To the resulting solution, 4.37 g of 2-adamantoxymethyl chloride was added, followed by stirring at room temperature for 20 hours. Following stirring, the reaction was terminated by adding water, and the reaction solution was then concentrated. Thereafter, the reaction solution was diluted with 400 ml of water, extracted three times with 100 ml of ethyl acetate, and then washed in turn with hydrochloric acid, a saturated aqueous NaHCO₃ solution and a saturated aqueous NaCl solution. The obtained solution was concentrated, purified by reprecipitation with a mixed solvent of ethyl acetate and n-heptane, and then dried to obtain a white solid.

GPC analysis revealed that the obtained polymer (A)-2 had Mw=4,200 and Mw/Mn=1.1 (polystyrene equivalent values). Further, the composition ratio (molar ratio) was calculated by ¹³C-NMR and ¹H-NMR.

The structure of the polymer (A)-2 synthesized by the above Synthesis Example 2 is shown below.

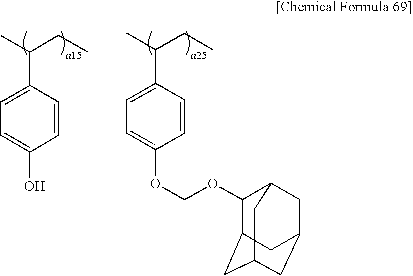

[a15/a25=75/25 (molar ratio); Mw=4,200, Mw/Mn=1.1]

### Synthesis Example 3

### Synthesis of Star Polymers (Polymers (A)-3 to (A)-11)

### Synthesis Examples 3-1 to 3-2

### Synthesis of Arm Portions (Polymer Chains) and Synthesis of Acid Decomposable Polymer

Acid decomposable polymers, each having a polymer chain of different molecular weight shown in Table 1 were obtained in the same manner as in Synthesis Example 1-2, with the exception that the amount of PEES dropwise added was changed as shown in Table 1.

TABLE 1

| | Amount of | | | Acid decomposable | Acid decomposable |
|---|---|---|---|---|---|
| | PEES added | Polymer chain | Polymer chain | polymer | polymer |
| | dropwise | Mn | Mw/Mn | Mn | Mw/Mn |
| Synthesis | 16.3 g | 990 | 1.22 | 3,000 | 1.26 |
| Example 3-1 | | | | | |
| Synthesis | 32.8 g | 1,860 | 1.10 | 4,100 | 1.34 |
| Example 3-2 | | | | | |

### Synthesis Examples 3-3 to 3-4

### Hydrolysis of PEES (Removal of Protecting Group)

Star polymers shown in Table 2 which contained a PHS segment as the main skeleton of arm portions were obtained in the same manner as in Synthesis Example 1-4, with the exception that the polymerization solution obtained in Synthesis Example 3-1 or Synthesis Example 3-2 was used instead of the polymerization solution obtained in Synthesis Example 1-3.

TABLE 2

| | | Star | Star |
|---|---|---|---|
| | | polymer | polymer |
| | Polymerization solution | Mn | Mw/Mn |
| Synthesis Example 3-3 | Synthesis Example 3-1 | 1,830 | 1.29 |
| Synthesis Example 3-4 | Synthesis Example 3-2 | 2,660 | 1.31 |

### Synthesis Examples 3-5 to 3-13

### Introduction of 2-(2-methyl)adamantyl acetate Group]

To each of the polymer solutions obtained in Synthesis Example 1-4, Synthesis Example 3-3 and Synthesis Example 3-4, MIBK was added, and the resulting organic layer was washed three times with ion exchanged water. Thereafter, the organic layer was concentrated under reduced pressure to prepare a solution containing 50% by weight of a polymer, and then the resulting solution was further prepared into a solution containing 10% by weight of a polymer by the addition of acetone.

To 50.0 g of the obtained polymer solution, 3.5 g of potassium carbonate was added, and the resulting mixture was kept at room temperature for 30 minutes with stirring. Then, 2-(2-methyl)adamantyl iodoacetate was added thereto in the amount indicated in Table 3, and the reaction was further continued at 35° C. for 8 hours.

MIBK was then added to the reaction system, and the resulting organic layer was washed once with an aqueous oxalic acid solution, and then washed three times with ion exchanged water. Thereafter, the organic layer was replaced with a PGMEA solution through a concentration operation under reduced pressure.

TABLE 3

| | | 2-(2-Methyl)adamantyl |
|---|---|---|
| | Polymer | iodoacetate |
| Synthesis Example 3-5 | Synthesis Example 1-4 | 1.6 g |
| Synthesis Example 3-6 | | 2.8 g |
| Synthesis Example 3-7 | | 4.0 g |
| Synthesis Example 3-8 | Synthesis Example 3-3 | 1.6 g |
| Synthesis Example 3-9 | | 2.8 g |
| Synthesis Example 3-10 | | 3.8 g |
| Synthesis Example 3-11 | Synthesis Example 3-4 | 1.8 g |
| Synthesis Example 3-12 | | 3.0 g |
| Synthesis Example 3-13 | | 4.3 g |

With respect to the obtained polymer, a measurement by ¹³C-NMR was conducted. As a result, absorptions attributed to a unit (hereafter, referred to as PHS-OAdE) in which a 2-(2-methyl)adamantyl acetate group was introduced into PHS were newly observed at about 89 ppm, 114 ppm and 169 ppm.

Further, the ratio of the PHS unit to PHS-OAdE was as shown in Table 4.

TABLE 4

| | PHS/PHS-OAdE |
|---|---|
| Synthesis Example 3-5 | 86/14 |
| Synthesis Example 3-6 | 76/24 |
| Synthesis Example 3-7 | 66/34 |
| Synthesis Example 3-8 | 86/14 |
| Synthesis Example 3-9 | 77/23 |
| Synthesis Example 3-10 | 67/33 |
| Synthesis Example 3-11 | 86/14 |
| Synthesis Example 3-12 | 82/18 |
| Synthesis Example 3-13 | 73/27 |

Further, it was confirmed that a peak at about 96 ppm attributed to the —O—CH₂—O— bond introduced into the core portion of a polymer was retained.

Furthermore, a GPC measurement was conducted with respect to the polymer after the reaction. As a result, it became clear that the polymer was a monodisperse polymer having Mn and Mw/Mn values shown in Table 5, and no change in the peak shape in the GPC measurement was observed before and after the introduction of 2-(2-methyl)adamantyl acetate group.

TABLE 5

| | Mn | Mw/Mn |
|---|---|---|
| Synthesis Example 3-5 | 2,900 | 1.23 |
| Synthesis Example 3-6 | 2,600 | 1.25 |
| Synthesis Example 3-7 | 3,200 | 1.22 |
| Synthesis Example 3-8 | 2,500 | 1.13 |
| Synthesis Example 3-9 | 2,700 | 1.13 |
| Synthesis Example 3-10 | 3,000 | 1.13 |
| Synthesis Example 3-11 | 3,700 | 1.12 |
| Synthesis Example 3-12 | 3,800 | 1.12 |
| Synthesis Example 3-13 | 4,300 | 1.10 |

From the results shown above, it was confirmed that an alkenylphenol-based polymer containing a PHS/PHS-OAdE segment as the main skeleton of arm portions was obtained, and that an acetal bond introduced into the core portion of the polymer was retained, and the polymer retained a star shape.

Hereafter, the polymers obtained in Synthesis Examples 3-5 to 3-13 will be referred to by the names shown in Table 6.

TABLE 6

| | Name |
|---|---|
| Synthesis Example 3-5 | Polymer (A)-3 |
| Synthesis Example 3-6 | Polymer (A)-4 |
| Synthesis Example 3-7 | Polymer (A)-5 |
| Synthesis Example 3-8 | Polymer (A)-6 |
| Synthesis Example 3-9 | Polymer (A)-7 |
| Synthesis Example 3-10 | Polymer (A)-8 |
| Synthesis Example 3-11 | Polymer (A)-9 |
| Synthesis Example 3-12 | Polymer (A)-10 |
| Synthesis Example 3-13 | Polymer (A)-11 |

The structures of the polymers (A)-3 to (A)-11 are shown below. In the chemical formulas shown below, each of the subscript numerals at the lower right of the brackets indicate the amount (mol %; composition ratio) of the respective structural units, based on the combined total of all structural units constituting the polymer chain as arm portions of the polymers (A)-3 to (A)-11, and each amount was calculated by ¹³C-NMR as shown in Table 4.

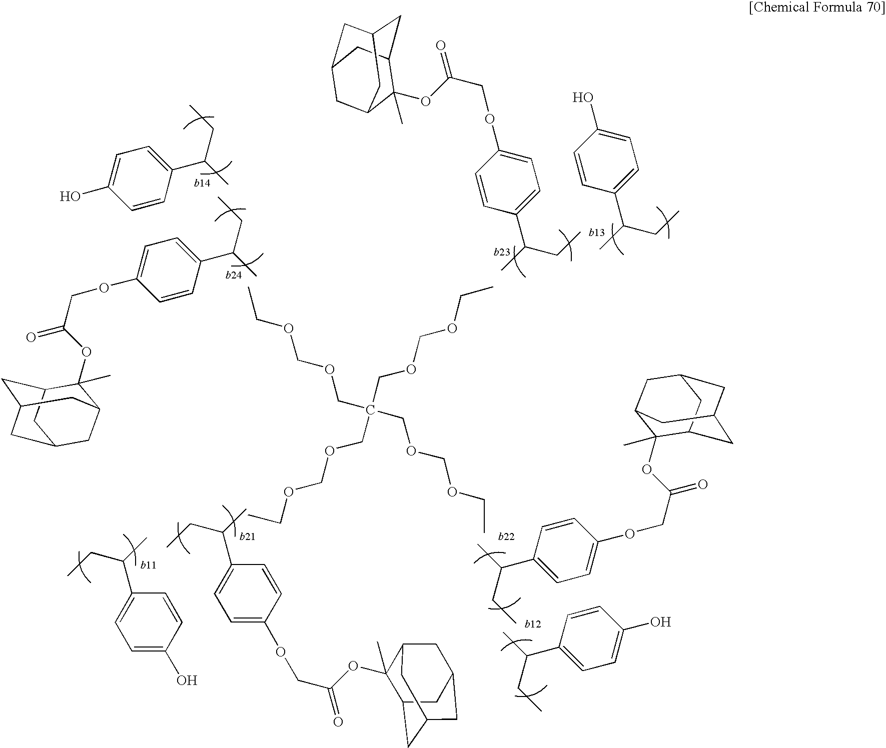

[(b11+b12+b13+b14)/(b21+b22+b23+b24)=percentage (molar ratio) of each structural unit]

### Synthesis Example 4

### Synthesis of Star Polymer (Polymer (A)-12)

5 g of poly-4-hydroxystyrene (Mn=2,900, Mw/Mn=1.06) was dissolved in 45 g of acetone, and 3.5 g of potassium carbonate was added thereto, and the resulting mixture was kept at room temperature for 30 minutes with stirring. Then, 3.5 g of 2-(2-methyl)adamantyl iodoacetate was added thereto, and the reaction was further continued at 35° C. for 8 hours.

MIBK was then added to the reaction system, and the resulting organic layer was washed once with an aqueous oxalic acid solution, and then washed three times with ion exchanged water. Thereafter, the organic layer was replaced with a PGMEA solution through a concentration operation under reduced pressure.

A GPC measurement was conducted. As a result, the obtained polymer (A)-12 had Mn=4,300 and Mw/Mn=1.05 (in terms of the polystyrene equivalent values). Further, the composition ratio (molar ratio) was calculated by ¹³C-NMR.

The structure of the polymer (A)-12 synthesized by the above Synthesis Example 4 is shown below. In the chemical formula shown below, each of the subscript numerals shown to the bottom right of the parentheses ( ) indicate the composition ratio (molar ratio) of the respective structural units.

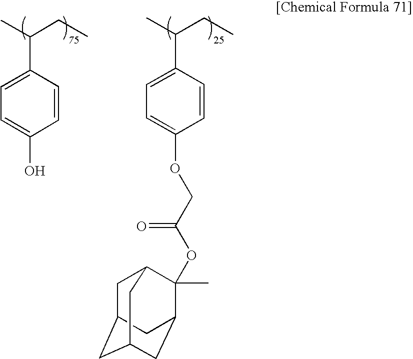

### Synthesis Example 5

### Synthesis of Star Polymer (Polymer (A)-13)

### Synthesis Example 5-1

### Synthesis of Coupling Agent for Anionic Polymerization

Under a nitrogen atmosphere, to 12.3 g of dipentaerythritol, 234.1 g of acetone, 50.1 g of diisopropylethylamine and 50.0 g of 2-chloroethyl chloromethyl ether were added, and the resulting mixture was kept at 50° C. for 4 hours with stirring. Thereafter, ethyl acetate was added to the reaction mixture, and the resulting organic layer was washed four times with an aqueous oxalic acid solution and ion exchanged water. Then, the obtained organic layer was concentrated under reduced pressure, thereby yielding 39.0 g (yield: 99%) of dipentaerythritol-hexa(2-chloroethoxymethyl)ether.

Under a nitrogen atmosphere, to 20.0 g of the aforementioned dipentaerythritol-hexa(2-chloroethoxymethyl)ether, 480.0 g of hexamethylphosphoric acid triamide, 161.6 g of bromoethane and 3.1 g of sodium bromide were added, and the resulting mixture was kept at 80° C. for 3 hours with stirring. Thereafter, the reaction mixture was concentrated under reduced pressure. To the obtained concentrated mixture, 107.7 g of bromoethane was newly added, and the resulting mixture was kept at 80° C. for 3 hours with stirring. Thereafter, the reaction mixture was concentrated under reduced pressure, and methyl t-butyl ether was added to the obtained concentrated mixture. Then, the resulting organic layer was washed four times with ion exchanged water. Then, the organic layer was dried by adding anhydrous magnesium sulfate thereto. After filtration, the filtrate was concentrated under reduced pressure, thereby yielding 10.5 g (yield: 39%) of dipentaerythritol-hexa(2-bromoethoxymethyl)ether as a coupling agent for anionic polymerization.

### Synthesis Example 5-2

### Synthesis of Arm Portions (Polymer Chains) and Synthesis of Acid Decomposable Polymer

Under a nitrogen atmosphere, 263.5 g of THF was cooled to −60° C. 30 mmol of s-butyl lithium was added thereto with stirring while maintaining the temperature at −60° C., and 42.4 g of PEES was then dropwise added thereto over 50 minutes, and the reaction was further continued for 1 hour.

At this stage, a small amount of the reaction solution was collected, and the reaction was terminated by the addition of methanol. Then, a GPC measurement was conducted. As a result, the obtained PEES polymer was a monodisperse polymer having Mn=1,430 and Mw/Mn=1.13 (in terms of the polystyrene equivalent values).

Subsequently, while maintaining the temperature of the reaction system at −60° C., 6.6 g of dipentaerythritol-hexa(2-bromoethoxymethyl)ether obtained in Synthesis Example 5-1 was dropwise added thereto over 10 minutes, and the reaction was further continued for 1 hour.

Then, the reaction was terminated by adding methanol to the reaction system and a GPC measurement was conducted. As a result, the obtained acid decomposable polymer was a monodisperse polymer having Mn=3,620 and Mw/Mn=1.42 (in terms of the polystyrene equivalent values).

In other words, it was confirmed that the polymer exhibited an increase in the molecular weight after the reaction of dipentaerythritol-hexa(2-bromoethoxymethyl)ether while retaining a monodisperse state as one before the reaction, and that the polymer was converted into a polymer having a star shape.

### Synthesis Example 5-3

### Hydrolysis of PEES (Removal of Protecting Group)

To the polymerization solution obtained in Synthesis Example 5-2, MIBK was added, and the resulting organic layer was washed twice with ion exchanged water. The organic layer was then subjected to a concentration operation under reduced pressure to prepare an MIBK solution containing 40% by weight of a polymer, and the resulting solution was further prepared into a solution containing 20% by weight of a polymer by the addition of IPA.

To 100 parts by weight of this solution, 1 part by weight of oxalic acid dihydrate and 2 parts by weight of ion exchanged water were added, followed by heating to 50° C. The reaction was further continued for 8 hours with stirring while maintaining the temperature at 50° C.

In this reaction, ¹³C-NMR measurement was conducted on the polymer before and after the reaction, and then the results were compared. An absorption attributed to a PEES polymer observed at about 117 ppm disappeared after the reaction, and an absorption attributed to a p-hydroxystyrene polymer was newly observed at about 115 ppm. Furthermore, it was confirmed that a peak attributed to an acetal bond (—O—CH₂—O—) observed at about 96 ppm was retained before and after hydrolysis.

Further, a measurement was conducted by GPC with respect to the polymer after the reaction. As a result, Mn was 2,000 (in terms of the polystyrene equivalent value), and no great change in the peak shape was observed before and after the reaction.

From the results described above, it was confirmed that the hydrolysis reaction proceeded in an ethoxyethoxy group of PEES to obtain an alkenylphenol-type polymer containing a p-hydroxystyrene (hereafter abbreviated as “PHS”) segment as the main skeleton of arm portions. It was also confirmed that the —O—CH₂—O— bond introduced into the core portion of the polymer was retained, and the polymer retained a star shape after the reaction.

### Synthesis Example 5-4

### Introduction of 2-(2-methyl)adamantyl acetate Group

MIBK was added to the polymer solution obtained in Synthesis Example 5-3, and the resulting organic layer was washed three times with ion exchanged water. Thereafter, the organic layer was concentrated under reduced pressure to prepare a solution containing 50% by weight of a polymer, and then the resulting solution was further prepared into a solution containing 10% by weight of a polymer by the addition of acetone.

To 50.0 g of the obtained polymer solution, 3.5 g of potassium carbonate was added, and the resulting mixture was kept at room temperature for 30 minutes with stirring. Then, 11.7 g of 2-(2-methyl)adamantyl iodoacetate was added thereto, and the reaction was further continued at 35° C. for 8 hours.

MIBK was then added to the reaction system, and the resulting organic layer was washed once with an aqueous oxalic acid solution, and then washed three times with ion exchanged water. Thereafter, the organic layer was replaced with a PGMEA solution through a concentration operation under reduced pressure.

With respect to the obtained polymer, a measurement by ¹³C-NMR was conducted. As a result, absorptions attributed to a unit (hereafter, referred to as PHS-OAdE) in which a 2-(2-methyl)adamantyl acetate group was introduced into PHS were newly observed at about 89 ppm, 114 ppm and 169 ppm.

Further, the ratio of the PHS unit to PHS-OAdE was 80/20.

Further, it was confirmed that a peak at about 96 ppm attributed to the -O-CH₂-O-bond introduced into the core portion of a polymer was retained.

Furthermore, a GPC measurement was conducted with respect to the polymer after the reaction. As a result, it became clear that the polymer was a monodisperse polymer having Mn=4,200 and Mw/Mn=1.34, and no change in the peak shape in the GPC measurement was observed before and after the introduction of 2-(2-methyl)adamantyl acetate group.

From the results shown above, it was confirmed that an alkenylphenol-type polymer containing a PHS/PHS-OAdE segment as the main skeleton of arm portions was obtained, and that an acetal bond introduced into the core portion of the polymer was retained, and the polymer retained a star shape.

The structure of the polymer obtained in Synthesis Example 5-4 above (hereafter, referred to as a polymer (A)-13) is shown below. In the chemical formulas shown below, each of the subscript numerals at the lower right of the brackets indicate the amount (mol %; composition ratio) of the respective structural units, based on the combined total of all structural units constituting the polymer chain as arm portions of the polymer (A)-13, and each amount was calculated by ¹³C-NMR.

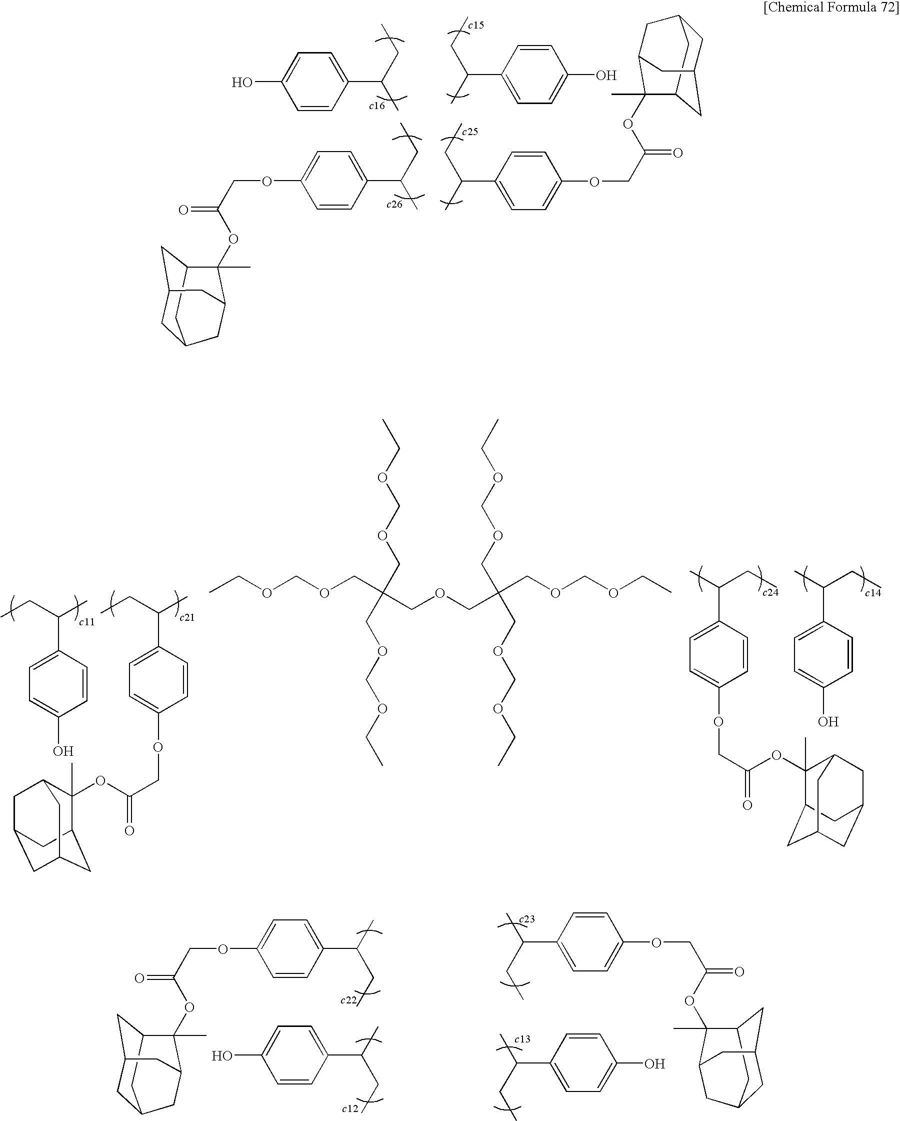

[(c11+c12+c13+c14+c15+c16)/(c21+c22+c23+c24+c25+c26)=80/20 (molar ratio); Mw=4,200, Mw/Mn=1.34]

### Synthesis Example 6

### Synthesis of Star Polymer (Polymer (A)-14)

### Synthesis Example 6-1

### Introduction of (1-adamantyloxy)ethyl Group

MIBK was added to the polymer solution obtained in Synthesis Example 1-4, and the resulting organic layer was washed three times with ion exchanged water. Thereafter, the organic layer was concentrated under reduced pressure to prepare a PGMEA solution containing 30% by weight of a polymer.

To 50.0 g of the obtained polymer solution, 0.7 g of trifluoroacetic acid was added, and the resulting mixture was heated to 30° C. with stirring. Then, 9.4 g of 1-adamantyl vinyl ether was added thereto, and the reaction was further continued at 30° C. for 3 hours.

After the reaction was terminated by adding triethylamine thereto, MIBK was added to the reaction system, and the resulting organic layer was washed three times with ion exchanged water. Thereafter, the organic layer was replaced with a PGMEA solution through a concentration operation under reduced pressure.

With respect to the obtained polymer, a measurement by ¹³C-NMR was conducted. As a result, absorptions attributed to units (hereafter, referred to as PHS-AdVE) in which an (1-adamantyloxy)ethyl group was introduced into PHS were newly observed at about 94 ppm, 118 ppm and 156 ppm.

Further, the ratio of the PHS unit to PHS-AdVE was 80/20.

Further, it was confirmed that a peak at about 96 ppm attributed to the —O—CH₂—O-bond introduced into the core portion of the polymer was retained.

Furthermore, a GPC measurement was conducted with respect to the polymer after the reaction. As a result, it became clear that the polymer was a monodisperse polymer having Mn=3,400 and Mw/Mn=1.22, and no great change in the peak shape in the GPC measurement was observed before and after the introduction of (1-adamantyloxy)ethyl groups.

From the results shown above, it was confirmed that an alkenylphenol-type polymer containing a PHS/PHS-AdVE segment as the main skeleton of arm portions was obtained, and that an acetal bond introduced into the core portion of the polymer was retained, and the polymer retained a star shape.

The structure of the polymer obtained in Synthesis Example 6-1 above (hereafter, referred to as a polymer (A)-14) is shown below. In the chemical formulas shown below, each of the subscript numerals at the lower right of the brackets indicate the amount (mol %; composition ratio) of the respective structural units, based on the combined total of all structural units constituting the polymer chain as arm portions of the polymer (A)-14, and each amount was calculated by ¹³C-NMR.

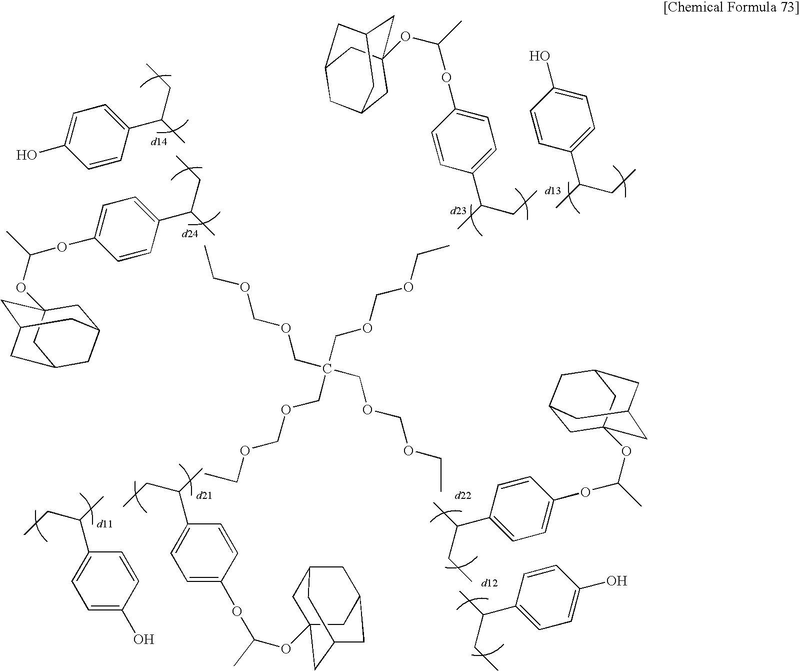

d11+d12+d13+d14)/(d21+d22+d23+d24)=80/20 (molar ratio); Mw=3,400, Mw/Mn=1.22]

### Synthesis Example 7

### Synthesis of Comb Polymer (Polymer (A)-15)

### Synthesis Example 7-1

### Trunk Polymer (Synthesis of Polymer (A0)-1)

### Synthesis Example 7-1-1

### Introduction of (2-chloroethoxy)methyl Group

In a nitrogen atmosphere, to 30.0 g of monodisperse p-hydroxystyrene polymer (hereafter, abbreviated as “PHS”) having Mn=2,700 and Mw/Mn=1.06, 270.0 g of tetrahydrofuran (hereafter, abbreviated as “THF”) and 9.0 g of sodium hydride were added. 35.4 g of 2-chloroethyl chloromethyl ether was then dropwise added thereto with stirring in an ice-cold bath over 20 minutes, and the resulting mixture was further kept at 30° C. for 4 hours with stirring. Thereafter, ethyl acetate was added to the reaction mixture, and the resulting organic layer was washed five times with an aqueous oxalic acid solution and ion exchanged water. Then, the obtained organic layer was concentrated under reduced pressure, thereby yielding a polymer represented by formula (01) shown below in the form of a 50 wt. % MIBK solution.

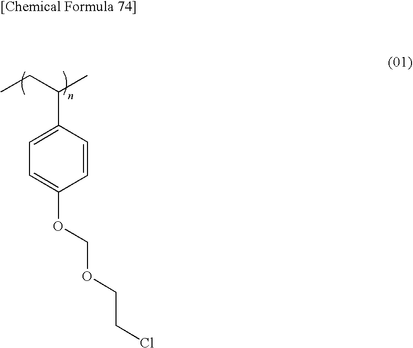

### [Mn=5,600, Mw/Mn=1.04]

### Synthesis Example 7-1-2

### Conversion to Bromine

In a nitrogen atmosphere, to 48.0 g of the polymer solution obtained in Synthesis Example 7-1-1, 552.0 g of hexamethyl phosphoric acid triamide (hereafter, abbreviated as “HMPA”), 123.0 g of bromoethane and 2.3 g of sodium bromide were added, followed by stirring for 4 hours while maintaining the temperature at 80° C. Thereafter, the reaction mixture was concentrated under reduced pressure. To the obtained concentrated mixture, 123.0 g of bromoethane was newly added, and the resulting mixture was kept at 80° C. for 4 hours with stirring. Thereafter, the reaction mixture was concentrated under reduced pressure, and toluene was added to the obtained concentrated mixture. Then, the resulting organic layer was washed four times with ion exchanged water. Then, the organic layer was dried by adding anhydrous magnesium sulfate thereto. After filtration, the filtrate was concentrated under reduced pressure, thereby yielding a polymer (A0)-1 represented by formula (A0)-1 shown below, which was to serve as a trunk portion of a comb polymer, in the form of a 40 wt. % toluene solution.

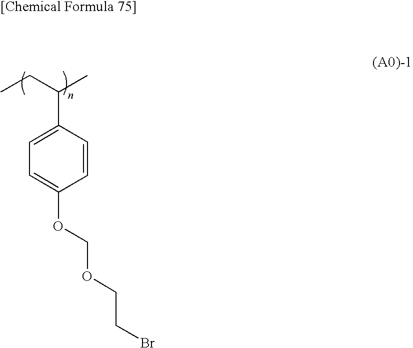

### [Mn=5,600, Mw/Mn=1.04]

### Synthesis Example 7-2

### Synthesis of Comb Polymer (Polymer (A)-15)

### Synthesis Example 7-2-1

### Synthesis of Branch Polymer and Synthesis of Acid Decomposable Polymer

Under a nitrogen atmosphere, 384.2 g of THF was cooled to −60° C. 74 mmol of s-butyl lithium was added thereto with stirring while maintaining the temperature at −60° C. Then, 73.3 g of p-(1-ethoxyethoxy)styrene (hereafter, abbreviated as “PEES”) was dropwise added thereto over 50 minutes with stirring while maintaining the temperature at −60° C., and the reaction was further continued for 1 hour. At this stage, a small amount of the reaction solution was collected, and the reaction was terminated by the addition of methanol. Then, an analysis was conducted by gel permeation chromatography (hereinafter abbreviated as “GPC”). As a result, the obtained PEES polymer was a monodisperse polymer having Mn=990 and Mw/Mn=1.24 (in terms of the polystyrene equivalent values).

Subsequently, while maintaining the temperature of the reaction system at −60° C., 56.9 g of the solution of the polymer (A0)-1 obtained in Synthesis Example 7-1-2 was dropwise added thereto over 40 minutes.

The reaction was further continued for 1 hour, and the reaction was then terminated by adding methanol to the reaction system, followed by an analysis conducted by GPC. As a result, the obtained acid decomposable polymer was a monodisperse polymer having Mn=14,500 and Mw/Mn=1.03 (in terms of the polystyrene equivalent values). Since an increase in the molecular weight was observed before and after the reaction with the polymer represented by formula (A0)-1 while the acid decomposable polymer retained a monodisperse state, it was confirmed that a polymer having a comb shape was obtained as designed.

### Synthesis Example 7-2-2

### Hydrolysis of PEES (Removal of Protecting Group)

MIBK was added to the polymerization solution obtained in Synthesis Example 7-2-1, and the resulting organic layer was washed twice with ion exchanged water. The organic layer was then subjected to a concentration operation under reduced pressure to prepare an MIBK solution containing 40% by weight of a polymer, and the resulting solution was further prepared into a solution containing 20% by weight of a polymer by the addition of isopropyl alcohol (hereafter, abbreviated as “IPA”).

To 100 parts by weight of this solution, 0.1 parts by weight of oxalic acid dihydrate and 9 parts by weight of ion exchanged water were added, followed by heating to 50° C. The reaction was further continued for 7 hours with stirring while maintaining the temperature at 50° C. In this reaction, analytical results of the polymer by ¹³C-NMR obtained before and after the reaction were compared. Absorptions attributed to a PEES polymer observed at about 117 ppm and 100 ppm disappeared after the reaction, and an absorption attributed to PHS was newly observed at about 115 ppm. Furthermore, it was confirmed that a peak attributed to the O—CH₂—O bond observed at about 94 ppm was retained before and after hydrolysis. Further, a measurement was conducted by GPC with respect to the polymer after the reaction. As a result, Mn was 10,900 (in terms of the polystyrene equivalent value), and no great change in the peak shape was observed before and after the reaction. From the observations described above, the hydrolysis reaction was conducted as designed to obtain an alkenylphenol-type polymer containing a PHS segment as a main skeleton. Furthermore, it was also confirmed that the O—CH₂—O bond introduced into the main chain skeleton was retained, thereby retaining the comb shape.

### Synthesis Example 7-2-3

### Introduction of 2(2-methyl)adamantyl acetate Group

MIBK was added to the polymer solution obtained in Synthesis Example 7-2-2, and the resulting organic layer was washed three times with ion exchanged water. Thereafter, the organic layer was concentrated under reduced pressure to prepare a solution containing 40% by weight of a polymer, and then the resulting solution was further prepared into a solution containing 10% by weight of a polymer by the addition of acetone.

To 160.0 g of the obtained polymer solution, 5.1 g of potassium carbonate was added, and the resulting mixture was kept at 50° C. for 30 minutes with stirring. Then, 7.97 g of 2-(2-methyl)adamantyl iodoacetate was added thereto, and the reaction was further continued at 50° C. for 5 hours.

MIBK was then added to the reaction system, and the resulting organic layer was washed once with an aqueous oxalic acid solution, and then washed three times with ion exchanged water. Thereafter, the organic layer was replaced with a PGMEA solution through a concentration operation under reduced pressure.

With respect to the obtained polymer, a measurement by ¹³C-NMR was conducted. As a result, absorptions attributed to a unit (hereafter, referred to as PHS-OAdE) in which a 2-(2-methyl)adamantyl acetate group was introduced into PHS were newly observed at about 89 ppm, 114 ppm and 169 ppm.

Further, the ratio of the PHS unit to PHS-OAdE was 75/25. Furthermore, it was confirmed that a peak attributed to the O—CH₂—O bond introduced into the main chain skeleton at about 94 ppm was retained. Further, a measurement was conducted by GPC with respect to the polymer after the reaction. As a result, the polymer was a monodisperse polymer having Mn=12,800 and Mw/Mn=1.03 (in terms of the polystyrene equivalent values), and no change in the peak shape was observed before and after the reaction. From the observations described above, it was confirmed that the introduction of a 2-(2-methyl)adamantyl acetate group was conducted as designed to obtain an alkenylphenol-type polymer containing a PHS/PHS-OAdE segment as a main skeleton, and that the O—CH₂—O bond introduced into the main chain skeleton was retained, thereby retaining the comb shape.

The structure of the polymer obtained in Synthesis Example 7-2-3 above (hereafter, referred to as a polymer (A)-15) is shown below. In the chemical formula shown below, each of the subscript numerals at the lower right of the brackets indicate the amount (mol %; composition ratio) of the respective structural units, based on the combined total of all structural units constituting the polymer chain as a branch portion of the polymer (A)-15, and each amount was calculated by ¹³C-NMR. The formula (A)-15 shown below indicates that the carbon atoms of the ethylene group in the trunk polymer are bonded to the ends of the main chain in the units (a1) and (a2) of the branch polymer.

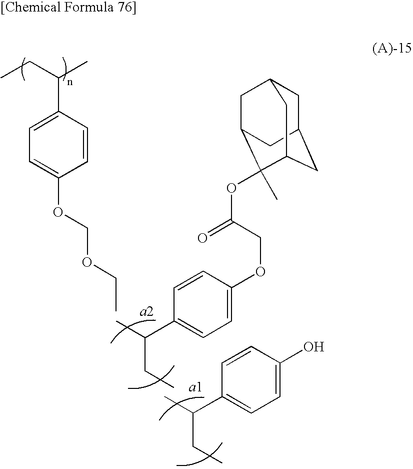

[(a1)/(a2)=75/25 (molar ratio); Mn=12,800, Mw/Mn=1.08]

### Synthesis Example 7-3

### Trunk Polymer (Synthesis of Polymers (A0)-2 to (A0)-3)

### Synthesis Examples 7-3-1 to 7-3-2

### Introduction of (2-chloroethoxy)methyl Group

In a nitrogen atmosphere, to 40.0 g of monodisperse PHS having Mn=2,700 and Mw/Mn=1.06, 360.0 g of THF and sodium hydride (in the amounts indicated in Table 7 below) were added. 2-Chloroethyl chloromethyl ether was then dropwise added thereto in the amounts indicated in Table 7 below with stirring in an ice-cold bath over 20 minutes, and the resulting mixture was further kept at 30° C. for 4 hours with stirring.

TABLE 7

| | | Amount of 2-chloroethyl |
|---|---|---|
| | Amount of sodium | chloromethyl ether |
| | hydride added | added dropwise |
| Synthesis Example 7-3-1 | 3.6 g | 13.8 g |
| Synthesis Example 7-3-2 | 8.4 g | 32.6 g |

Thereafter, MIBK was added to the reaction mixture, and the resulting organic layer was washed five times with an aqueous oxalic acid solution and ion exchanged water. Then, the obtained organic layer was concentrated under reduced pressure, thereby yielding a polymer represented by formula (03) and Table 8 shown below in the form of a 50 wt. % MIBK solution.

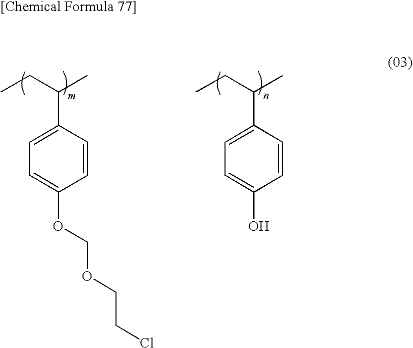

TABLE 8

| | Mn | Mw/Mn | m/n (molar ratio) |
|---|---|---|---|
| Synthesis Example 7-3-1 | 3,900 | 1.07 | 30/70 |
| Synthesis Example 7-3-2 | 5,200 | 1.06 | 70/30 |

### Synthesis Examples 7-3-3 to 7-3-4

### Conversion to Bromine

In a nitrogen atmosphere, to 50.0 g of the polymer solution obtained in Synthesis Example 7-3-1 or Synthesis Example 7-3-2, HIVIPA, bromoethane and sodium bromide were added in the amounts indicated in Table 9 below, followed by stirring for 6 hours while maintaining the temperature at 80° C.

TABLE 9

| | Polymer | Amount of | Amount of | Amount of |
|---|---|---|---|---|
| | solution | HMPA | bromoethane | sodium bromide |
| | used | added | added | added |
| Synthesis | Synthesis | 575.0 g | 184.2 g | 3.5 g |
| Example | Example | | | |
| 7-3-3 | 7-3-1 | | | |
| Synthesis | Synthesis | 575.0 g | 147.3 g | 2.8 g |
| Example | Example | | | |
| 7-3-4 | 7-3-1 | | | |

Thereafter, the reaction mixture was concentrated under reduced pressure. To the obtained concentrated mixture, bromoethane was newly added in the amount indicated in Table 10 below, and the resulting mixture was kept at 80° C. for 6 hours with stirring.

TABLE 10

| | Amount of |
|---|---|
| | bromoethane added |
| Synthesis Example 7-3-3 | 184.2 g |
| Synthesis Example 7-3-4 | 147.3 g |

Thereafter, the reaction mixture was concentrated under reduced pressure, and MIBK was added to the obtained concentrated mixture. Then, the resulting organic layer was washed four times with ion exchanged water. Then, the organic layer was concentrated under reduced pressure, and the obtained polymer solution was reprecipitated with n-hexane. The obtained polymer powder was dried under reduced pressure, thereby yielding a polymer represented by formula (04) and Table 11 shown below.

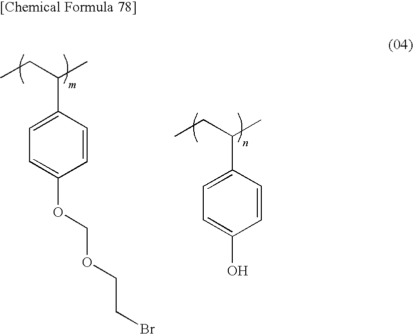

TABLE 11

| | Mn | Mw/Mn | m/n (molar ratio) |
|---|---|---|---|
| Synthesis Example 7-3-3 | 2,900 | 1.36 | 30/70 |
| Synthesis Example 7-3-4 | 3,800 | 1.40 | 70/30 |

### Synthesis Examples 7-3-5 to 7-3-6

### Introduction of Ethoxyethyl Group

In a nitrogen atmosphere, to 20.0 g of the polymer obtained in Synthesis Example 7-3-3 or Synthesis Example 7-3-4, THF, trifluoroacetic acid and ethyl vinyl ether were added in the amounts indicated in Table 12 below, followed by stirring for 5 hours while maintaining the temperature at 30° C.

TABLE 12

| | | | Amount of | Amount of |
|---|---|---|---|---|
| | Polymer | Amount of | trifluoroacetic | ethyl vinyl |
| | used | THF added | acid added | ether added |
| Synthesis | Synthesis | 46.7 g | 1.1 g | 8.0 g |
| Example | Example | | | |
| 7-3-5 | 7-3-3 | | | |
| Synthesis | Synthesis | 46.7 g | 0.7 g | 4.0 g |
| Example | Example | | | |
| 7-3-6 | 7-3-4 | | | |

Thereafter, the reaction was terminated by adding triethylamine to the reaction liquid. Then, toluene was added thereto, and the resulting organic layer was washed four times with ion exchanged water. Then, the organic layer was dried by adding anhydrous magnesium sulfate thereto. After filtration, the filtrate was concentrated under reduced pressure, thereby yielding a polymer (A0)-2 or (A0)-3 represented by formula (A0)-2 or (A0)-2 and Table 13 shown below, which was to serve as a trunk portion of a comb polymer, in the form of a 40 wt. % toluene solution.

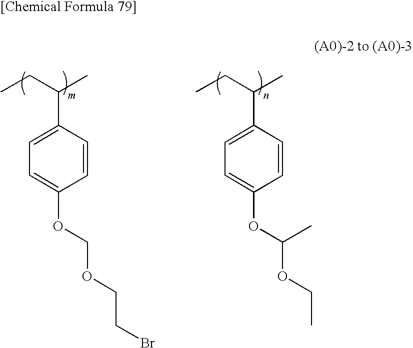

TABLE 13

| | Polymer | | | m/n |
|---|---|---|---|---|
| | name | Mn | Mw/Mn | (molar ratio) |
| Synthesis Example 7-3-5 | (A0)-2 | 5,700 | 1.64 | 30/70 |
| Synthesis Example 7-3-6 | (A0)-3 | 3,200 | 1.94 | 70/30 |

### Synthesis Example 7-4

### Production of Comb Polymers (Production of Polymers (A)-19 to (A)-20)

### Synthesis Examples 7-4-1 to 7-4-2

### Synthesis of Branch Polymer and Synthesis of Acid Decomposable Polymer

Under a nitrogen atmosphere, 179.8 g of THF was cooled to −60° C. 42 mmol of s-butyl lithium was added thereto with stirring while maintaining the temperature at −60° C. Then, 40.5 g of PEES was dropwise added thereto over 30 minutes with stirring while maintaining the temperature at −60° C., and the reaction was further continued for 1 hour. At this stage, a small amount of the reaction solution was collected, and the reaction was terminated by the addition of methanol. Then, an analysis was conducted by GPC. As a result, the obtained PEES polymer was a monodisperse polymer having Mn=970 and Mw/Mn=1.22 (in terms of the polystyrene equivalent values).

Subsequently, while maintaining the temperature of the reaction system at −60° C., the solution of the polymer (A0)-2 obtained in Synthesis Example 7-3-5 or the solution of the polymer (A0)-3 obtained in Synthesis Example 7-3-6 was dropwise added thereto over 40 minutes in the amount indicated in Table 14 below.

TABLE 14

| | | Amount of polymer solution |
|---|---|---|
| | Polymer used | added dropwise |
| Synthesis Example 7-4-1 | (A0)-2 | 86.4 g |
| Synthesis Example 7-4-2 | (A0)-3 | 42.7 g |

The reaction was further continued for 1 hour, and the reaction was then terminated by adding methanol to the reaction system, followed by an analysis conducted by GPC. As a result, the obtained acid decomposable polymer was a monodisperse polymer having Mn and Mw/Mn values indicated in Table 15 below.

TABLE 15

| | Mn | Mw/Mn |
|---|---|---|
| Synthesis Example 7-4-1 | 9,500 | 1.08 |
| Synthesis Example 7-4-2 | 12,900 | 1.05 |

Since an increase in the molecular weight was observed before and after the reaction with the trunk polymer while the acid decomposable polymer retained a monodisperse state, it was confirmed that a polymer having a comb shape was obtained as designed.

### Synthesis Examples 7-4-3 to 7-4-4

### Hydrolysis of PEES (Removal of Protecting Group)

MIBK was added to the polymerization solutions obtained in Synthesis Example 7-4-1 and Synthesis Example 7-4-2, and the resulting organic layers were washed twice with ion exchanged water. The organic layers were then subjected to a concentration operation under reduced pressure to prepare MIBK solutions containing 40% by weight of a polymer, and the resulting solutions were further prepared into a solution containing 20% by weight of a polymer by the addition of IPA.

To 100.0 g of these solutions, 0.5 g of oxalic acid dihydrate and 10.0 g of ion exchanged water were added, followed by heating to 50° C. The reaction was further continued for 1 hour with stirring while maintaining the temperature at 50° C. Further, a GPC analysis was conducted with respect to the polymers after the reaction. As a result, it was confirmed that polymers having Mn and Mw/Mn values indicated in Table 16 below were obtained.

TABLE 16

| | Polymerization liquid used | Mn | Mw/Mn |
|---|---|---|---|
| Synthesis Example 7-4-3 | Synthesis Example 7-4-1 | 6,400 | 1.10 |
| Synthesis Example 7-4-4 | Synthesis Example 7-4-2 | 9,500 | 1.09 |

Further, in this reaction, analytical results of the polymer by ¹³C-NMR obtained before and after the reaction were compared. Absorptions attributed to a PEES polymer observed at about 117 ppm and 100 ppm disappeared after the reaction, and an absorption attributed to a p-hydroxystyrene polymer was newly observed at about 115 ppm. Furthermore, it was confirmed that a peak attributed to the O—CH₂—O bond observed at about 94 ppm was retained before and after hydrolysis. Further, a measurement was conducted by GPC with respect to the polymer after the reaction. As a result, no great change in the peak shape was observed before and after the reaction. From the observations described above, the hydrolysis reaction was conducted as designed to obtain an alkenylphenol-type polymer containing a PHS segment as a main skeleton. Furthermore, it was also confirmed that the O—CH₂—O bond introduced into the main chain skeleton was retained, thereby retaining the comb shape.

### Synthesis Examples 7-4-5 to 7-4-6

### Introduction of 2-(methyl)adamantyl acetate Group

MIBK was added to the polymer solution obtained in Synthesis Example 7-4-3 or the polymer solution obtained in Synthesis Example 7-4-4, and the resulting organic layer was washed three times with ion exchanged water. Thereafter, the organic layer was concentrated under reduced pressure to prepare a solution containing 40% by weight of a polymer, and then the resulting solution was further prepared into a solution containing 10% by weight of a polymer by the addition of acetone.

To 200.0 g of the obtained polymer solution, potassium carbonate was added in the amount indicated in Table 17 below, and the resulting mixture was kept at 55° C. for 30 minutes with stirring. Then, 2(2-methyl)adamantyl iodoacetate was added thereto in the amount indicated in Table 17, and the reaction was further continued at 55° C. for 5 hours.

TABLE 17

| | | Amount of | Amount of 2-(2- |
|---|---|---|---|
| | Polymer solution | potassium | methyl)adamantyl |
| | used | carbonate added | iodoacetate added |
| Synthesis | Synthesis | 6.0 g | 9.5 g |
| Example 7-4-5 | Example 7-4-3 | | |
| Synthesis | Synthesis | 5.8 g | 9.0 g |
| Example 7-4-6 | Example 7-4-4 | | |

MIBK was then added to the reaction system, and the resulting organic layer was washed once with an aqueous oxalic acid solution, and then washed three times with ion exchanged water. Thereafter, the organic layer was replaced with a PGMEA solution through a concentration operation under reduced pressure.

With respect to the obtained polymer, a measurement by ¹³C-NMR was conducted. As a result, absorptions attributed to the PHS-OAdE unit were newly observed at about 89 ppm, 114 ppm and 169 ppm.

Furthermore, it was confirmed that a peak attributed to the O—CH₂—O bond introduced into the main chain skeleton at about 94 ppm was retained. Further, the ratio of the PHS unit to PHS-OAdE was as shown in Table 18 below. Furthermore, a measurement was conducted by GPC with respect to the polymer after the reaction. As a result, the polymer was a monodisperse polymer having Mn and Mw/Mn values indicated in Table 18, and no change in the peak shape was observed before and after the reaction.

TABLE 18

| | PHS/PHS-OAdE | Mn | Mw/Mn |
|---|---|---|---|
| Synthesis Example 7-4-5 | 75/25 | 7,100 | 1.18 |
| Synthesis Example 7-4-6 | 75/25 | 10,000 | 1.21 |

From the observations described above, it was confirmed that the introduction of a 2-(2-methyl)adamantyl acetate group was conducted as designed to obtain an alkenylphenol-type polymer containing a PHS/PHS-OAdE segment as a main skeleton, and that the O—CH₂—O bond introduced into the main chain skeleton was retained, thereby retaining the comb shape.

The structure of the obtained comb polymer is shown below. In the chemical formula shown below, each of the subscript numerals at the lower right of the brackets indicate the amount (mol %; composition ratio) of the respective structural units constituting the comb polymer, and each amount was calculated by ¹³C-NMR. The formula shown below indicates that the carbon atoms of the ethylene group in the (b3) unit of the trunk polymer are bonded to the ends of the main chain in the units (a1) and (a2) of the branch polymer.

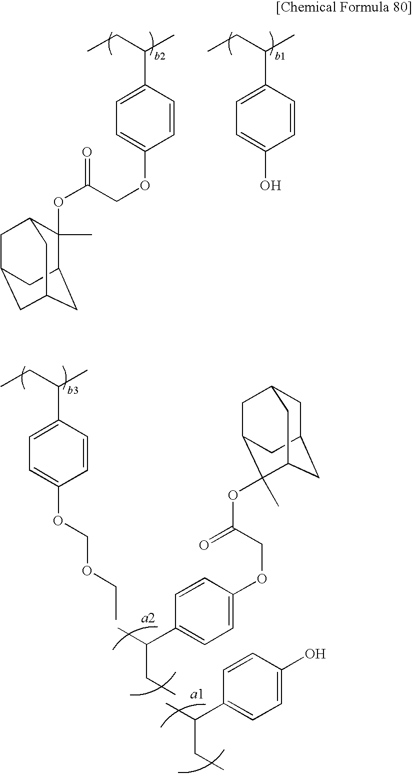

[(a1+b1)/(a2+b2)=(molar ratio; refer to Table 19)]
[b3/(b1+b2)=(molar ratio; refer to Table 19)]

TABLE 19

| | Polymer | (a1 + b1)/ | b3/ |
|---|---|---|---|
| | name | (a2 + b2) | (b1 + b2) |
| Synthesis Example 7-4-5 | (A)-19 | 75/25 | 30/70 |
| Synthesis Example 7-4-6 | (A)-20 | 75/25 | 70/30 |

### <Preparation of Positive Resist Composition Solution-(1)>

### Example 1, Comparative Examples 1 to 13

The components shown in Table 20 were mixed together and dissolved to obtain positive resist composition solutions.

TABLE 20

| | Component (A) | Component (B) | Component (D) | Component (E) | Component (S) |
|---|---|---|---|---|---|
| Comp. Ex. 1 | (A)-3 | (B)-1 | (D)-1 | (E)-1 | (S)-1 |
| | [100] | [37.5] | [1.8] | [0.72] | [3,900] |
| Comp. Ex. 2 | (A)-4 | (B)-1 | (D)-1 | (E)-1 | (S)-1 |
| | [100] | [37.5] | [1.8] | [0.72] | [3,900] |
| Comp. Ex. 3 | (A)-5 | (B)-1 | (D)-1 | (E)-1 | (S)-1 |
| | [100] | [37.5] | [1.8] | [0.72] | [3,900] |
| Comp. Ex. 4 | (A)-6 | (B)-1 | (D)-1 | (E)-1 | (S)-1 |
| | [100] | [37.5] | [1.8] | [0.72] | [3,900] |
| Comp. Ex. 5 | (A)-7 | (B)-1 | (D)-1 | (E)-1 | (S)-1 |
| | [100] | [37.5] | [1.8] | [0.72] | [3,900] |
| Comp. Ex. 6 | (A)-8 | (B)-1 | (D)-1 | (E)-1 | (S)-1 |
| | [100] | [37.5] | [1.8] | [0.72] | [3,900] |
| Comp. Ex. 7 | (A)-9 | (B)-1 | (D)-1 | (E)-1 | (S)-1 |
| | [100] | [37.5] | [1.8] | [0.72] | [3,900] |
| Comp. Ex. 8 | (A)-10 | (B)-1 | (D)-1 | (E)-1 | (S)-1 |
| | [100] | [37.5] | [1.8] | [0.72] | [3,900] |
| Comp. Ex. 9 | (A)-11 | (B)-1 | (D)-1 | (E)-1 | (S)-1 |
| | [100] | [37.5] | [1.8] | [0.72] | [3,900] |
| Comp. Ex. 10 | (A)-12 | (B)-1 | (D)-1 | (E)-1 | (S)-1 |
| | [100] | [37.5] | [1.8] | [0.72] | [3,900] |
| Comp. Ex. 11 | (A)-1 | (B)-1 | (D)-1 | (E)-1 | (S)-1 |
| | [100] | [37.5] | [1.8] | [0.72] | [3,900] |
| Comp. Ex. 12 | (A)-2 | (B)-1 | (D)-1 | (E)-1 | (S)-1 |
| | [100] | [37.5] | [1.8] | [0.72] | [3,900] |
| Comp. Ex. 13 | (A)-14 | (B)-1 | (D)-1 | (E)-1 | (S)-1 |
| | [100] | [37.5] | [1.8] | [0.72] | [3,900] |
| Ex. 1 | (A)-13 | (B)-1 | (D)-1 | (E)-1 | (S)-1 |
| | [100] | [37.5] | [1.8] | [0.72] | [3,900] |

In Table 20, the reference characters indicate the following. Further, the values in brackets [ ] indicate the amount (in terms of parts by weight) of the component added.

(A)-1: the aforementioned polymer (A)-1

(A)-2: the aforementioned polymer (A)-2

(A)-3: the aforementioned polymer (A)-3

(A)-4: the aforementioned polymer (A)-4

(A)-5: the aforementioned polymer (A)-5

(A)-6: the aforementioned polymer (A)-6

(A)-7: the aforementioned polymer (A)-7

(A)-8: the aforementioned polymer (A)-8

(A)-9: the aforementioned polymer (A)-9

(A)-10: the aforementioned polymer (A)-10

(A)-11: the aforementioned polymer (A)-11

(A)-12: the aforementioned polymer (A)-12

(A)-13: the aforementioned polymer (A)-13

(A)-14: the aforementioned polymer (A)-14

(B)-1: a compound represented by chemical formula (B)-1 shown below

(D)-1: tri-n-octylamine

(E)-1: salicylic acid

(S)-1: a mixed solvent of PGMEA/PGME=6/4 (weight ratio)

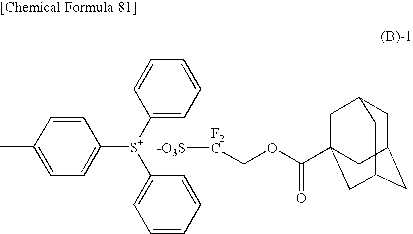

The Tf and Tf′ values were measured for each resist compositions in the following manner, and the results (Tf and (Tf−Tf′) values) are shown in Table 21.

### [Measurements of Tf and Tf′]

In the measurements of Tf and Tf′ values, 15 parts by weight of triphenylsulfonium nonafluorobutanesulfonate as the component (B) and 1.0 part by mass of tri-n-octylamine as the component (D), relative to the 100 parts by weight of the respective component (A), dissolved in 3,900 parts by weight of a mixed solvent of PGMEA/PGME=6/4 (weight ratio) were used.

### [(1) Formation of Isolated Hole Pattern]

An organic anti-reflection film composition (product name: DUV-42P, manufactured by Brewer Science Ltd.) was applied onto an 8-inch silicon wafer using a spinner, and the composition was then baked and dried on a hotplate at 180° C. for 60 seconds, thereby forming an organic anti-reflection film having a film thickness of 65 nm. Then, each of the positive resist composition solutions was applied onto the anti-reflection film using a spinner, and was then prebaked (PAB) on a hotplate at temperatures indicated in Table 21 for 60 seconds and dried, thereby forming a resist film having a film thickness of 100 nm.

Subsequently, the resist film was selectively irradiated with a KrF excimer laser (248 nm) through a mask pattern, using a KrF exposure apparatus NSR-5203 (manufactured by Nikon Corporation, NA (numerical aperture)=0.68, σ=0.75).

Thereafter, a post exposure bake (PEB) treatment was conducted at temperatures indicated in Table 21 for 60 seconds, followed by alkali development for 60 seconds at 23° C. in a 2.38% by weight aqueous solution of tetramethylammonium hydroxide (TMAH) (product name: NMD-3, manufactured by Tokyo Ohka Kogyo Co., Ltd.).

As a result, in each of the examples, an isolated hole pattern having a hole diameter of 170 nm with a pitch of 1,200 nm was formed on the resist film. The optimum exposure dose (Eop; mJ/cm²) during this step is shown in Table 21.

### [(2) Measurement of Resist Softening Point Before Exposure (Tf)]

Each of the obtained isolated hole patterns was subjected either to a temperature of 23° C. (i.e., no postbake treatment) or a postbake treatment of different temperatures; i.e., at 80° C., 90° C. or a total of 14 different temperatures from 95° C. to 160° C. with 5° C. intervals, for 60 seconds.

The dimensional variation in the hole diameter was recorded for the hole patterns subjected to a postbake treatment at each temperature. The resist softening point before exposure (Tf) was defined as a temperature at which the extent of reduction in the hole dimension reaches 10%, with respect to the hole dimension of the hole pattern with no postbake treatment (i.e., the hole pattern subjected to a temperature of 23° C.).

### [(3) Measurement of Resist Softening Point After Exposure (Tf′)]

Each of the isolated hole patterns described in the above section (2) on which no postbake treatment has been conducted was subjected to exposure across the entire surface by irradiating with a Krf excimer laser (248 nm) thereto once again, using a KrF exposure apparatus NSR-S203 (manufactured by Nikon Corporation, NA (numerical aperture)=0.68, σ=0.75). The exposure dose for each of the resist compositions in this process was the same level as the optimum exposure dose for obtaining an isolated hole pattern with a hole diameter of 170 nm described in the above section (1). Then, a second round of PEB treatment was conducted at temperatures indicated in Table 21 for 60 seconds. Thereafter, as in the section (2) described above, each of the obtained isolated hole patterns was subjected either to a temperature of 23° C. (i.e., no postbake treatment) or a postbake treatment of different temperatures; i.e., at 80° C., 90° C. or a total of 14 different temperatures from 95° C. to 160° C. with 5° C. intervals, for 60 seconds. The dimensional variation in the hole diameter was recorded for the hole patterns subjected to a postbake treatment at each temperature. The resist softening point after exposure (Tf′) was defined as a temperature at which the extent of reduction in the hole dimension reaches 10%, with respect to the hole dimension of the hole pattern with no postbake treatment (i.e., the hole pattern subjected to a temperature of 23° C.).

TABLE 21

| | | | | PEB | | |
|---|---|---|---|---|---|---|
| | | | | (Second | | |
| | PAB | Eop | PEB | round) | | Tf − Tf′ |
| | (° C.) | (mJ/cm²) | (° C.) | (° C.) | Tf (° C.) | (° C.) |
| Comp. Ex. 1 | 80 | 26 | 80 | 80 | 98.5 | −20.5 |
| Comp. Ex. 2 | 80 | 34 | 80 | 80 | 97.2 | −17.2 |
| Comp. Ex. 3 | 80 | 34 | 80 | 80 | 96.4 | −16.4 |
| Comp. Ex. 4 | 80 | 26 | 80 | 80 | 114.7 | −16.7 |
| Comp. Ex. 5 | 80 | 34 | 80 | 80 | 114.5 | −17.0 |
| Comp. Ex. 6 | 80 | 40 | 80 | 80 | 111.8 | −15.9 |
| Comp. Ex. 7 | 80 | 28 | 80 | 80 | 125.6 | −11.0 |
| Comp. Ex. 8 | 80 | 34 | 80 | 80 | 125.5 | −10.0 |
| Comp. Ex. 9 | 80 | 42 | 80 | 80 | 125.2 | −9.9 |
| Comp. Ex. 10 | 80 | 34 | 80 | 80 | 145.6 | +8.2 |
| Comp. Ex. 11 | 80 | 32 | 80 | 80 | 98.6 | −18.6 |
| Comp. Ex. 12 | 100 | 30 | 100 | 100 | 165 | +31.5 |
| Comp. Ex. 13 | 80 | 24 | 80 | 80 | 118.0 | −12.5 |
| Ex. 1 | 80 | 32 | 80 | 80 | 117.1 | −20.6 |

### <Formation of Resist Pattern-(1)>

[Sensitivity]

Using the obtained positive resist compositions, the resolution was evaluated.

Using a spinner, each of the positive resist composition solutions obtained in the respective Examples was uniformly applied onto an 8-inch silicon wafer that had been treated with hexamethyldisilazane (HMDS) at 90° C. for 36 seconds, and the solution was then prebaked (PAB) at temperatures indicated in Table 22 for 60 seconds, thus forming a resist film with a film thickness of 80 nm.

This resist film was then subjected to direct patterning (exposure) with an electron beam lithography apparatus HL-800D (VSB) (manufactured by Hitachi, Ltd.) at an acceleration voltage of 70 kV, and was subsequently subjected to a post exposure bake (PEB) treatment at temperatures indicated in Table 22 for 60 seconds, developed for 30 seconds in a 2.38% by weight aqueous tetramethylammonium hydroxide (TMAH) solution (product name: NMD-3, manufactured by Tokyo Ohka Kogyo Co., Ltd.) at 23° C., and then rinsed with pure water for 15 seconds, thereby forming a line and space (L/S) pattern.

At this time, the exposure dose (Eop; μC/cm²) for forming an L/S (1:1) pattern having a line width of 100 nm was determined. The results are shown in Table 22.

### [Evaluation of Line Width Roughness (LWR)

With respect to each of the L/S (1:1) patterns having a line width of 100 nm and formed with the above Eop, the line width at 5 points in the lengthwise direction of the line were measured using a measuring scanning electron microscope (SEM) (product name: S-9220, manufactured by Hitachi, Ltd.; acceleration voltage: 800V), and from the results, the value of 3 times the standard deviation s (i.e., 3s) was calculated as a yardstick of LWR. The results are shown in Table 22. The smaller this 3s value is, the lower the level of roughness of the line width, indicating that an L/S pattern with a uniform width was obtained. The results are shown in Table 22.

TABLE 22

| | PAB | PEB | Eop | LWR |
|---|---|---|---|---|
| | (° C.) | (° C.) | (μC/cm²) | (nm) |
| Comp. Ex. 1 | 100 | 80 | 42 | 15.5 |
| Comp. Ex. 2 | 100 | 80 | 44 | 12.3 |
| Comp. Ex. 3 | 100 | 80 | 42 | 14.6 |
| Comp. Ex. 4 | 100 | 80 | 52 | 18.6 |
| Comp. Ex. 5 | 100 | 80 | 54 | 14.0 |
| Comp. Ex. 6 | 100 | 80 | 48 | 16.7 |
| Comp. Ex. 7 | 100 | 80 | 50 | 15.2 |
| Comp. Ex. 8 | 100 | 80 | 54 | 19.0 |
| Comp. Ex. 9 | 80 | 80 | 44 | 18.5 |
| Comp. Ex. 10 | 100 | 80 | 58 | 20.0 |
| Comp. Ex. 11 | 80 | 80 | 48 | 15.0 |
| Comp. Ex. 12 | 80 | 80 | 19 | 18.0 |
| Comp. Ex. 13 | 80 | 80 | 20 | 20.5 |
| Ex. 1 | 80 | 80 | 42 | 12.0 |

From the results shown in Table 22, it was confirmed that the positive resist composition of Example 1 according to the present invention was excellent in terms of LWR, as compared to the positive resist compositions of Comparative Examples 1 to 13.

### <Preparation of Positive Resist Composition Solution-(2)>

### Example 2, Comparative Example 14

The components shown in Table 23 were mixed together and dissolved to obtain positive resist composition solutions.

Further, the values of Tf, Tf′, bake temperatures and exposure dose for each resist compositions measured in the same manner as described above are shown in Table 24.

TABLE 23

| | Component | Component | Component | Component |
|---|---|---|---|---|
| | (A) | (B) | (D) | (S) |
| Comp. Ex. 14 | (A)-7 | (B)-2 | (D)-1 | (S)-1 |
| | [100] | [23] | [1.5] | [3,900] |
| Ex. 2 | (A)-13 | (B)-2 | (D)-1 | (S)-1 |
| | [100] | [23] | [1.5] | [3,900] |

In Table 23, the reference characters (A)-7, (A)-13, (D)-1 and (S)-1 are the same as defined above, respectively, and (B)-2 indicates a compound represented by chemical formula shown below. Further, the values in brackets [ ] indicate the amount (in terms of parts by weight) of the component added.

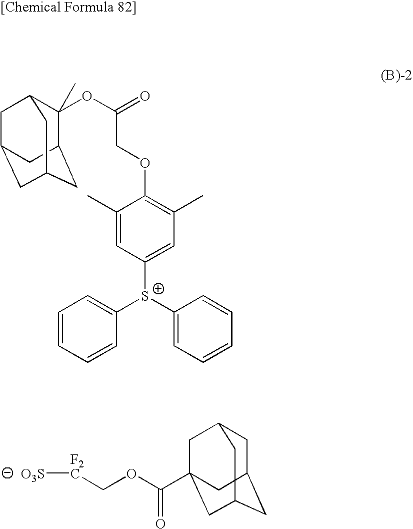

TABLE 24

| | | | | PEB | | |
|---|---|---|---|---|---|---|
| | | | | (Second | | |
| | PAB | Eop | PEB | round) | | Tf − Tf′ |
| | (° C.) | (mJ/cm²) | (° C.) | (° C.) | Tf (° C.) | (° C.) |
| Comp. Ex. 14 | 80 | 34 | 80 | 80 | 116.0 | −17.0 |
| Ex. 2 | 80 | 32 | 80 | 80 | 119.0 | −20.2 |

### <Formation of Resist Pattern-(2)>

[Sensitivity•LWR]

Resist patterns were formed using the obtained positive resist compositions in the same manner as described above in the section <Formation of resist pattern-(1)>, with the exception that the PAB temperature and PEB temperature were changed to those indicated in Table 25. In each cases, an L/S (1:1) pattern having a line width of 100 nm was formed. The exposure dose (Eop; μC/cm²) during this step is shown in Table 25.

Further, LWR was also evaluated in the same manner as described above. The results are shown in Table 25.

TABLE 25

| | PAB | PAB | | Eop | LWR |
|---|---|---|---|---|---|
| | (° C.) | (° C.) | PEB (° C.) | (μC/cm²) | (nm) |
| Comp. Ex. 14 | 80 | 80 | 80 | 42 | 15.6 |
| Ex. 2 | 80 | 80 | 80 | 42 | 14.0 |

From the results shown in Table 25, it was confirmed that the positive resist composition of Example 2 according to the present invention was excellent in terms of LWR, as compared to the positive resist composition of Comparative Examples 14.

### <Preparation of Positive Resist Composition Solution-(3)>

### Examples 3 to 6, Comparative Example 15

The components shown in Table 26 were mixed together and dissolved to obtain positive resist composition solutions.

Further, the values of Tf, Tf′, bake temperatures and exposure dose for each resist compositions measured in the same manner as described above are shown in Table 27.

TABLE 26

| | Component (A) | Component (B) | Component (D) | Component (E) | Component (S) |
|---|---|---|---|---|---|
| Ex. 3 | (A)-15 | (B)-2 | (D)-1 | (E)-1 | (S)-1 |
| | [100] | [40.1] | [1.4] | [0.56] | [3,900] |
| Ex. 4 | (A)-16 | (B)-2 | (D)-1 | (E)-1 | (S)-1 |
| | [100] | [40.1] | [1.4] | [0.56] | [3,900] |
| Comp. Ex. 15 | (A)-17 | (B)-2 | (D)-1 | (E)-1 | (S)-1 |
| | [100] | [40.1] | [1.4] | [0.56] | [3,900] |
| Ex. 5 | (A)-19 | (B)-2 | (D)-1 | (E)-1 | (S)-1 |
| | [100] | [40.1] | [1.4] | [0.56] | [3,900] |
| Ex. 6 | (A)-20 | (B)-2 | (D)-1 | (E)-1 | (S)-1 |
| | [100] | [40.1] | [1.4] | [0.56] | [3,900] |

In Table 26, the values in brackets [ ] indicate the amount (in terms of parts by weight) of the component added. Further, in Table 26, the reference characters (D)-1 and (S)-1 are the same as defined above, respectively, and other reference characters indicate the following.

(A)-15: the aforementioned polymer (A)-15

(A)-16: a polymer (A)-16 (Mn=3,950, Mw/Mn=1.09, PHS/PHS-OAdE=75/25 (molar ratio)) synthesized in the same manner as in Synthesis Example 5 (for the polymer (A)-13 synthesis), with the exception that the amount of 2-(2-methyl)adamantyl iodoacetate charged was changed to 2.8 g

(A)-17: a polymer represented by formula (A)-17 shown below (Mw; 13,000, dispersity; 1.13, m/n=75/25 (molar ratio)) synthesized in accordance with the descriptions disclosed in Japanese Unexamined Patent Application, First Publication No. 2008-250157. The protecting group precursor compound used for the introduction of 2-(2-methyl)adamantyl acetate group is 2-(2-methyl)adamantyl iodoacetate.

(A)-19: the aforementioned polymer (A)-19

(A)-20: the aforementioned polymer (A)-20

(B)-3: a compound represented by chemical formula (B)-3 shown below

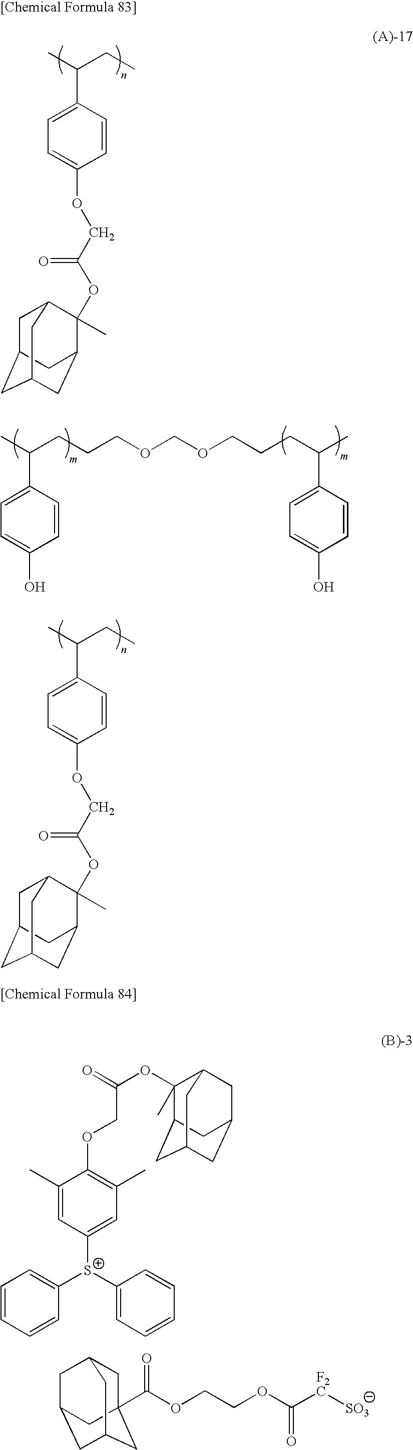

TABLE 27

| | | | | PEB | | |
|---|---|---|---|---|---|---|
| | | | | (Second | | |
| | PAB | Eop | PEB | round) | | Tf − Tf′ |
| | (° C.) | (mJ/cm²) | (° C.) | (° C.) | Tf (° C.) | (° C.) |
| Ex. 3 | 80 | 40 | 80 | 80 | 114.9 | −22.9 |
| Ex. 4 | 80 | 35 | 80 | 80 | 106.6 | −25.6 |
| Comp. Ex. 15 | 80 | 50 | 80 | 80 | 130.0 | +1.5 |
| Ex. 5 | 80 | 65 | 80 | 80 | 117.0 | −23.5 |
| Ex. 6 | 80 | 65 | 80 | 80 | 125.5 | −31.0 |

### <Formation of Resist Pattern-(3)>

[Sensitivity•LWR]

Using a spinner, each of the positive resist composition solutions obtained in the respective Examples was uniformly applied onto an 8-inch silicon wafer that had been treated with hexamethyldisilazane (HMDS) at 90° C. for 36 seconds, and the solution was then prebaked (PAB) at 90° C. for 60 seconds, thus forming a resist film with a film thickness of 50 nm.

This resist film was then subjected to direct patterning (exposure) with an electron beam lithography apparatus HL-800D (VSB) (manufactured by Hitachi, Ltd.) at an acceleration voltage of 70 keV, and was subsequently subjected to a post exposure bake (PEB) treatment at 80° C. for 60 seconds, developed for 60 seconds in a 2.38% by weight aqueous tetramethylammonium hydroxide (TMAH) solution (product name: NMD-3, manufactured by Tokyo Ohka Kogyo Co., Ltd.) at 23° C., and then rinsed with pure water for 15 seconds, thereby forming a line and space (L/S) pattern.

At this time, the exposure dose (Eop; μC/cm²) for forming an L/S (1:1) pattern having a line width of 100 nm was determined. The results are shown in Table 28.

Further, LWR was also evaluated in the same manner as described above. The results are shown in Table 28.

TABLE 28

| | Eop | LWR |
|---|---|---|
| | (μC/cm²) | (nm) |
| Ex. 3 | 40 | 11.7 |
| Ex. 4 | 35 | 9.6 |
| Comp. Ex. 15 | 50 | 12.8 |
| Ex. 5 | 56 | 9.0 |
| Ex. 6 | 62 | 10.1 |

From the results shown in Table 28, it was confirmed that the positive resist compositions of Examples 3 to 6 according to the present invention were excellent in terms of LWR, as compared to the positive resist composition of Comparative Examples 15.

### <Preparation of Positive Resist Composition Solution-(4)>

### Example 7, Comparative Examples 16 to 18

The components shown in Table 29 were mixed together and dissolved to obtain positive resist composition solutions.

Further, the values of Tf, Tf′, bake temperatures and exposure dose for each resist compositions measured in the same manner as described above are shown in Table 30.

TABLE 29

| | | | Component | Component | Component | Component |
|---|---|---|---|---|---|---|
| | Component (A) | | (B) | (D) | (E) | (S) |
| Ex. 7 | (A)-4 | (A)-21 | (B)-3 | (D)-1 | (E)-1 | (S)-1 |
| | [25] | [75] | [40.1] | [1.4] | [0.56] | [3,900] |
| Comp. Ex. 16 | — | (A)-21 | (B)-3 | (D)-1 | (E)-1 | (S)-1 |
| | | [100] | [40.1] | [1.4] | [0.56] | [3,900] |
| Comp. Ex. 17 | (A)-4 | (A)-21 | (B)-3 | (D)-1 | (E)-1 | (S)-1 |
| | [50] | [50] | [40.1] | [1.4] | [0.56] | [3,900] |
| Comp. Ex. 18 | (A)-4 | — | (B)-3 | (D)-1 | (E)-1 | (S)-1 |
| | [100] | | [40.1] | [1.4] | [0.56] | [3,900] |

In Table 29, the values in brackets [ ] indicate the amount (in terms of parts by weight) of the component added. Further, in Table 29, the reference characters (D)-1, (E)-1 and (S)-1 are the same as defined above, respectively, and other reference characters indicate the following. A compound represented by formula (B)-3 was synthesized by referring to Japanese Unexamined Patent Application, First Publication No. 2009-209128.

(A)-21: a polymer represented by formula (A)-21 shown below (Mw; 4,300, Mw/Mn=1.05)

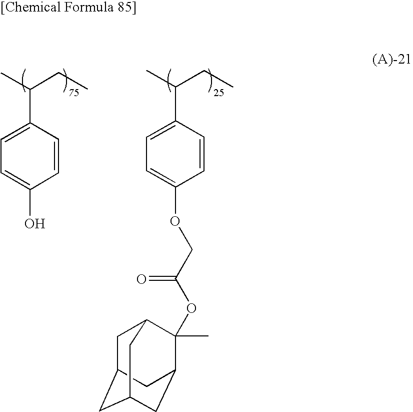

[In the formula, each of the subscript numerals shown to the bottom right of the parentheses ( ) indicate the percentage (molar ratio) of the respective structural units.]

TABLE 30

| | | | | PEB | | |
|---|---|---|---|---|---|---|
| | | | | (Second | | |
| | PAB | Eop | PEB | round) | | Tf − Tf′ |
| | (° C.) | (mJ/cm²) | (° C.) | (° C.) | Tf (° C.) | (° C.) |
| Ex. 7 | 80 | 34 | 80 | 80 | 110.2 | −20.3 |
| Comp. Ex. 16 | 80 | 34 | 80 | 80 | 145.4 | +8.2 |
| Comp. Ex. 17 | 80 | 30 | 80 | 80 | 121.7 | −13.2 |
| Comp. Ex. 18 | 80 | 34 | 80 | 80 | 97.2 | −17.2 |

### <Formation of Resist Pattern-(4)>

[Sensitivity•LWR]

Resist patterns were formed using the obtained positive resist compositions in the same manner as described above in the section <Formation of resist pattern-(3)>. In each case, an L/S (1:1) pattern having a line width of 100 nm was formed. The exposure dose (Eop; μC/cm²) during this step is shown in Table 31.

Further, LWR was also evaluated in the same manner as described above for those which exhibited an adequate level of resolution in the following evaluations. The results are shown in Table 31.

### [Resolution]

The critical resolution (nm) at the above Eop value was determined using a scanning electron microscope (SEM) (product name: S-9220, manufactured by Hitachi, Ltd.), and was evaluated with the following criteria. The results are shown in Table 31.

A: an L/S (1:1) pattern with a line width of 50 nm was resolved.

B: an L/S (1:1) pattern with a line width of 50 nm was not resolved.

### [Pattern Shape]

With respect to the L/S (1:1) patterns formed at the above Eop value, the cross-sectional shape of the resist patterns was observed using a scanning electron microscope (product name: S-4700; manufactured by Hitachi, Ltd.), and the shape was evaluated with the following criteria. The results are shown in Table 31.

A: High rectangularity

B: No rectangularity

TABLE 31

| | EOP | LWR | | |
|---|---|---|---|---|
| | (μC/cm²) | (nm) | Resolution | Pattern shape |
| Ex. 7 | 50 | 13.4 | A | A |
| Comp. Ex. 16 | 54 | 16.0 | A | B |
| Comp. Ex. 17 | 46 | 13.4 | A | B |
| Comp. Ex. 18 | 44 | — | B | B |

From the results shown in Table 31, it was confirmed that the positive resist composition of Example 7 according to the present invention was excellent in terms of resolution, as compared to the positive resist composition of Comparative Example 18. Furthermore, it was also confirmed that the positive resist composition of Example 7 according to the present invention exhibited a comparable or even superior level of LWR, as compared to those of the positive resist compositions of Comparative Examples 16 and 17, and the shape of the pattern formed was also excellent.

What is claimed is:

1. A positive resist composition comprising:
a base material component (A) which exhibits increased solubility in an alkali developing solution under action of acid; and
an acid generator component (B) which generates acid upon exposure,
wherein in those cases where a resist film is formed on a substrate using the positive resist composition and is then subjected to a selective exposure and developing to form a hole pattern, followed by a bake treatment,
a bake treatment temperature (Tf), at which the size of the hole is reduced by 10%, as compared to the size of the hole before the bake treatment, is at least 100° C.; and also
in those cases where a resist film is formed on a substrate using the positive resist composition and is then subjected to a selective exposure and developing to form a hole pattern, followed by the entire surface exposure and then by a bake treatment, a bake treatment temperature (Tf′), at which the size of the hole is reduced by 10%, as compared to the size of the hole before the bake treatment, is at least 18° C. lower than the Tf

2. The positive resist composition according to claim 1,
wherein the base material component (A) includes a polymeric compound (A11) having a core portion constituted of a hydrocarbon group or a heterocycle of two or more valences; and
at least one arm portion bonded to the core portion and also represented by general formula (1) shown below:
[Chemical Formula 1]
—(X)—Y (1)
[wherein X represents a divalent linking group having an acid dissociable group, and Y represents a polymer chain].

3. The positive resist composition according to claim 2,
wherein the polymeric compound (A11) includes two or more of the core portions; and also these core portions are bonded to each other via a linkage portion composed of an atom or a divalent linking group.

4. The positive resist composition according to claim 1,
wherein the base material component (A) includes a polymeric compound (A12) having a core portion constituted of a polymer having a molecular weight within a range from 500 to 20,000; and at least one arm portion bonded to the core portion and also represented by general formula (1) shown below:
[Chemical Formula 2]
—(X)—Y (1)
[wherein X represents a divalent linking group having an acid dissociable group, and Y represents a polymer chain].

5. The positive resist composition according to claim 4,
wherein the polymeric compound (A12) is a polymeric compound represented by general formula (A12-1) shown below: 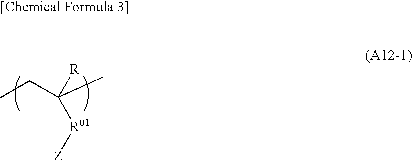
[wherein, R represents a hydrogen atom, an alkyl group of 1 to 5 carbon atoms or a halogenated alkyl group of 1 to 5 carbon atoms; R⁰¹ represents a divalent aromatic group; and Z represents —OH, —COOH, a group represented by the formula (1) above, or a group in which the hydrogen atom in —OH or —COOH has been replaced with an acid dissociable, dissolution inhibiting group (excluding the group represented by the formula (1) above)];
with the proviso that in a plurality of arm portions in the polymeric compound (A12), R and Z may be the same with each other or may be different from each other, and one or more Z is a group represented by the formula (1) above.]

6. A method of forming a resist pattern, comprising:
applying the positive resist composition of any one of claims 1 to 5 to a substrate to form a resist film on the substrate;
subjecting the resist film to exposure; and
alkali developing the resist film to form a resist pattern.
